(19) United States
(12) Patent Application Publication
(10) Pub. No.: US 2025/0016927 A1
(43) Pub. Date: Jan. 9, 2025

(54) MODULE, IMAGE DISPLAY DEVICE LAMINATE, IMAGE DISPLAY DEVICE, MANUFACTURING METHOD OF MODULE, AND WIRING BOARD

(71) Applicant: DAI NIPPON PRINTING CO., LTD., Tokyo-to (JP)

(72) Inventors: Hiroki FURUSHOU, Tokyo-to (JP); Seiji TAKE, Tokyo-to (JP); Kazuki KINOSHITA, Tokyo-to (JP); Masashi SAKAKI, Tokyo-to (JP)

(73) Assignee: DAI NIPPON PRINTING CO., LTD., Tokyo-to (JP)

(21) Appl. No.: 18/708,255

(22) PCT Filed: Nov. 8, 2022
(86) PCT No.: PCT/JP2022/041513

§ 371 Date: Aug. 5, 2024

(30) Foreign Application Priority Data
Nov. 8, 2021 (JP) 2021-182097
Dec. 24, 2021 (JP) 2021-211431
Dec. 24, 2021 (JP) 2021-211456

(51) Int. Cl. H05K 1/18; G02F 1/1345; H01Q 1/22; H10K 59/131

(52) U.S. Cl. CPC H05K 1/181; H01Q 1/22; H10K 59/131; G02F 1/1345; H05K 2201/10128

(57) ABSTRACT

A module includes a wiring board that has a substrate and a mesh wiring layer and a power supply unit and a protective layer, and a power supply line that is electrically connected to the power supply unit via an anisotropic conductive film containing conductive particles. The substrate has transparency. The protective layer covers only part of the power supply unit. The anisotropic conductive film covers a region of the power supply unit that is not covered by the protective layer.

### TECHNICAL FIELD

An embodiment according to the present disclosure relates to a module, an image display device laminate, an image display device, a manufacturing method of the module, and a wiring board.

### BACKGROUND ART

Increased performance, reduction in size, reduction in thickness, and reduction in weight are currently advancing for mobile terminal equipment, such as smartphones, tablets, smart glasses (ΔR, MR, etc.), and so forth. Such mobile terminal equipment uses a plurality of communication bands, and accordingly, a plurality of antennas are required in accordance with the communication bands. For example, mobile terminal equipment is equipped with a plurality of antennas, such as an antenna for telephone, an antenna for WiFi (Wireless Fidelity), an antenna for 3G (Generation), an antenna for 4G (Generation), an antenna for 5G (Generation), an antenna for LTE (Long Term Evolution), an antenna for Bluetooth (registered trademark), an antenna for NFC (Near Field Communication), and so forth. However, due to reduction in size of mobile terminal equipment, space for installing antennas is limited, and the degree in freedom for antenna design is becoming narrower. Also, antennas are built into limited space, and accordingly radio wave sensitivity is not necessarily satisfactory.

Accordingly, film antennas that can be installed in display regions of mobile terminal equipment or transmitting regions of smart glasses have been developed. In such film antennas, an antenna pattern is formed on a transparent base material. The antenna pattern is formed of a mesh-like conductor mesh layer that includes a conductor portion serving as a formation portion of a non-transparent conductor layer, and a great number of openings serving as a non-formation portion.

### CITATION LIST

### Patent Literature

Patent Literature 1: Japanese Unexamined Patent Application Publication No. 2011-66610
Patent Literature 2: Japanese Patent No. 5636735
Patent Literature 3: Japanese Patent No. 5695947

Now, in film antennas, a power supply line is connected to a power supply unit for electrically connecting the conductor mesh layer to external equipment. In this case, there is demand for protecting the power supply unit from corrosion and so forth, while suppressing deterioration in electrical connectability between the power supply unit and the power supply line.

Also, in film antennas, the conductor mesh layer and the power supply unit are preferably covered by a protective layer, to protect the conductor mesh layer and the power supply unit that electrically connects the conductor mesh layer to external equipment. However, in a case of covering the conductor mesh layer by the protective layer, there is a concern that a wiring board will become easier to visually recognize, due to light being reflected at the protective layer.

It is an object of the present embodiment to provide a module, an image display device laminate, and an image display device, capable of suppressing deterioration in electrical connectability between the power supply line and the power supply unit, and also protecting the power supply unit.

The present embodiment provides a wiring board, an image display device laminate, and an image display device, capable of protecting a metal layer that is present in a region that does not overlap a display region of the image display device, and also making the wiring board that is present in a region that overlaps the display region difficult to visually recognize.

The present embodiment provides a wiring board, an image display device laminate, and an image display device, capable of protecting the metal layer and also making the wiring board difficult to visually recognize.

### SUMMARY OF INVENTION

A first aspect of the present disclosure is a module including a wiring board that has a substrate including a first face and a second face situated on an opposite side from the first face, a mesh wiring layer disposed on the first face of the substrate, a power supply unit electrically connected to the mesh wiring layer, and a protective layer that is disposed on the first face of the substrate and that covers the mesh wiring layer and the power supply unit, and a power supply line that is electrically connected to the power supply unit via an anisotropic conductive film containing conductive particles. The substrate has transparency, the protective layer covers only part of the power supply unit, and the anisotropic conductive film covers a region of the power supply unit that is not covered by the protective layer.

With a second aspect of the present disclosure, in the module according to the above first aspect, part of the anisotropic conductive film may be disposed on the protective layer.

With a third aspect of the present disclosure, in the module according to the above first aspect or the above second aspect, a region of the power supply unit that is covered by neither the protective layer nor the anisotropic conductive film may be covered by a covering layer containing a material that has corrosion resistance.

With a fourth aspect of the present disclosure, in the module according to each one of the above first aspect to the above third aspect, the power supply line may be electrically connected to the power supply unit by the conductive particles entering into the protective layer.

With a fifth aspect of the present disclosure, in the module according to each one of the above first aspect to the above fourth aspect, a thickness of the protective layer may be 4.0 μm or more and 8.0 μm or less.

With a sixth aspect of the present disclosure, in the module according to each one of the above first aspect to the above fifth aspect, a dummy wiring layer that is electrically isolated from the mesh wiring layer may be provided on a periphery of the mesh wiring layer.

With a seventh aspect of the present disclosure, in the module according to each one of the above first aspect to the above sixth aspect, the wiring board may have a radio wave transmission/reception function.

With an eighth aspect of the present disclosure, in the module according to each one of the above first aspect to the above seventh aspect, the mesh wiring layer may include a transfer portion that is connected to the power supply unit and a transmission/reception unit that is connected to the transfer portion.

A ninth aspect of the present disclosure is an image display device laminate including the module according to any one of the above first aspect to the above eighth aspect, a first adhesive layer situated on the first face side of the substrate, and a second adhesive layer situated on the second face side of the substrate. A partial region of the substrate is disposed in a partial region between the first adhesive layer and the second adhesive layer.

A tenth aspect of the present disclosure is an image display device including the image display device laminate according to the above ninth aspect, and a display device that is laminated on the image display device laminate.

An eleventh aspect of the present disclosure is a manufacturing method of a module, the method including a step of preparing a substrate that includes a first face and a second face situated on an opposite side from the first face, a step of forming a mesh wiring layer and a power supply unit that is electrically connected to the mesh wiring layer on the first face of the substrate, a step of forming a protective layer on the first face of the substrate, so as to cover the mesh wiring layer and the power supply unit, and a step of electrically connecting a power supply line to the power supply unit via an anisotropic conductive film containing conductive particles. The substrate has transparency, the protective layer covers only part of the power supply unit, and the anisotropic conductive film covers a region of the power supply unit that is not covered by the protective layer.

A twelfth aspect of the present disclosure is a wiring board for an image display device, the wiring board including a substrate, a metal layer disposed on the substrate, and a protective layer that covers part of the metal layer. The substrate has transparency, the metal layer includes a mesh wiring layer, and the protective layer is present in a first region that does not overlap a display region of the image display device, and is not present in a second region that overlaps the display region of the image display device. Note that in the present specification, to have transparency means that transmittance of light rays of wavelengths of 400 nm or higher and 700 nm or lower is 85% or more.

With a thirteenth aspect of the present disclosure, in the wiring board according to the above twelfth aspect, a difference in a coefficient of thermal contraction of the protective layer and a coefficient of thermal contraction of the substrate after one hour at 120° C. may be 1% or less.

With a fourteenth aspect of the present disclosure, in the wiring board according to the above twelfth aspect or the above thirteenth aspect, a dissipation factor of the protective layer may be 0.002 or less.

With a fifteenth aspect of the present disclosure, in the wiring board according to each one of the above twelfth aspect to the above fourteenth aspect, a proportion of a thickness T₁₂ of the protective layer as to a thickness T₁ of the substrate (T₁₂/T₁) may be 0.02 or more and 5.0 or less.

With a sixteenth aspect of the present disclosure, in the wiring board according to each one of the above twelfth aspect to the above fifteenth aspect, a thickness of the substrate may be 10 μm or more and 50 μm or less.

With a seventeenth aspect of the present disclosure, in the wiring board according to each one of the above twelfth aspect to the above sixteenth aspect, a dummy wiring layer that is electrically isolated from the mesh wiring layer may be provided on a periphery of the mesh wiring layer.

With an eighteenth aspect of the present disclosure, in the wiring board according to each one of the above twelfth aspect to the above seventeenth aspect, the mesh wiring layer may function as an antenna.

With a nineteenth aspect of the present disclosure, the wiring board according to each one of the above twelfth aspect to the above eighteenth aspect may further include a power supply unit electrically connected to the mesh wiring layer. The mesh wiring layer may include a transfer portion that is connected to the power supply unit and a transmission/reception unit that is connected to the transfer portion.

With a twentieth aspect of the present disclosure, in the wiring board according to each one of the above twelfth aspect to the above nineteenth aspect, the substrate, the metal layer, and the protective layer may be bent in the first region.

A twenty-first aspect of the present disclosure is a module including the wiring board according to any one of the above twelfth aspect to the above nineteenth aspect, and a power supply line electrically connected to the wiring board.

A twenty-second aspect of the present disclosure is an image display device laminate including the wiring board according to any one of the above twelfth aspect to the above nineteenth aspect, a third adhesive layer that has a wider area than the substrate, and a fourth adhesive layer that has a wider area than the substrate. The third adhesive layer has transparency, the fourth adhesive layer has transparency, and a partial region of the substrate is disposed in a partial region between the third adhesive layer and the fourth adhesive layer.

With a twenty-third aspect of the present disclosure, in the image display device laminate according to the above twenty-second aspect, at least one thickness of a thickness of the third adhesive layer and a thickness of the fourth adhesive layer may be 1.5 times or more a thickness of the substrate.

With a twenty-fourth aspect of the present disclosure, in the image display device laminate according to the above twenty-second aspect or the above twenty-third aspect, material of the third adhesive layer may be acrylic-based resin, and material of the fourth adhesive layer may be acrylic-based resin.

A twenty-fifth aspect of the present disclosure is an image display device including the image display device laminate according to any one of the above twenty-second aspect to the above twenty-fourth aspect, and a display unit that has a display region and that is laminated on the image display device laminate.

A twenty-sixth aspect of the present disclosure is a wiring board for an image display device, the wiring board including a substrate, a metal layer disposed on the substrate, and a protective layer that covers the metal layer. The substrate has transparency, the metal layer includes a mesh wiring layer, and a difference in refractive index of the substrate and refractive index of the protective layer is 0.1 or less. Note that in the present specification, to have transparency means that transmittance of light rays of wavelengths of 400 nm or higher and 700 nm or lower is 85% or more.

With a twenty-seventh aspect of the present disclosure, in the wiring board according to the above twenty-sixth aspect, a difference in a coefficient of thermal contraction of the protective layer and a coefficient of thermal contraction of the substrate after one hour at 120° C. may be 1% or less.

With a twenty-eighth aspect of the present disclosure, in the wiring board according to the above twenty-sixth aspect or the above twenty-seventh aspect, a dissipation factor of the protective layer may be 0.002 or less.

With a twenty-ninth aspect of the present disclosure, in the wiring board according to each one of the above twenty-sixth aspect to the above twenty-eighth aspect, a proportion of a thickness T₁₂ of the protective layer as to a thickness T₁ of the substrate (T₁₂/T₁) may be 0.02 or more and 5.0 or less.

With a thirtieth aspect of the present disclosure, in the wiring board according to each one of the above twenty-sixth aspect to the above twenty-ninth aspect, a thickness of the substrate may be 10 μm or more and 50 μm or less.

With a thirty-first aspect of the present disclosure, in the wiring board according to each one of the above twenty-sixth aspect to the above thirtieth aspect, a dummy wiring layer that is electrically isolated from the mesh wiring layer may be provided on a periphery of the mesh wiring layer.

With a thirty-second aspect of the present disclosure, in the wiring board according to each one of the above twenty-sixth aspect to the above thirty-first aspect, the mesh wiring layer may function as an antenna.

With a thirty-third aspect of the present disclosure, the wiring board according to each one of the above twenty-sixth aspect to the above thirty-second aspect, may further include a power supply unit electrically connected to the mesh wiring layer. The mesh wiring layer may include a transfer portion that is connected to the power supply unit and a transmission/reception unit that is connected to the transfer portion.

With a thirty-fourth aspect of the present disclosure, in the wiring board according to each one of the above twenty-sixth aspect to the above thirty-third aspect, the substrate, the metal layer, and the protective layer are partially bent.

A thirty-fifth aspect of the present disclosure is a module including the wiring board according to any one of the above twenty-sixth aspect to the above thirty-fourth aspect, and a power supply line electrically connected to the wiring board.

A thirty-sixth aspect of the present disclosure is an image display device laminate including a third adhesive layer, a fourth adhesive layer, and a wiring board disposed between the third adhesive layer and the fourth adhesive layer. The wiring board has a substrate, a metal layer disposed on the substrate, and a protective layer covering the metal layer, the substrate has transparency, the third adhesive layer has transparency, the fourth adhesive layer has transparency, the metal layer includes a mesh wiring layer, and a difference between a greatest value and a smallest value of refractive index of the substrate, refractive index of the protective layer, refractive index of the third adhesive layer, and refractive index of the fourth adhesive layer, is 0.1 or less.

With a thirty-seventh aspect of the present disclosure, in the image display device laminate according to the above thirty-sixth aspect, at least one thickness of a thickness of the third adhesive layer and a thickness of the fourth adhesive layer may be 1.5 times or more a thickness of the substrate.

With a thirty-eighth aspect of the present disclosure, in the image display device laminate according to the above thirty-sixth aspect or the above thirty-seventh aspect, material of the third adhesive layer may be acrylic-based resin, and material of the fourth adhesive layer may be acrylic-based resin.

A thirty-ninth aspect of the present disclosure is an image display device including the image display device laminate according to any one of the above thirty-sixth aspect to the above thirty-eighth aspect, and a display unit that is laminated on the image display device laminate.

According to an embodiment of the present disclosure, deterioration in electrical connectability between the power supply line and the power supply unit can be suppressed, and also the power supply unit can be protected.

According to an embodiment of the present disclosure, the metal layer that is present in the region that does not overlap the display region of the image display device can be protected, and also the wiring board that is present in the region that overlaps the display region can be made to be difficult to visually recognize.

According to an embodiment of the present disclosure, the metal layer can be protected, and also the wiring board can be made to be difficult to visually recognize.

### BRIEF DESCRIPTION OF DRAWINGS

FIG. 1 is a plan view illustrating an image display device according to a first embodiment.

FIG. 2 is a cross-sectional view (cross-sectional view along line II-II in FIG. 1) illustrating the image display device according to the first embodiment.

FIG. 3 is a plan view illustrating a wiring board according to the first embodiment.

FIG. 4 is an enlarged plan view illustrating a mesh wiring layer of the wiring board and a power supply unit according to the first embodiment.

FIG. 5 is a cross-sectional view (cross-sectional view along line V-V in FIG. 4) illustrating the wiring board according to the first embodiment.

FIG. 6 is a cross-sectional view (cross-sectional view along line VI-VI in FIG. 4) illustrating the wiring board according to the first embodiment.

FIG. 7 is a plan view illustrating a module according to the first embodiment.

FIG. 8 (a) is an enlarged plan view illustrating a power supply unit of the module according to the first embodiment, and FIG. 8 (b) is an enlarged plan view illustrating a power supply line of the module according to the first embodiment.

FIG. 9 is a cross-sectional view (cross-sectional view along line IX-IX in FIG. 7) illustrating the module according to the first embodiment.

FIG. 10 (a) to (f) are cross-sectional views illustrating a manufacturing method of the wiring board according to the first embodiment.

FIG. 11 (a) to (c) are cross-sectional views illustrating a manufacturing method of the module according to the first embodiment.

FIG. 12 (a) to (c) are cross-sectional views illustrating a manufacturing method of an image display device laminate according to the first embodiment.

FIG. 13 is a cross-sectional view illustrating a module according to a first modification.

FIG. 14 is a cross-sectional view illustrating a module according to a second modification.

FIG. 15 (a) to (d) are cross-sectional views illustrating a manufacturing method of the module according to the second modification.

FIG. 16 is a cross-sectional view illustrating a module according to a third modification.

FIG. 17 (a) to (c) are cross-sectional views illustrating a manufacturing method of the module according to the third modification.

FIG. 18 is a plan view illustrating a wiring board according to a first modification.

FIG. 19 is an enlarged plan view illustrating the wiring board according to the first modification.

FIG. 20 is a plan view illustrating a wiring board according to a second modification.

FIG. 21 is an enlarged plan view illustrating the wiring board according to the second modification.

FIG. 22 is an enlarged plan view illustrating a mesh wiring layer of a wiring board according to a third modification.

FIG. 23 is a plan view illustrating an image display device according to a second embodiment.

FIG. 24 is a cross-sectional view (cross-sectional view along line XXIV-XXIV in FIG. 23) illustrating the image display device according to the second embodiment.

FIG. 25 is a plan view illustrating the wiring board.

FIG. 26 is an enlarged plan view illustrating a mesh wiring layer of the wiring board.

FIG. 27 is a cross-sectional view (cross-sectional view along line XXVII-XXVII in FIG. 26) illustrating the wiring board.

FIG. 28 is a cross-sectional view (cross-sectional view along line XXVIII-XXVIII in FIG. 26) illustrating the wiring board.

FIG. 29 (a) to (g) are cross-sectional views illustrating a manufacturing method of the wiring board according to the second embodiment.

FIG. 30 is a cross-sectional view illustrating the wiring board in a bent state.

FIG. 31 is a plan view illustrating a wiring board according to a first modification.

FIG. 32 is a plan view illustrating a wiring board according to a second modification.

FIG. 33 is a cross-sectional view illustrating a wiring board according to a third modification.

FIG. 34 is a cross-sectional view illustrating a wiring board according to a fourth modification.

FIG. 35 is a cross-sectional view illustrating an image display device according to a third embodiment (cross-sectional view corresponding to FIG. 24).

FIG. 36 is a plan view illustrating the wiring board.

FIG. 37 (a) to (g) are cross-sectional views illustrating a manufacturing method of the wiring board according to the third embodiment.

FIG. 38 is a plan view illustrating a wiring board according to a first modification.

FIG. 39 is a plan view illustrating a wiring board according to a second modification.

### DESCRIPTION OF EMBODIMENTS

### First Embodiment

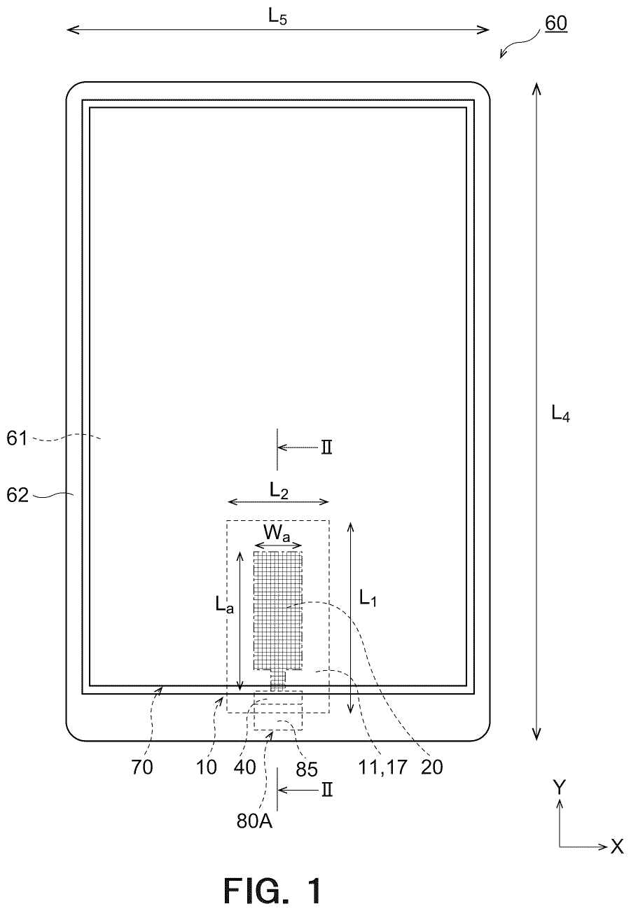

First, a first embodiment will be described by way of FIG. 1 to FIG. 12. FIG. 1 to FIG. 12 are diagrams illustrating the present embodiment.

The diagrams described below are schematically illustrated diagrams. Accordingly, sizes and shapes of each of the portions are exaggerated as appropriate, in order to facilitate understanding. Also, implementation can be carried out modified as appropriate without departing from the technical spirit. Note that in the diagrams described below, parts that are the same are denoted by the same signs, and detailed description may be partly omitted. Also, numerical values, such as dimensions and so forth, and names of materials of the members described in the present specification are exemplary as embodiments, and can be selected as appropriate and used without being limited thereto. In the present specification, terms that identify shapes or geometrical conditions, such as for example, the terms parallel, orthogonal, perpendicular, and so forth, can be interpreted including, in addition to strict meanings thereof, states that are substantially the same.

Also, in the embodiment below, “X direction” is a direction parallel to one side of an image display device. “Y direction” is a direction that is perpendicular to the X direction and also parallel to the other side of the image display device. “Z direction” is a direction that is perpendicular to both the X direction and the Y direction, and is parallel to a thickness direction of the image display device. Also, “front face” is a face on a plus side in the Z direction, which is a light-emitting face side of the image display device, and is a face that faces an observer side. “Rear face” is a face on a minus side in the Z direction, which is a face opposite to the light-emitting face of the image display device and to the face that faces the observer side. Note that in the present embodiment, an example will be described in which a mesh wiring layer 20 is a mesh wiring layer 20 having radio wave transmission/reception functions (functions as an antenna), but the mesh wiring layer 20 does not have to have such radio wave transmission/reception functions (functions as an antenna).

### [Configuration of Image Display Device]

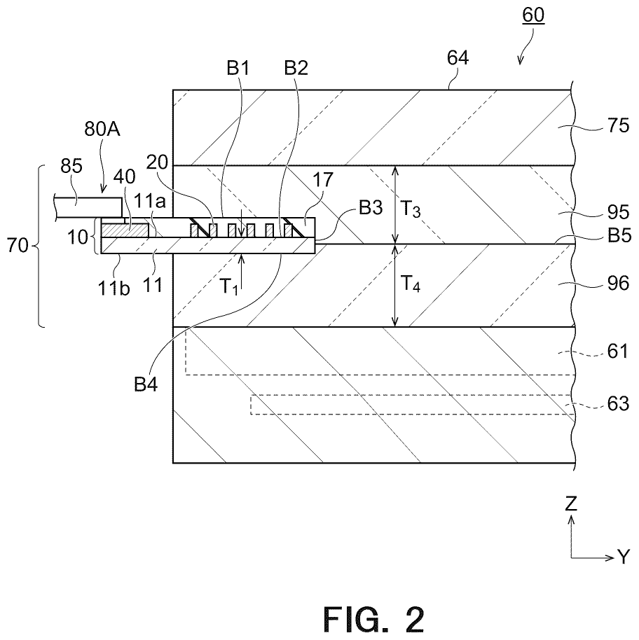

A configuration of the image display device according to the present embodiment will be described with reference to FIG. 1 and FIG. 2.

As illustrated in FIG. 1 and FIG. 2, an image display device 60 according to the present embodiment includes an image display device laminate 70, and a display device (display) 61 that is laminated on the image display device laminate 70. Of these, the image display device laminate 70 includes a first transparent adhesive layer (first adhesive layer) 95, a second transparent adhesive layer (second adhesive layer) 96, and a module 80A. The module 80A of the image display device laminate 70 includes a wiring board 10, and a power supply line 85 that is electrically connected to the wiring board 10.

The wiring board 10 of the module 80A has a substrate 11, a mesh wiring layer 20, a power supply unit 40, and a protective layer 17 that covers the mesh wiring layer 20 and the power supply unit 40. The substrate 11 includes a first face 11a and a second face 11b situated on an opposite side from the first face 11a. The mesh wiring layer 20 is disposed on the first face 11a of the substrate 11. Also, the power supply unit 40 is electrically connected to the mesh wiring layer 20. Further, a communication module 63 is disposed on the minus side of the display device 61 in the Z direction. The image display device laminate 70, the display device 61, and the communication module 63 are accommodated in a housing 62.

In the image display device 60 illustrated in FIG. 1 and FIG. 2, radio waves of a predetermined frequency can be transmitted/received, and communication can be performed via the communication module 63. The communication module 63 may include one of an antenna for telephone, an antenna for WiFi, an antenna for 3G, an antenna for 4G, an antenna for 5G, an antenna for LTE, an antenna for Bluetooth (registered trademark), an antenna for NFC, and so forth. Examples of such image display devices 60 include mobile terminal equipment such as smartphones, tablets, and so forth, and smart glasses.

As illustrated in FIG. 2, the image display device 60 has a light-emitting face 64. The image display device 60 includes the wiring board 10 that is situated on the light-emitting face 64 side (plus side in Z direction) as to the display device 61, and the communication module 63 that is situated on the opposite side from the light-emitting face 64 (minus side in Z direction) as to the display device 61.

The display device 61 is made up of an organic EL (Electro Luminescence) display device, for example. The display device 61 may include a metal layer, a support base material, a resin base material, a thin-film transistor (TFT), and an organic EL layer, which are not illustrated, for example. A touch sensor that is not illustrated may be disposed over the display device 61. Also, the wiring board 10 is disposed over the display device 61 with the second transparent adhesive layer 96 interposed therebetween. Note that the display device 61 is not limited to an organic EL display device. For example, the display device 61 may be another display device that has functions of light emission in itself, and may be a micro-LED display device including microscopic LED elements (light emitters). Alternatively, the display device 61 may be a liquid crystal display device including liquid crystal. Also, a cover glass (surface protective plate) 75 is disposed over the wiring board 10 with the first transparent adhesive layer 95 interposed therebetween. Note that a decorative film and a polarizing plate, which are not illustrated, may be disposed between the first transparent adhesive layer 95 and the cover glass 75.

The first transparent adhesive layer 95 is an adhesive layer that directly or indirectly performs adhesion of the wiring board 10 to the cover glass 75. This first transparent adhesive layer 95 is situated in the first face 11a side of the substrate 11. The first transparent adhesive layer 95 has optical transparency, and may be an OCA (Optical Clear Adhesive) layer. The OCA layer is a layer that is fabricated as follows, for example. First, a curable adhesive layer composition that is in a liquid state and that includes a polymerizable compound is coated on a releasing film of polyethylene terephthalate (PET) or the like, and then cured by using ultraviolet rays (UV) or the like, for example, thereby obtaining an OCA sheet. This OCA sheet is applied to an object, following which the releasing film is removed by separation, thereby obtaining the OCA layer. The material of the first transparent adhesive layer 95 may be an acrylic-based resin, a silicone-based resin, a urethane-based resin, or the like. In particular, the first transparent adhesive layer 95 may contain an acrylic-based resin. In this case, the second transparent adhesive layer 96 preferably contains acrylic-based resin. This substantially does away with difference in refractive index between the first transparent adhesive layer 95 and the second transparent adhesive layer 96, and reflection of visible light at an interface B5 between the first transparent adhesive layer 95 and the second transparent adhesive layer 96 can be suppressed in a more reliable manner.

Also, the transmittance of visible light rays (light rays of wavelengths 400 nm or more and 700 nm or less) of the first transparent adhesive layer 95 may be 85% or more, and preferably is 90% or more. Note that there is no upper limit in particular to the transmittance of visible light rays of the first transparent adhesive layer 95, but this may be, for example, 100% or less. Making the transmittance of visible light rays of the first transparent adhesive layer 95 to be in the above range raises the transparency of the image display device laminate 70, thereby facilitating visibility of the display device 61 of the image display device 60.

The wiring board 10 is disposed on the light-emitting face 64 side from the display device 61, as described above. In this case, the wiring board 10 is situated between the first transparent adhesive layer 95 and the second transparent adhesive layer 96. More specifically, a partial region of the substrate 11 of the wiring board 10 is disposed in a partial region between the first transparent adhesive layer 95 and the second transparent adhesive layer 96. In this case, the first transparent adhesive layer 95, the second transparent adhesive layer 96, the display device 61, and the cover glass 75 each have a greater area than that of the substrate 11 of the wiring board 10. Thus, disposing the substrate 11 of the wiring board 10 in not the entire area of the image display device 60 in plan view but in a partial region thereof enables the overall thickness of the image display device 60 to be reduced.

The wiring board 10 has the substrate 11 that has transparency, the mesh wiring layer 20 disposed on the first face 11a of the substrate 11, the power supply unit 40 that is electrically connected to the mesh wiring layer 20, and the protective layer 17 that is disposed on the first face 11a of the substrate 11 and that covers the mesh wiring layer 20 and the power supply unit 40. The power supply unit 40 is electrically connected to the mesh wiring layer 20. The power supply unit 40 is electrically connected to the communication module 63 via the power supply line 85. Also, part of the wiring board 10 is not disposed between the first transparent adhesive layer 95 and the second transparent adhesive layer 96, but protrudes to an outer side (minus side in Y direction) from between the first transparent adhesive layer 95 and the second transparent adhesive layer 96. Specifically, a region of the wiring board 10 in which the power supply unit 40 is provided protrudes to the outer side. Accordingly, electrical connection between the power supply unit 40 and the communication module 63 is facilitated. On the other hand, a region of the wiring board 10 in which the mesh wiring layer 20 is provided is situated between the first transparent adhesive layer 95 and the second transparent adhesive layer 96. Note that details of the wiring board 10 and the power supply line 85 will be described later.

The second transparent adhesive layer 96 is an adhesive layer that directly or indirectly performs adhesion of the display device 61 to the wiring board 10. The second transparent adhesive layer 96 is situated on the second face 11b side of the substrate 11. The second transparent adhesive layer 96 has optical transparency, and may be an OCA (Optical Clear Adhesive) layer, in the same way as the first transparent adhesive layer 95. The material of the second transparent adhesive layer 96 may be an acrylic-based resin, a silicone-based resin, a urethane-based resin, or the like. In particular, the second transparent adhesive layer 96 may contain an acrylic-based resin. This substantially does away with difference in refractive index between the first transparent adhesive layer 95 and the second transparent adhesive layer 96, and reflection of visible light at the interface B5 between the first transparent adhesive layer 95 and the second transparent adhesive layer 96 can be suppressed in a more reliable manner.

Also, the transmittance of visible light rays (light rays of wavelengths 400 nm or more and 700 nm or less) of the second transparent adhesive layer 96 may be 85% or more, and preferably is 90% or more. Note that there is no upper limit in particular to the transmittance of visible light rays of the second transparent adhesive layer 96, but this may be, for example, 100% or less. Making the transmittance of visible light rays of the second transparent adhesive layer 96 to be in the above range raises the transparency of the image display device laminate 70, thereby facilitating visibility of the display device 61 of the image display device 60.

In this image display device laminate 70, the difference between the refractive index of the first transparent adhesive layer 95 and the refractive index of the protective layer 17 of the wiring board 10 is 0.1 or less, and preferably is 0.05 or less. Also, the difference between the refractive index of the protective layer 17 and the refractive index of the substrate 11 is 0.1 or less, and preferably is 0.05 or less. Here, refractive index refers to absolute refractive index, and can be found on the basis of Method A of JIS K-7142. For example, in a case in which the material of the first transparent adhesive layer 95 is an acrylic-based resin (refractive index 1.49), the refractive index of the protective layer 17 is 1.39 or more and 1.59 or less.

Suppressing the difference between the refractive index of the first transparent adhesive layer 95 and the refractive index of the protective layer 17 to 0.1 or less in this way suppresses reflection of visible light at an interface B1 between the first transparent adhesive layer 95 and the protective layer 17, and the substrate 11 on which the protective layer 17 is provided can be made to be difficult to visually recognize by the bare eye of the observer. Also, suppressing the difference between the refractive index of the protective layer 17 and the refractive index of the substrate 11 to 0.1 or less suppresses reflection of visible light at an interface B2 between the protective layer 17 and the substrate 11, and the substrate 11 can be made to be difficult to visually recognize by the bare eye of the observer.

Also, in the image display device laminate 70, the difference between the refractive index of the substrate 11 and the refractive index of the first transparent adhesive layer 95 is 0.1 or less, and preferably is 0.05 or less. Also, the difference between the refractive index of the second transparent adhesive layer 96 and the refractive index of the substrate 11 is 0.1 or less, and preferably is 0.05 or less. Further, the difference between the refractive index of the first transparent adhesive layer 95 and the refractive index of the second transparent adhesive layer 96 is preferably 0.1 or less, and more preferably is 0.05 or less. For example, in a case in which the material of the first transparent adhesive layer 95 and the material of the second transparent adhesive layer 96 are acrylic-based resin (refractive index 1.49), the refractive index of the substrate 11 is 1.39 or more and 1.59 or less. Examples of such materials include fluororesins, silicone-based resins, polyolefin resins, polyester-based resins, acrylic-based resins, polycarbonate-based resins, polyimide-based resins, cellulose-based resins, and so forth.

Suppressing the difference between the refractive index of the substrate 11 and the refractive index of the first transparent adhesive layer 95 to 0.1 or less in this way suppresses reflection of visible light at an interface B3 between the substrate 11 and the first transparent adhesive layer 95, and the substrate 11 can be made to be difficult to visually recognize by the bare eye of the observer. Also, suppressing the difference between the refractive index of the second transparent adhesive layer 96 and the refractive index of the substrate 11 to 0.1 or less suppresses reflection of visible light at an interface B4 between the second transparent adhesive layer 96 and the substrate 11, and the substrate 11 can be made to be difficult to visually recognize by the bare eye of the observer. Further, suppressing the difference between the refractive index of the first transparent adhesive layer 95 and the refractive index of the second transparent adhesive layer 96 to 0.1 or less suppresses reflection of visible light at the interface B5 between the first transparent adhesive layer 95 and the second transparent adhesive layer 96, and the first transparent adhesive layer 95 and the second transparent adhesive layer 96 can be made to be difficult to visually recognize by the bare eye of the observer.

In particular, the material of the first transparent adhesive layer 95 and the material of the second transparent adhesive layer 96 is preferably the same material as each other. Accordingly, the difference in the refractive indices between the first transparent adhesive layer 95 and the second transparent adhesive layer 96 can be further reduced, and reflection of visible light at the interface B5 between the first transparent adhesive layer 95 and the second transparent adhesive layer 96 can be suppressed.

Also, in FIG. 2, at least one thickness of thickness T₃ of the first transparent adhesive layer 95 and thickness T₄ of the second transparent adhesive layer 96 may be 1.5 times the thickness T₁ of the substrate 11 or more, preferably is 2 times thereof or more, and even more preferably is 2.5 times thereof or more. By making the thickness T₃ of the first transparent adhesive layer 95 or the thickness T₄ of the second transparent adhesive layer 96 to be sufficiently thick as to the thickness T₁ of the substrate 11 in this way, the first transparent adhesive layer 95 or the second transparent adhesive layer 96 deforms in the thickness direction in a region overlapping the substrate 11, and takes up the thickness of the substrate 11. Accordingly, stepped portions can be suppressed from being formed in the first transparent adhesive layer 95 or the second transparent adhesive layer 96 at a peripheral edge of the substrate 11, and the presence of the substrate 11 can be made to be difficult to visually recognize by the observer.

Also, at least one thickness of the thickness T₃ of the first transparent adhesive layer 95 and the thickness T₄ of the second transparent adhesive layer 96 is preferably 10 times the thickness T₁ of the substrate 11 or less, and even more preferably is five times thereof or less. Accordingly, the thickness T₃ of the first transparent adhesive layer 95 or the thickness T₄ of the second transparent adhesive layer 96 does not become excessively great, and the thickness of the overall image display device 60 can be reduced.

Also, in FIG. 2, the thickness T₃ of the first transparent adhesive layer 95 and the thickness T₄ of the second transparent adhesive layer 96 may be the same as each other. In this case, the thickness T₃ of the first transparent adhesive layer 95 and the thickness T₄ of the second transparent adhesive layer 96 may each be 1.5 times the thickness T₁ of the substrate 11 or more, and preferably 2.0 times thereof or more. That is to say, the total of the thickness T₃ of the first transparent adhesive layer 95 and the thickness T₄ of the second transparent adhesive layer 96 (T₃+T₄) is three times the thickness T₁ of the substrate 11 or more. Thus, by making the total of thicknesses T₃ and T₄ of the first transparent adhesive layer 95 and the second transparent adhesive layer 96 to be sufficiently thick with respect to the thickness T₁ of the substrate 11, the first transparent adhesive layer 95 and the second transparent adhesive layer 96 deform (contract) in the thickness direction in the region overlapping the substrate 11, and take up the thickness of the substrate 11. Accordingly, stepped portions can be suppressed from being formed in the first transparent adhesive layer 95 or the second transparent adhesive layer 96 at the peripheral edge of the substrate 11, and the presence of the substrate 11 can be made to be difficult to visually recognize by the observer.

Also, in a case in which the thickness T₃ of the first transparent adhesive layer 95 and the thickness T₄ of the second transparent adhesive layer 96 are the same as each other, the thickness T₃ of the first transparent adhesive layer 95 and the thickness T₄ of the second transparent adhesive layer 96 may each be five times the thickness T₁ of the substrate 11 or less, and preferably three times thereof or less. Accordingly, the thicknesses T₃ and T₄ of both of the first transparent adhesive layer 95 and the second transparent adhesive layer 96 do not become excessively great, and the thickness of the overall image display device 60 can be reduced.

Specifically, the thickness T₁ of the substrate 11 may be 2 μm or more and 200 μm or less for example, may be 2 μm or more and 50 μm or less, may be 10 μm or more and 50 μm or less, and preferably is 15 μm or more and 25 μm or less. By making the thickness T₁ of the substrate 11 to be 2 μm or more, strength of the wiring board 10 can be maintained, so that a first-direction wiring line 21 and a second-direction wiring line 22, which will be described later, of the mesh wiring layer 20, are not readily deformed. By making the thickness T₁ of the substrate 11 to be 200 μm or less, stepped portions can be suppressed from being formed between the first transparent adhesive layer 95 and the second transparent adhesive layer 96 at the peripheral edge of the substrate 11, and the presence of the substrate 11 can be made to be difficult to visually recognize by the observer. Also, by making the thickness T₁ of the substrate 11 to be 50 μm or less, stepped portions can be further suppressed from being formed in the first transparent adhesive layer 95 and the second transparent adhesive layer 96 at the peripheral edge of the substrate 11, and the presence of the substrate 11 can be made to be even more difficult to visually recognize by the observer.

The thickness T₃ of the first transparent adhesive layer 95 may be 15 μm or more and 500 μm or less for example, preferably is 15 μm or more and 300 μm or less, and even more preferably is 20 μm or more and 250 μm or less. The thickness T₄ of the second transparent adhesive layer 96 may be 15 μm or more and 500 μm or less for example, preferably is 15 μm or more and 300 μm or less, and even more preferably is 20 μm or more and 250 μm or less.

As described above, the image display device laminate 70 is made up of the module 80A equipped with the wiring board 10, the first transparent adhesive layer 95 that has a greater area than that of the substrate 11 of the wiring board 10, and the second transparent adhesive layer 96 that has a greater area than that of the substrate 11. Such an image display device laminate 70 is also provided in the present embodiment. Also, as described above, the image display device laminate 70 makes up the image display device 60 along with the display device 61. Note that the image display device laminate 70 may be assembled into a head-mounted display (smart glasses) by being attached to a frame that is not illustrated.

Referencing FIG. 2 again, the cover glass (surface protective plate) 75 is directly or indirectly disposed on the first transparent adhesive layer 95. This cover glass 75 is a member made of glass that transmits light. The cover glass 75 is plate-like, and may have a rectangular shape in plan view. The thickness of the cover glass 75 may be 200 μm or more and 1000 μm or less for example, and preferably is 300 μm or more and 700 μm or less. The length of the cover glass 75 in a longitudinal direction (Y direction) may be 20 mm or more and 500 mm or less for example, and preferably 100 mm or more and 200 mm or less, and the length of the cover glass 75 in a lateral direction (X direction) may be 20 mm or more and 500 mm or less, and preferably 50 mm or more and 100 mm or less.

As illustrated in FIG. 1, the image display device 60 is generally rectangular overall in plan view, the longitudinal direction thereof is parallel to the Y direction, and the lateral direction thereof is parallel to the X direction. A length L₄ of the image display device 60 in the longitudinal direction (Y direction) can be selected from a range of 20 mm or more and 500 mm or less for example, and preferably 100 mm or more and 200 mm or less. A length L₅ of the image display device 60 in the lateral direction (X direction) can be selected from a range of 20 mm or more and 500 mm or less for example, and preferably 50 mm or more and 100 mm or less. Note that corner portions of the image display device 60 each may be rounded.

[Configuration of Wiring board]

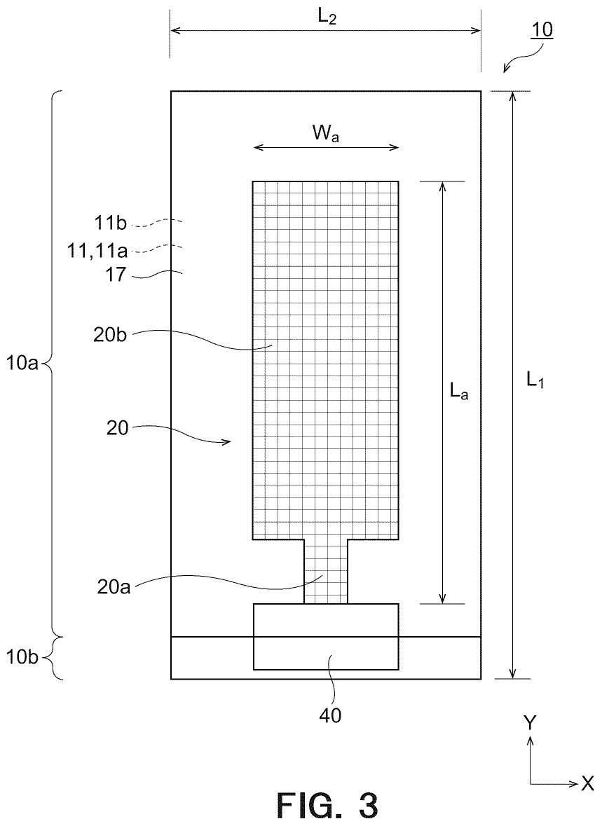

Next, a configuration of the wiring board will be described with reference to FIG. 3 to FIG. 6. FIG. 3 to FIG. 6 are diagrams illustrating the wiring board according to the present embodiment.

As illustrated in FIG. 3, the wiring board 10 according to the present embodiment is used in the image display device 60 (see FIG. 1 and FIG. 2) described above, and is disposed between the first transparent adhesive layer 95 and the second transparent adhesive layer 96, closer to the light-emitting face 64 side than the display device 61. Such a wiring board 10 includes the substrate 11 that has transparency, the mesh wiring layer 20 disposed on the substrate 11, the power supply unit 40 that is electrically connected to the mesh wiring layer 20, and the protective layer 17 that is disposed on the substrate 11 and that covers the mesh wiring layer 20 and the power supply unit 40. Also, the power supply unit 40 is electrically connected to the mesh wiring layer 20.

Of these, the substrate 11 has a generally rectangular shape in plan view, with the longitudinal direction thereof being parallel to the Y direction, and the lateral direction thereof being parallel to the X direction. The substrate 11 has transparency and also has a generally plate-like shape, and a thickness thereof is generally uniform overall. A length L1 of the substrate 11 in the longitudinal direction (Y direction) can be selected from a range of 2 mm or more and 300 mm or less, a range of 10 mm or more and 200 mm or less, or a range of 100 mm or more and 200 mm or less, for example. A length L₂ of the substrate 11 in the lateral direction (X direction) can be selected from a range of 2 mm or more and 300 mm or less, a range of 3 mm or more and 100 mm or less, or a range of 50 mm or more and 100 mm or less, for example. Note that corner portions of the substrate 11 may each be rounded.

It is sufficient for material of the substrate 11 to be a material that has transparency in the visible light domain, and electrical insulating properties. Although the material of the substrate 11 is polyethylene terephthalate in the present embodiment, this is not restrictive. A polyester-based resin such as polyethylene terephthalate or the like, an acrylic-based resin such as polymethyl methacrylate, a polycarbonate-based resin, a polyimide-based resin, or a polyolefin-based resin such as a cycloolefin polymer, a cellulose-based resin such as triacetyl cellulose or the like, a fluororesin material such as PTFE, PFA, and so forth, and like organic insulating materials, for example, is preferably used as the material of the substrate 11. Alternatively, an organic insulating material such as a cycloolefin polymer (e.g., ZF-16 manufactured by Zeon Corporation), a polynorbornene polymer (manufactured by Sumitomo Bakelite Co. Ltd.), or the like may be used as the material of the substrate 11. Also, depending on the usage, glass, ceramics, and so forth can be selected as appropriate as the material of the substrate 11. Note that an example is illustrated in which the substrate 11 is made up of a single layer, but this is not restrictive, and a structure may be made in which a plurality of base materials or layers are laminated. Also, the substrate 11 may be film-like or may be plate-like.

Also, the dissipation factor of the substrate 11 preferably is 0.002 or less. Having the dissipation factor of the substrate 11 in the above range enables loss of gain (sensitivity) in conjunction with transmission/reception of electromagnetic waves to be reduced, particularly in a case in which the electromagnetic waves transmitted/received by the mesh wiring layer 20 (e.g., millimeter waves) are radio frequency waves.

The relative permittivity of the substrate 11 preferably is 2 or more and 10 or less. A greater range of options is available as the material of the substrate 11 by the relative permittivity of the substrate 11 being 2 or more. Also, loss of gain (sensitivity) in conjunction with transmission/reception of electromagnetic waves can be reduced by the relative permittivity of the substrate 11 being 10 or less. That is to say, in a case in which the relative permittivity of the substrate 11 is great, the effects of the thickness of the substrate 11 on propagation of electromagnetic waves increases. Also, in a case in having adverse effects on the propagation of electromagnetic waves, the dissipation factor of the substrate 11 increases, and loss of gain (sensitivity) in conjunction with transmission/reception of electromagnetic waves can increase. Conversely, the relative permittivity of the substrate 11 being 10 or less can reduce the effects of the thickness of the substrate 11 on the propagation of electromagnetic waves. Accordingly, loss of gain (sensitivity) in conjunction with transmission/reception of electromagnetic waves can be reduced. In particular, in a case in which the electromagnetic waves transmitted/received by the mesh wiring layer 20 (e.g., millimeter waves) are radio frequency waves, loss of gain (sensitivity) in conjunction with transmission/reception of electromagnetic waves can be reduced.

The dissipation factor and the relative permittivity of the substrate 11 can be measured in conformance with IEC 62562. Specifically, first, a portion of the substrate 11 on which the mesh wiring layer 20 is not formed is cut out to prepare a test piece. The dimensions of the test piece are 10 mm to 20 mm in width and 50 mm to 100 mm in length. Next, the dissipation factor or the relative permittivity is measured in conformance with IEC 62562.

Also, the substrate 11 has transparency. In the present specification, “has transparency” means transmittance of visible light rays (light rays having wavelength of 400 nm or higher and 700 nm or lower) being 85% or more. The transmittance of the substrate 11 regarding visible light rays (light rays having wavelength of 400 nm or higher and 700 nm or lower) may be 85% or more, and preferably is 90% or more. There is no upper limit to the transmittance of visible light rays of the substrate 11 in particular, but may be 100% or less, for example. Having the transmittance of visible light rays of the substrate 11 in the above range increases the transparency of the wiring board 10, and facilitates visual recognition of the display device 61 of the image display device 60. Note that the term visible light rays refers to light rays having a wavelength of 400 nm or higher and 700 nm or lower. Also, the term transmittance of visible light rays of 85% or more means that transmittance of the entire wavelength domain of 400 nm or higher and 700 nm or lower is 85% or more when light absorbance is measured for the substrate 11 using a known spectrophotometer (e.g., spectroscope: V-670 manufactured by JASCO Corporation).

In the present embodiment, the mesh wiring layer 20 is made up of an antenna pattern having functions as an antenna. In FIG. 3, one mesh wiring layer 20 is formed on the substrate 11. Also, as illustrated in FIG. 3, the mesh wiring layer 20 may be present only on a partial region of the substrate 11, rather than being present over the entire face of the substrate 11. This mesh wiring layer 20 corresponds to a predetermined frequency band. That is to say, the length (length in Y direction) La of the mesh wiring layer 20 has a length corresponding to a particular frequency band. Note that the lower frequency the corresponding frequency band is, the longer a length La of the mesh wiring layer 20 becomes. The mesh wiring layer 20 may correspond to one of an antenna for telephone, an antenna for WiFi, an antenna for 3G, an antenna for 4G, an antenna for 5G, an antenna for LTE, an antenna for Bluetooth (registered trademark), an antenna for NFC, an antenna for millimeter waves, and so forth. Note that a plurality of the mesh wiring layers 20 may be formed on the substrate 11. In this case, the lengths of the plurality of mesh wiring layers 20 may differ from each other, and may correspond to different frequency bands from each other. Alternatively, in a case in which the wiring board 10 does not have radio wave transmission/reception functions, each mesh wiring layer 20 may have functions such as, for example, hovering (a function enabling a user to perform operations even without directly touching the display), fingerprint authentication, heater, noise reduction (shielding), and so forth.

The mesh wiring layer 20 has a basal side portion (transfer portion) 20a on the power supply unit 40 side, and a distal side portion (transmission/reception unit) 20b connected to the basal side portion 20a. The basal side portion 20a and the distal side portion 20b are each generally rectangular in shape, in plan view. In this case, the length (Y-direction distance) of the distal side portion 20b may be longer than the length (Y-direction distance) of the basal side portion 20a, and the width (X-direction distance) of the distal side portion 20b may be broader than the width (X-direction distance) of the basal side portion 20a.

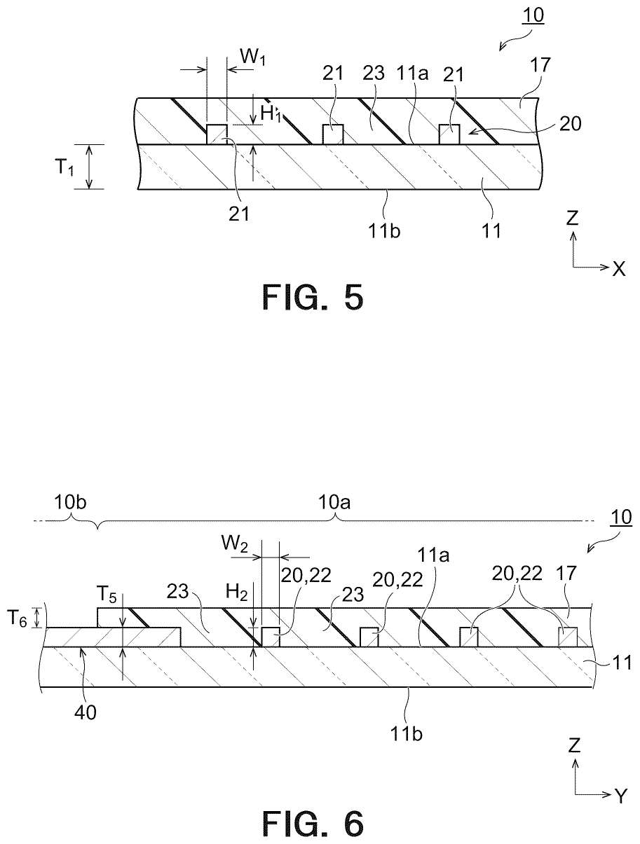

With the mesh wiring layer 20, the longitudinal direction thereof is parallel to the Y direction, and the lateral direction thereof is parallel to the X direction. The length La of the mesh wiring layer 20 in the longitudinal direction (Y direction) can be selected from a range of 2 mm or more and 100 mm or less, or may be selected from a range of 3 mm or more and 100 mm or less, for example. A width Wₐ in the lateral direction (X direction) of the mesh wiring layer 20 (distal side portion 20b) can be selected from a range of 1 mm or more and 10 mm or less, for example. In particular, in a case in which the mesh wiring layer 20 is a millimeter wave antenna, the length La of the mesh wiring layer 20 can be selected from a range of 1 mm or more and 10 mm or less, more preferably 1.5 mm or more and 5 mm or less. Note that while FIG. 5 illustrates a form of a case in which the mesh wiring layer 20 functions as a monopole antenna, this is not restrictive, and forms may be used such as a dipole antenna, a loop antenna, a slot antenna, a microstrip antenna, a patch antenna, and so forth.

The mesh wiring layer 20 is formed with respective metal lines being formed in a grid-like or fishnet-like form, having a repetitive pattern in the X direction and in the Y direction. That is to say, the mesh wiring layer 20 has a pattern form that is made up of portions extending in the X direction (second-direction wiring lines 22), and portions extending in the X direction (first-direction wiring lines 21)

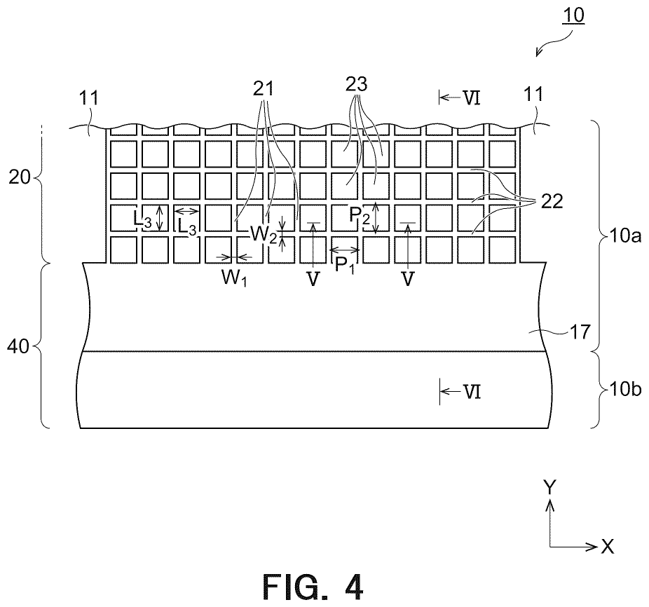

As illustrated in FIG. 4, the mesh wiring layer 20 includes a plurality of the first-direction wiring lines (antenna wiring lines) 21 having functions as an antenna, and a plurality of the second-direction wiring lines (antenna interconnection wiring lines) 22 interconnecting the plurality of first-direction wiring lines 21. Specifically, the plurality of first-direction wiring lines 21 and the plurality of second-direction wiring lines 22 overall and integrally form a grid-like or fishnet-like form. The first-direction wiring lines 21 extend in a direction corresponding to the frequency band of the antenna (longitudinal direction, Y direction), and the second-direction wiring lines 22 extend in a direction orthogonal to the first-direction wiring lines 21 (width direction, X direction). The first-direction wiring lines 21 exhibit functions primarily as an antenna by having the length La (length of the mesh wiring layer 20 described above, see FIG. 3) corresponding to the predetermined frequency band. On the other hand, the second-direction wiring lines 22 interconnect these first-direction wiring lines 21 to each other, and thereby serve to suppress trouble in which the first-direction wiring lines 21 are disconnected, or the first-direction wiring lines 21 and the power supply unit 40 lose electrical connection, or the like.

In the mesh wiring layer 20, a plurality of openings 23 are formed by being surrounded by the first-direction wiring lines 21 adjacent to each other and the second-direction wiring lines 22 adjacent to each other. Also, the first-direction wiring lines 21 and the second-direction wiring lines 22 are disposed equidistantly to each other. That is to say, the plurality of first-direction wiring lines 21 are disposed equidistantly to each other, and a pitch P₁ thereof may be in a range of 0.01 mm or more and 1 mm or less, for example. Also, the plurality of second-direction wiring lines 22 are disposed equidistantly to each other, and a pitch P₂ thereof may be in a range of 0.01 mm or more and 1 mm or less, for example. In this way, due to the plurality of first-direction wiring lines 21 and the plurality of second-direction wiring lines 22 being each disposed equidistantly, variance in the size of the openings 23 in the mesh wiring layer 20 is eliminated, and the mesh wiring layer 20 can be made to be difficult to visually recognize by the bare eye. Also, the pitch P₁ of the first-direction wiring lines 21 is equal to the pitch P₂ of the second-direction wiring lines 22. Accordingly, the openings 23 each have a generally square shape in plan view, and the substrate 11 that has transparency is exposed from each of the openings 23. Thus, the transparency of the wiring board 10 overall can be increased by increasing the area of the openings 23. Note that a length L3 of one side of the openings 23 may be in a range of 0.01 mm or more and 1 mm or less, for example. Note that while the first-direction wiring lines 21 and the second-direction wiring lines 22 are orthogonal to each other, this is not restrictive, and these may intersect at acute angles or obtuse angles. Also, the shapes of the openings 23 preferably are the same shape and the same size over the entire area, but do not have to be uniform over the entire area, with changes being made thereto depending on the location, or the like.

As illustrated in FIG. 5, the cross-section of each first-direction wiring line 21 perpendicular to the longitudinal direction (X-direction cross-section) is a generally rectangular shape or a generally square shape. In this case, the cross-sectional shape of the first-direction wiring lines 21 is generally uniform in the longitudinal direction (Y direction) of the first-direction wiring lines 21. Also, as illustrated in FIG. 6, the cross-sectional shape of each second-direction wiring line 22 perpendicular to the longitudinal direction (Y-direction cross-section) is a generally rectangular shape or a generally square shape, and is generally the same as the cross-sectional shape of the first-direction wiring lines 21 described above (X-direction cross-section). In this case, the cross-sectional shape of the second-direction wiring lines 22 is generally uniform in the longitudinal direction (X direction) of the second-direction wiring lines 22. The cross-sectional shape of the first-direction wiring lines 21 and the second-direction wiring lines 22 does not necessarily have to be a generally rectangular shape or a generally square shape, and for example may be a generally trapezoidal shape in which the front face side (plus side in the Z direction) is narrower than the rear face side (minus side in the Z direction), or a shape in which side faces situated on both sides in the longitudinal direction are curved.

In the present embodiment, a line width W₁ (length in X direction, see FIG. 5) of the first-direction wiring lines 21 and a line width W₂ (length in Y direction, see FIG. 6) of the second-direction wiring lines 22 are not limited in particular, and can be selected as appropriate in accordance with the usage. For example, the line width W₁ of the first-direction wiring lines 21 can be selected from a range of 0.1 μm or more and 5.0 μm or less, and preferably is 0.2 μm or more and 2.0 μm or less. Also, the line width W₂ of the second-direction wiring lines 22 can be selected from a range of 0.1 μm or more and 5.0 μm or less, and preferably is 0.2 μm or more and 2.0 μm or less. Further, a height H₁ (length in Z direction, see FIG. 5) of the first-direction wiring lines 21 and a height H₂ (length in Z direction, see FIG. 6) of the second-direction wiring lines 22 are not limited in particular and can be selected as appropriate in accordance with the usage. The height H₁ of the first-direction wiring lines 21 and the height H₂ of the second-direction wiring lines 22 can each be selected from a range of 0.1 μm or more and 5.0 μm or less for example, and preferably are 0.2 μm or more and 2.0 μm or less.

It is sufficient for the material of the first-direction wiring lines 21 and the second-direction wiring lines 22 to be a metal material that has conductivity. The material of the first-direction wiring lines 21 and the second-direction wiring lines 22 is copper in the present embodiment, but is not limited thereto. Metal materials (including alloys) such as gold, silver, copper, platinum, tin, aluminum, iron, nickel, and so forth, for example, can be used as the material of the first-direction wiring lines 21 and the second-direction wiring lines 22. Also, the first-direction wiring lines 21 and the second-direction wiring lines 22 may be plating layers formed by electrolytic plating.

An overall aperture ratio At of the mesh wiring layer 20 may be in a range of 87% or more and less than 100%, for example. By setting the aperture ratio At of the overall mesh wiring layer 20 to this range, conductivity and transparency of the wiring board 10 can be secured. Note that an aperture ratio is a ratio (%) of area of opening regions (regions where no metal portions, such as the first-direction wiring lines 21, second-direction wiring lines 22, and so forth, are present, and the substrate 11 is exposed) within a unit area of a predetermined region (e.g., the entire mesh wiring layer 20).

Referencing FIG. 3 and FIG. 4 again, the power supply unit 40 is electrically connected to the mesh wiring layer 20. This power supply unit 40 is made up of a thin-plate-like member that is generally rectangular and that has conductivity. The longitudinal direction of the power supply unit 40 is parallel to the X direction, and the lateral direction of the power supply unit 40 is parallel to the Y direction. Also, the power supply unit 40 is disposed on the longitudinal-direction end portion (minus-side end portion in the Y direction) of the substrate 11. Metal materials (including alloys) such as gold, silver, copper, platinum, tin, aluminum, iron, nickel, and so forth, for example, can be used as the material of the power supply unit 40. The power supply unit 40 may be a plate-like member that does not have openings, unlike the mesh wiring layer 20. When the module 80A that includes the wiring board 10 is assembled into the image display device 60 (see FIG. 1 and FIG. 2), the power supply unit 40 is electrically connected to the communication module 63 of the image display device 60 via the power supply line 85. Note that while the power supply unit 40 is provided on the first face 11a of the substrate 11, this is not restrictive, and part or all of the power supply unit 40 may be situated on an outer side from the peripheral edge of the substrate 11. Also, the power supply unit 40 may be formed flexibly, such that the power supply unit 40 can run around to a side face and a rear face of the image display device 60 for electrical connection on the side face and the rear face.

As illustrated in FIG. 4, the plurality of first-direction wiring lines 21 are electrically connected to the power supply unit 40 on the plus side in the Y direction. In this case, the power supply unit 40 is integrally formed with the mesh wiring layer 20. A thickness T₅ (length in Z direction, see FIG. 6) of the power supply unit 40 can be made to be the same as the height H₁ (see FIG. 5) of the first-direction wiring lines 21 and the height H₂ (see FIG. 6) of the second-direction wiring lines 22, and can be selected from a range of 0.1 μm or more and 5.0 μm or less, for example.

Further, as illustrated in FIG. 5 and FIG. 6, the protective layer 17 is formed on the first face 11a of the substrate 11, so as to cover the mesh wiring layer 20 and the power supply unit 40. The protective layer 17 is a layer that protects the mesh wiring layer 20 and the power supply unit 40. As illustrated in FIG. 3, FIG. 4, and FIG. 6, the protective layer 17 covers only part of the power supply unit 40. That is to say, a region not covered by the protective layer 17 is formed on the power supply unit 40. Specifically, the protective layer 17 covers the entire region of the mesh wiring layer 20, and a partial region of the power supply unit 40 on the plus side in the Y direction. A partial region of the power supply unit 40 on the minus side in the Y direction is not covered by the protective layer 17. In other words, a protected region 10a in which the first face 11a is covered by the protective layer 17, and an unprotected region 10b in which the first face 11a is not covered by the protective layer 17, are formed on the wiring board 10.

A thickness T₆ (length in Z direction, see FIG. 6) of the protective layer 17 may be 4.0 μm or more and 8.0 μm or less. Due to the thickness T₆ of the protective layer 17 being 4.0 μm or more, abrasion resistance and weather resistance of the protective layer 17 can be improved. Also, due to the thickness T₆ of the protective layer 17 being 8.0 μm or less, the thickness T₆ of the protective layer 17 can be kept from becoming excessively thick, and the overall thickness of the image display device 60 can be reduced. Note that in the present embodiment, the thickness T₆ of the protective layer 17 is a distance in the Z direction from a surface of the power supply unit 40 to a surface of the protective layer 17.

Further, the dissipation factor of the protective layer 17 is preferably 0.005 or lower. Accordingly, the protective layer 17 can be effectively suppressed from affecting transmission/reception of radio waves by the mesh wiring layer 20. Thus, deterioration in antenna performance can be suppressed. Note that the dissipation factor of the protective layer 17 can be measured in conformance with IEC 62562, by the same method as when measuring the relative permittivity of the substrate 11. The dissipation factor of the protective layer 17 is measured in a state in which the protective layer 17 is peeled off from the substrate 11 at this time.

Acrylic resins such as polymethyl (meth)acrylate, polyethyl (meth)acrylate, and so forth, and denatured resins and copolymers thereof, polyvinyl resins such as polyester resin, polyvinyl alcohol, polyvinyl acetate, polyvinyl acetal, polyvinyl butyral, and so forth, and copolymers thereof, polyurethane resin, epoxy resin, polyamide resin, chlorinated polyolefin, and so forth, and like insulating resins that are colorless and transparent, can be used as the material of the protective layer 17.

The protective layer 17 preferably includes acrylic resin or polyester resin in particular. Accordingly, adhesion between the first-direction wiring lines 21 and the second-direction wiring lines 22, and adhesion thereof as to the substrate 11 can be further improved. Accordingly, abrasion resistance and weather resistance of the first-direction wiring lines 21 and the second-direction wiring lines 22 can be improved. Further, non-visibility can be maintained, and antenna performance can be maintained.

Further, the protective layer 17 preferably contains silicon dioxide. The silicon dioxide may be added to resin in a powder form. Alternatively, a film may be formed thereof that substantially contains no resin, by a technique such as vapor deposition, sputtering, CVD, or the like. Thus, sliding properties of the surface of the protective layer 17 and antireflection properties of the protective layer 17 can be improved.

### [Configuration of Module]

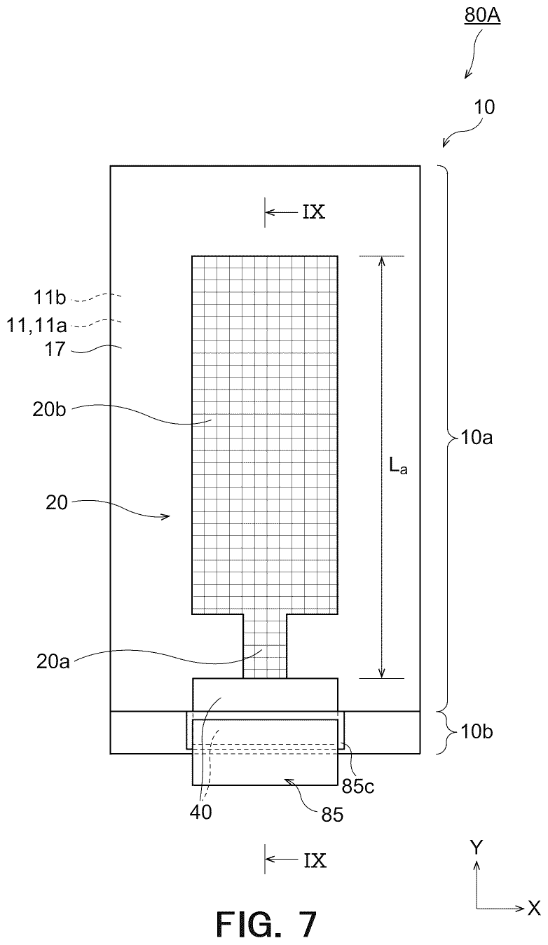

Next, a configuration of the module will be described with reference to FIG. 7 to FIG. 9. FIG. 7 to FIG. 9 are diagrams illustrating the module according to the present embodiment.

As illustrated in FIG. 7, the module 80A includes the wiring board 10 described above, and the power supply line 85 that is electrically connected to the power supply unit 40 via an anisotropic conductive film 85c. As described above, when the module 80A is assembled into the image display device 60 having the display device 61, the power supply unit 40 of the wiring board 10 is electrically connected to the communication module 63 of the image display device 60 via the power supply line 85.

The power supply line 85 has a generally rectangular shape in plan view. In this case, the width (X-direction distance) of the power supply line 85 may be generally the same as the width (X-direction distance) of the power supply unit 40. Also, the area of the power supply line 85 may be generally the same as the area of the power supply unit 40. Thus, electric resistance of the power supply line 85 and electric resistance of the power supply unit 40 can be brought close to each other. Accordingly, impedance matching can be easily performed between the power supply line 85 and the power supply unit 40, and thus deterioration in electrical connectivity between the power supply line 85 and the power supply unit 40 can be suppressed.

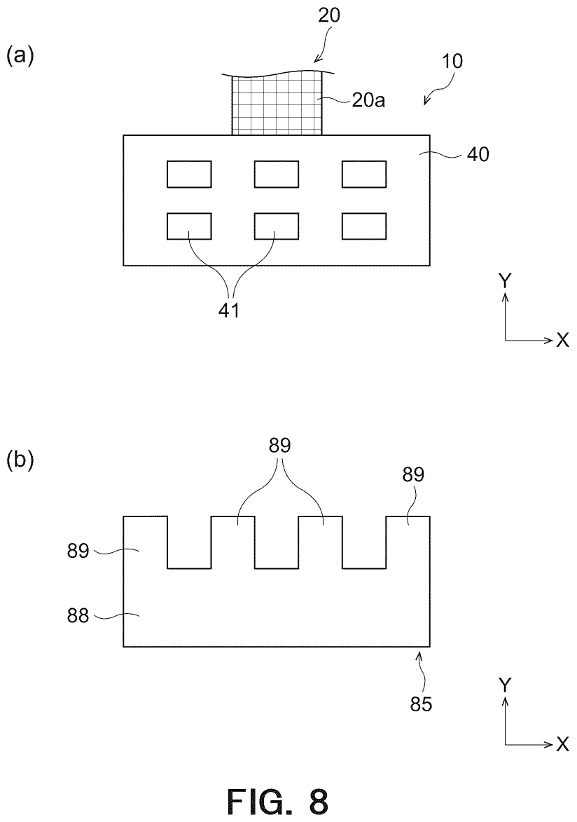

Now, through holes 41 may be formed in the power supply unit 40, as illustrated in FIG. 8 (a). In the example that is illustrated, a plurality of (six) through holes 41 are formed in the power supply unit 40. That is to say, in FIG. 8 (a), three through holes 41 are provided in the X direction, and two rows of this row having the three through holes 41 are provided in the Y direction. Note that the number of through holes 41 disposed is not limited to this. Thus, forming the through holes 41 in the power supply unit 40 enables the area of the power supply unit 40 (area of a region in which a metal portion is present) to be easily adjusted.

Also, as illustrated in FIG. 8 (b), a combtooth formation may be formed at an edge portion of the power supply line 85 on the power supply unit 40 side. That is to say, the power supply line 85 may have a main body portion 88 that has a generally rectangular shape in plan view, and a plurality of (four) protruding portions 89 protruding from the main body portion 88 toward the power supply unit 40 side (plus side in Y direction). This enables the area of the power supply line 85 to be easily adjusted. Accordingly, the area of the power supply line 85 and the area of the power supply unit 40 can be made to be generally the same. Note that the number of the protruding portions 89 may be one or more and three or less, or may be five or more.

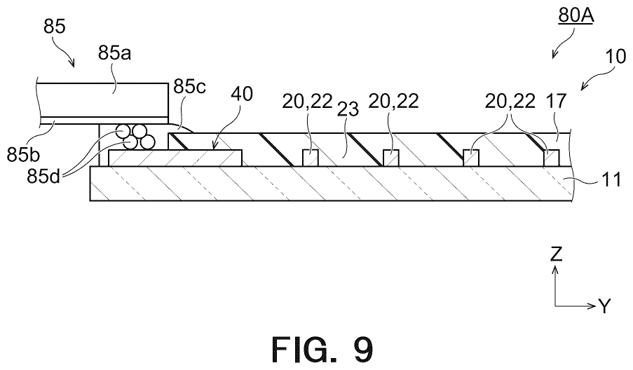

Referring to FIG. 7 again, the power supply line 85 is pressure-bonded to the wiring board 10 via the anisotropic conductive film (ACF) 85c. The anisotropic conductive film 85c contains a resin material such as acrylic resin, epoxy resin, or the like, and conductive particles 85d (see FIG. 9). The anisotropic conductive film 85c covers the region of the power supply unit 40 that is not covered by the protective layer 17. Thus, corrosion and so forth of the power supply unit 40 can be suppressed. In the present embodiment, the anisotropic conductive film 85c covers the entire region of the power supply unit 40 that is not covered by the protective layer 17.

Also, part of the anisotropic conductive film 85c is disposed over the protective layer 17, as illustrated in FIG. 9. Thus, the region of the power supply unit 40 that is not covered by the protective layer 17 can be covered by the anisotropic conductive film 85c in a sure manner, and corrosion and so forth of the power supply unit 40 can be suppressed more effectively.

The anisotropic conductive film 85c is disposed so as to face the power supply unit 40. Part of the conductive particles 85d are in contact with the power supply unit 40. Thus, the power supply line 85 is electrically connected to the power supply unit 40. Note that part of the anisotropic conductive film 85c may flow out to the surroundings of the power supply line 85 at the time of pressure-bonding of the power supply line 85 to the wiring board 10. Also, the grain size of the conductive particles 85d may be around 7 μm, for example.

The power supply line 85 may be a flexible printed board, for example. As illustrated in FIG. 9, the power supply line 85 has a base material 85a, and a metal wiring portion 85b that is layered on the base material 85a. Of these, the base material 85a may contain a resin material such as polyimide or the like, and a liquid crystal polymer, for example. Also, the metal wiring portion 85b may contain copper, for example. This metal wiring portion 85b is electrically connected to the power supply unit 40 via the conductive particles 85d.

### [Manufacturing Method of Wiring Board, Manufacturing Method of Module, and Manufacturing Method of Image Display Device Laminate]

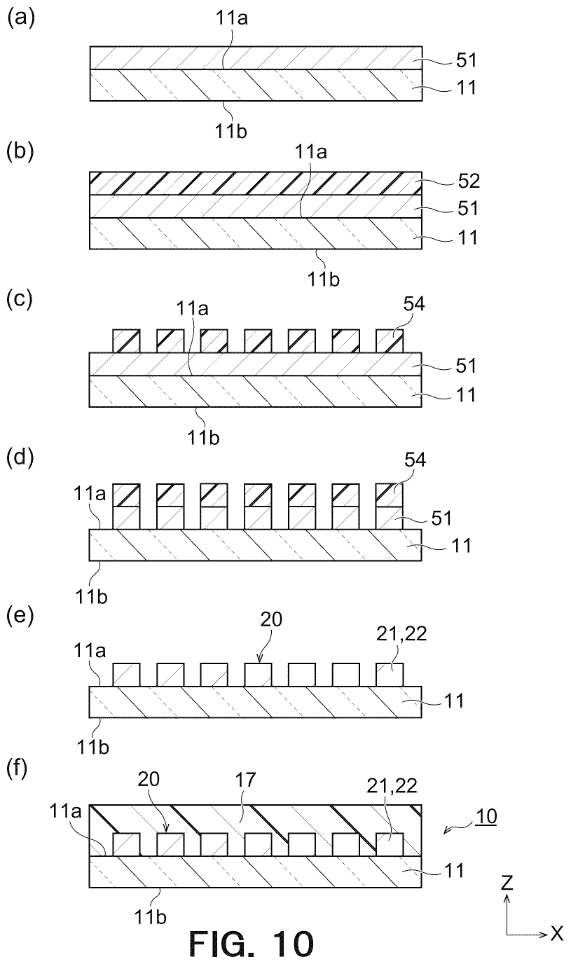

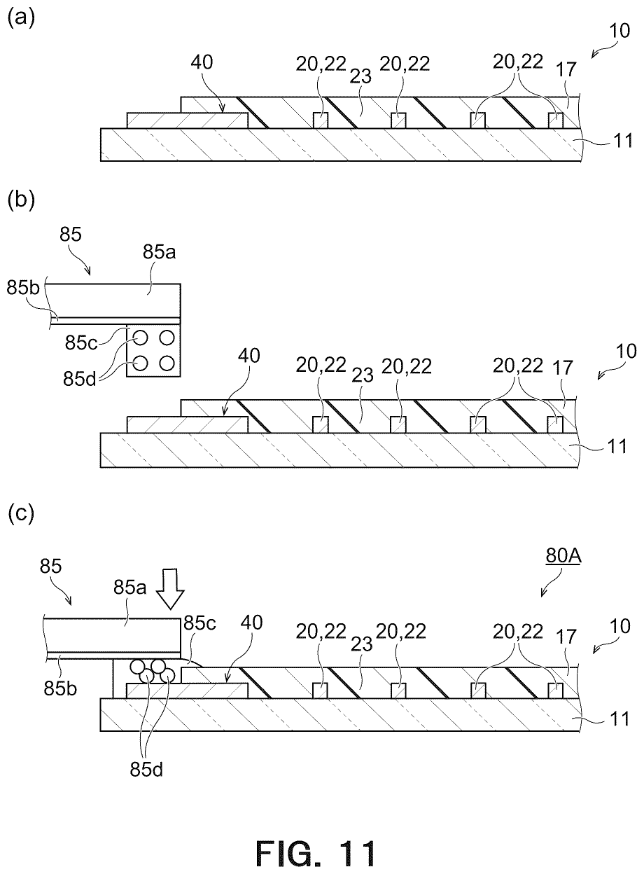

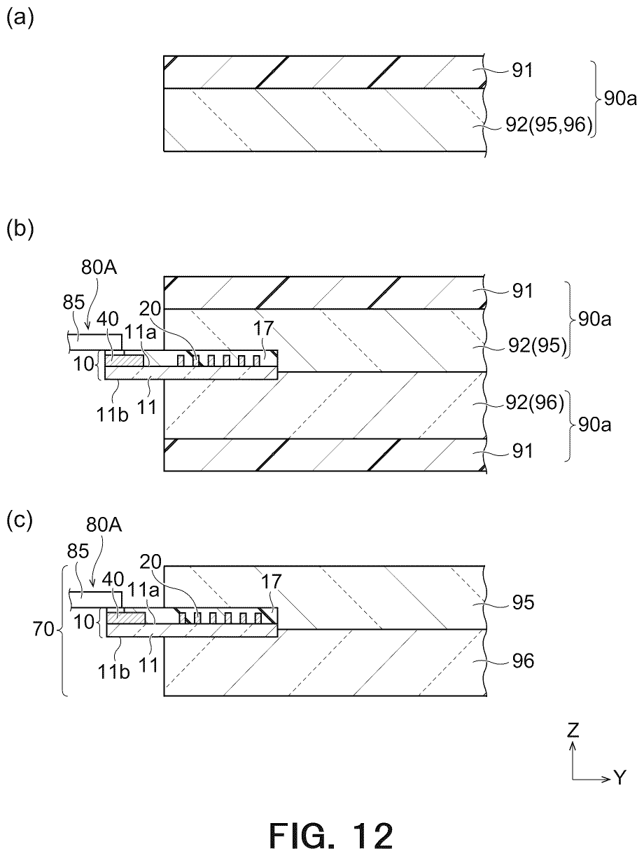

Next, a manufacturing method of the wiring board 10, a manufacturing method of the module 80A, and a manufacturing method of the image display device laminate 70, according to the present embodiment, will be described with reference to FIG. 10 (a) to (f), FIG. 11 (a) to (c), and FIG. 12 (a) to (c). FIG. 10 (a) to (f) are cross-sectional views illustrating the manufacturing method of the wiring board 10 according to the present embodiment. FIG. 11 (a) to (c) are cross-sectional views illustrating the manufacturing method of the module 80A according to the present embodiment. FIG. 12 (a) to (c) are cross-sectional views illustrating the manufacturing method of the image display device laminate 70 according to the present embodiment.

First, the manufacturing method of the wiring board according to the present embodiment will be described with reference to FIG. 10 (a) to (f).

First, the substrate 11 that has the first face 11a and the second face 11b situated on the opposite side from the first face 11a is prepared. The substrate 11 has transparency.

Next, the mesh wiring layer 20, and the power supply unit 40 that is electrically connected to the mesh wiring layer 20, are formed on the first face 11a of the substrate 11.

At this time, first, as illustrated in FIG. 10 (a), metal foil 51 is laminated on generally the entire region of the first face 11a of the substrate 11. The thickness of the metal foil 51 in the present embodiment may be 0.1 μm or more and 5.0 μm or less. The metal foil 51 in the present embodiment may contain copper.

Next, as illustrated in FIG. 10 (b), photo-curing insulating resist 52 is supplied to generally the entire region of the surface of the metal foil 51. Examples of this photo-curing insulating resist 52 include organic resins such as acrylic resins, epoxy-based resins, and so forth.

Next, as illustrated in FIG. 10 (c), an insulating layer 54 is formed by photolithography. In this case, the photo-curing insulating resist 52 is patterned by photolithography, thereby forming the insulating layer 54 (resist pattern). At this time, the insulating layer 54 is formed such that the metal foil 51 corresponding to the first-direction wiring lines 21 and the second-direction wiring lines 22 is exposed.

Next, as illustrated in FIG. 10 (d), the metal foil 51 situated at portions on the first face 11a of the substrate 11 not covered by the insulating layer 54 is removed. At this time, the metal foil 51 is etched such that the first face 11a of the substrate 11 is exposed, by performing wet processing using such as ferric chloride, cupric chloride, strong acids such as sulfuric acid, hydrochloric acid, or the like, persulfate, hydrogen peroxide, or aqueous solutions thereof, or combinations of the above, or the like.

Next, as illustrated in FIG. 10 (e), the insulating layer 54 is removed. At this time, the insulating layer 54 on the metal foil 51 is removed by performing wet processing using a permanganate solution, N-methyl-2-pyrrolidone, acid or alkali solutions, or the like, or dry processing using oxygen plasma.

Thus, the substrate 11, and the mesh wiring layer 20 provided on the first face 11a of the substrate 11, are obtained. In this case, the mesh wiring layer 20 includes the first-direction wiring lines 21 and the second-direction wiring lines 22. At this time, the power supply unit 40 may be formed from part of the metal foil. Alternatively, the power supply unit 40 that is plate-like may be separately prepared, and this power supply unit 40 may be electrically connected to the mesh wiring layer 20.

Thereafter, as illustrated in FIG. 10 (f), the protective layer 17 is formed on the first face 11a of the substrate 11, so as to cover the mesh wiring layer 20 and the power supply unit 40. The protective layer 17 is formed so as to cover only part of the power supply unit 40 (see FIG. 9). Roll coating, gravure coating, reverse gravure coating, micro-gravure coating, slot-die coating, die coating, knife coating, ink-jet coating, dispenser coating, kiss coating, spray coating, screen printing, offset printing, or flexo printing may be used as the method for forming the protective layer 17.

Thus, the wiring board 10 that has the substrate 11, the mesh wiring layer 20 disposed on the first face 11a of the substrate 11, the power supply unit 40 electrically connected to the mesh wiring layer 20, and the protective layer 17 that is disposed on the first face 11a of the substrate 11 and that covers the mesh wiring layer 20 and the power supply unit 40, is obtained.

Next, the manufacturing method of the module according to the present embodiment will be described with reference to FIG. 11 (a) to (c).

First, as illustrated in FIG. 11 (a), the wiring board 10 is prepared. At this time, the wiring board 10 is fabricated by the method illustrated in FIG. 10 (a) to (f), for example.

Next, the power supply line 85 is electrically connected to the power supply unit 40 via the anisotropic conductive film 85c including the conductive particles 85d. At this time, first, as illustrated in FIG. 11 (b), the anisotropic conductive film 85c is disposed on the wiring board 10. At this time, the anisotropic conductive film 85c is disposed so as to face the power supply unit 40.

Next, as illustrated in FIG. 11 (c), the power supply line 85 is pressure-bonded to the wiring board 10. At this time, pressure and heat are applied to the power supply line 85, thereby pressure-bonding the power supply line 85 to the wiring board 10. Part of the conductive particles 85d then come into contact with the power supply unit 40. Thus, the power supply line 85 is electrically connected to the power supply unit 40. At the time of pressure-bonding the power supply line 85 to the wiring board 10, the power supply line 85 is pressure-bonded to the wiring board 10 such that the anisotropic conductive film 85c covers the region of the power supply unit 40 that is not covered by the protective layer 17. Also, part of the anisotropic conductive film 85c is disposed on the protective layer 17 due to part of the anisotropic conductive film 85c flowing out to the surroundings of the power supply line 85.

Thus, the module 80A, which includes the wiring board 10 and the power supply line 85 electrically connected to the power supply unit 40 via the anisotropic conductive film 85c containing the conductive particles 85d, is obtained.

Next, the manufacturing method of the image display device laminate 70 according to the present embodiment will be described with reference to FIG. 12 (a) to (c).

Next, the first transparent adhesive layer 95, the wiring board 10 of the module 80A, and the second transparent adhesive layer 96 are laminated on each other. At this time, first, as illustrated in FIG. 12 (a), an OCA sheet 90a is prepared that includes, for example, a release film 91 of polyethylene terephthalate (PET), and an OCA layer 92 (first transparent adhesive layer 95 or second transparent adhesive layer 96) laminated on the release film 91. At this time, the OCA layer 92 may be a layer obtained by coating a curable adhesive layer composition that is in a liquid state and that includes a polymerizable compound, on the releasing film 91, and cured by using ultraviolet rays (UV) or the like, for example. This curable adhesive layer composition contains a polar-group-containing monomer.

Next, as illustrated in FIG. 12 (b), the OCA layers 92 of the OCA sheets 90a are applied to the wiring board 10. The wiring board 10 is thus interposed between the OCA layers 92.

Thereafter, as illustrated in FIG. 12 (c), the release films 91 are removed by separation from the OCA layers 92 of the OCA sheets 90a applied to the wiring board 10, thereby obtaining the first transparent adhesive layer 95 (OCA layer 92), the wiring board 10, and the second transparent adhesive layer 96 (OCA layer 92), which are laminated on each other.

Thus, the image display device laminate 70 including the module 80A that includes the first transparent adhesive layer 95, the second transparent adhesive layer 96, and the wiring board 10, is obtained.

Thereafter, the display device 61 is laminated on the image display device laminate 70, thereby obtaining the image display device 60 including the image display device laminate 70 and the display device 61 laminated on the image display device laminate 70.

### Effects of Present Embodiment

Next, the effects of the present embodiment having such a configuration will be described.

As illustrated in FIG. 1 and FIG. 2, the wiring board 10 is assembled into the image display device 60 that has the display device 61. At this time, the wiring board 10 is disposed above the display device 61. The mesh wiring layer 20 of the wiring board 10 is electrically connected to the communication module 63 of the image display device 60 via the power supply unit 40 and the power supply line 85. In this way, radio waves of the predetermined frequency can be transmitted/received via the mesh wiring layer 20, and communication can be performed by using the image display device 60.

According to the present embodiment, the protective layer 17 covers only part of the power supply unit 40, and the anisotropic conductive film 85c covers the region of the power supply unit 40 that is not covered by the protective layer 17. Accordingly, deterioration in electrical connectivity between the power supply line 85 and the power supply unit 40 can be suppressed, and also corrosion and the like of the power supply unit 40 can be suppressed.

Also, according to the present embodiment, the wiring board 10 includes the substrate 11, and the mesh wiring layer 20 disposed on the substrate 11. Also, the substrate 11 has transparency. Further, the mesh wiring layer 20 has a mesh-like pattern made up of a conductor portion serving as a formation portion of a non-transparent conductor layer, and a great number of openings. Accordingly, the transparency of the wiring board 10 is secured. Thus, when the wiring board 10 is disposed over the display device 61, the display device 61 can be visually recognized from the openings 23 of the mesh wiring layer 20, and visual recognition of the display device 61 is not impeded.

Further, according to the present embodiment, part of the anisotropic conductive film 85c is disposed on the protective layer 17. Accordingly, the anisotropic conductive film 85c can cover the region of the power supply unit 40 that is not covered by the protective layer 17 in a sure manner, and corrosion and so forth of the power supply unit 40 can be suppressed more effectively.

### [Modifications]

Next, modifications of the module will be described.

### (First Modification)

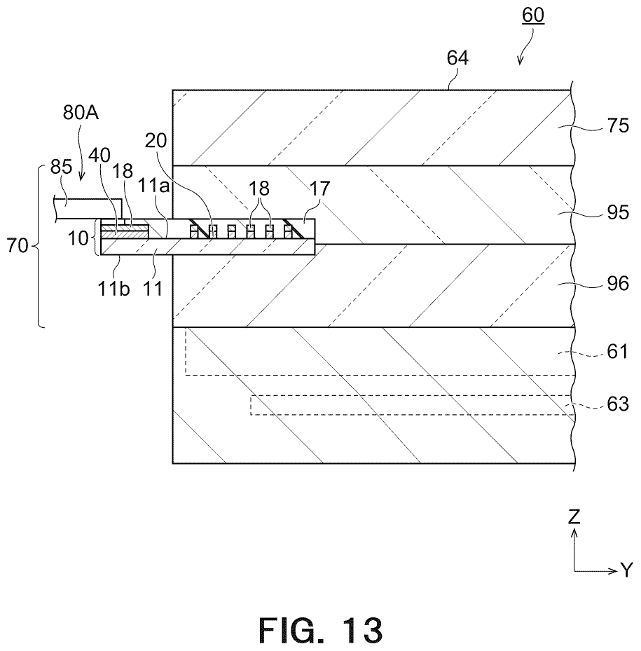

FIG. 13 illustrates a first modification of the module. The modification illustrated in FIG. 13 differs with respect to the point that the wiring board 10 further has a dark layer 18 provided on the mesh wiring layer 20, and other configurations are generally the same as those of the embodiment illustrated in FIG. 1 to FIG. 12 described above. In FIG. 13, portions that are the same as in the embodiment illustrated in FIG. 1 to FIG. 12 are denoted by the same symbols, and detailed description will be omitted.

In the module 80A illustrated in FIG. 13, the dark layer (blackened layer) 18 is formed on the mesh wiring layer 20 of the wiring board 10. This dark layer 18 is a layer for making the mesh wiring layer 20 difficult to visually recognize by the bare eye, by suppressing reflection of visible light at the mesh wiring layer 20. As illustrated in FIG. 13, the dark layer 18 covers the entire region of the mesh wiring layer 20 and the entire region of the power supply unit 40. Also, the dark layer 18 is covered by the protective layer 17.

It is sufficient for the dark layer 18 to be a layer that has a lower reflective index with respect to visible light than that of the protective layer 17, for example, and may be a layer of a dark color such as black or the like, for example. The dark layer 18 may also be a layer of which the surface thereof has been roughened.

The dark layer 18 may be formed from a part making up the mesh wiring layer 20 or the power supply unit 40, by subjecting part of the metal material making up the mesh wiring layer 20 or the power supply unit 40 to darkening processing (blackening processing), for example. In this case, the dark layer 18 may be formed as a layer made up of a metal oxide or a metal sulfide. Also, the dark layer 18 may be formed on the surface of the mesh wiring layer 20 or the power supply unit 40 as a coated film of dark material, or a plated layer of nickel, chromium, or the like. Further, the dark layer 18 may be formed by roughening the surface of the mesh wiring layer 20 or the power supply unit 40.

According to the present modification, the wiring board 10 further has the dark layer 18 provided on the mesh wiring layer 20. Accordingly, reflection of visible light at the mesh wiring layer 20 can be suppressed, and the mesh wiring layer 20 can be made to be even more difficult to visually recognize by the bare eye.

Also, in the present modification as well, the protective layer 17 covers only part of the power supply unit 40, and the anisotropic conductive film 85c (see FIG. 9) covers the region of the power supply unit 40 that is not covered by the protective layer 17. Accordingly, deterioration in electrical connectivity between the power supply line 85 and the power supply unit 40 can be suppressed, and also corrosion and the like of the power supply unit 40 can be suppressed. Now, in a case of forming the dark layer 18 on the power supply unit 40 to suppress reflection of visible light at the mesh wiring layer 20, corrosion resistance of the power supply unit 40 can decrease. Conversely, according to the present modification, corrosion and the like of the power supply unit 40 can be suppressed, as described above. Thus, according to the present modification, reflection of visible light at the mesh wiring layer 20 can be suppressed while also suppressing corrosion and the like of the power supply unit 40.

### (Second Modification)

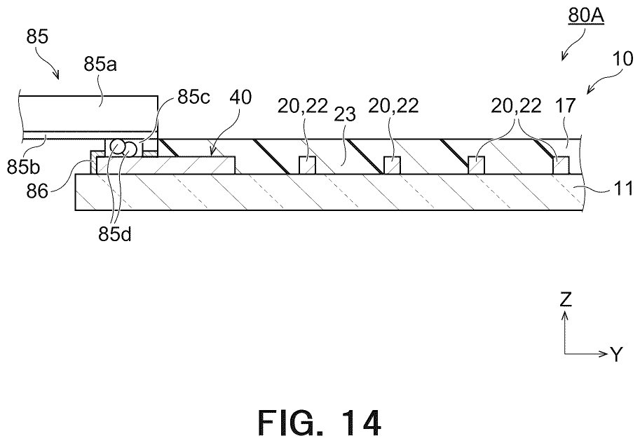

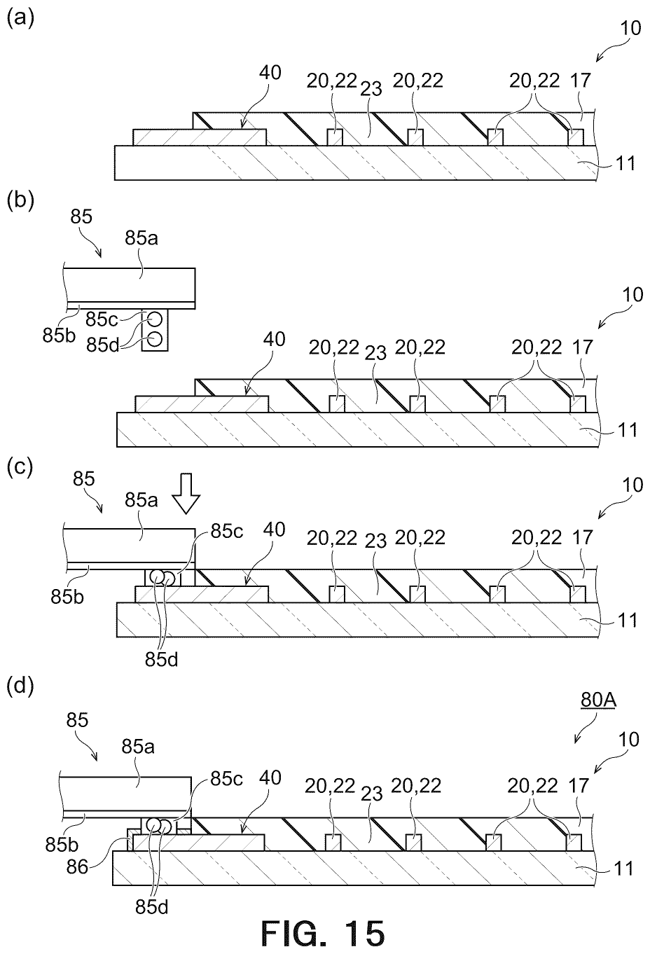

FIG. 14 and FIG. 15 illustrate a second modification of the module. The modification illustrated in FIG. 14 and FIG. 15 differs with respect to the point that the anisotropic conductive film 85c covers only part of the region of the power supply unit 40 that is not covered by the protective layer 17, and other configurations are generally the same as those of the embodiment illustrated in FIG. 1 to FIG. 13 described above. In FIG. 14 and FIG. 15, portions that are the same as in the embodiment illustrated in FIG. 1 to FIG. 13 are denoted by the same symbols, and detailed description will be omitted.

In the module 80A illustrated in FIG. 14, the anisotropic conductive film 85c covers only part of the region of the power supply unit 40 that is not covered by the protective layer 17. The region of the power supply unit 40 that is covered by neither the protective layer 17 nor the anisotropic conductive film 85c is covered by a covering layer 86 containing a material that has corrosion-resistant properties. In this case, metals such as gold or the like, or resins such as epoxy resin, imide resin, acrylic resin, or the like, can be used as the material of the covering layer 86.

Next, a manufacturing method of the module according to the present modification will be described with reference to FIG. 15 (a) to (d).

First, as illustrated in FIG. 15 (a), the wiring board 10 is prepared. At this time, the wiring board 10 is fabricated by the method illustrated in FIG. 10 (a) to (f), for example.

Next, the power supply line 85 is pressure-bonded to the wiring board 10 via the anisotropic conductive film 85c containing the conductive particles 85d. In doing so, as illustrated in FIG. 15 (b), the anisotropic conductive film 85c is first disposed over the wiring board 10. At this time, the anisotropic conductive film 85c is disposed so as to face the power supply unit 40.

Next, as illustrated in FIG. 15 (c), the power supply line 85 is pressure-bonded to the wiring board 10. At this time, the power supply line 85 is pressure-bonded to the wiring board 10 such that the anisotropic conductive film 85c covers only part of the region of the power supply unit 40 not covered by the protective layer 17.

Next, as illustrated in FIG. 15 (d), the covering layer 86 is formed in the region of the power supply unit 40 that is covered by neither the protective layer 17 nor the anisotropic conductive film 85c, so as to cover the power supply unit 40. In doing so, the covering layer 86 may be formed by plating, and the metal used for making up the covering layer 86 may be gold, for example.

Thus, the module 80A, which includes the wiring board 10 and the power supply line 85 electrically connected to the power supply unit 40 via the anisotropic conductive film 85c containing the conductive particles 85d, is obtained.

According to the present modification, the region of the power supply unit 40 that is covered by neither the protective layer 17 nor the anisotropic conductive film 85c is covered by the covering layer 86 that contains a material having corrosion-resistant properties. In this case as well, deterioration in electrical connectivity between the power supply line 85 and the power supply unit 40 can be suppressed, and also corrosion and the like of the power supply unit 40 can be suppressed.

### (Third Modification)

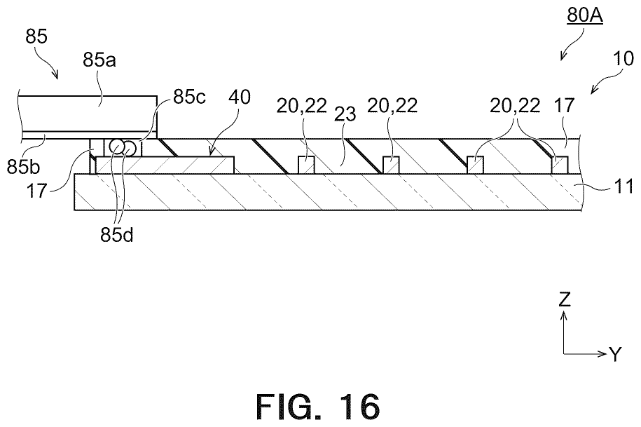

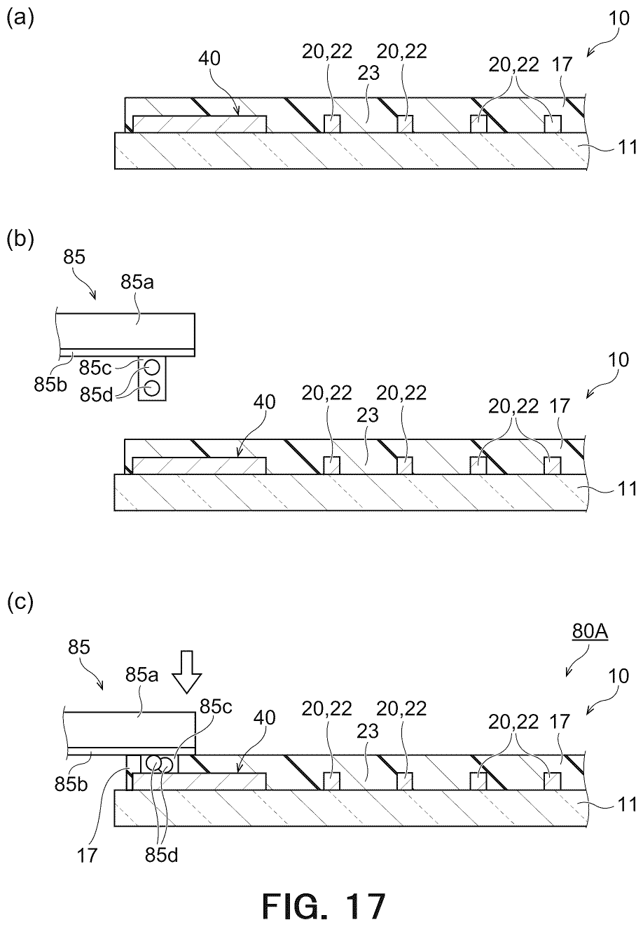

FIG. 16 and FIG. 17 illustrate a third modification of the module. The modification illustrated in FIG. 16 and FIG. 17 differs with respect to the point that the conductive particles 85d have entered into the protective layer 17, and other configurations are generally the same as those of the embodiment illustrated in FIG. 1 to FIG. 15 described above. In FIG. 16 and FIG. 17, portions that are the same as in the embodiment illustrated in FIG. 1 to FIG. 15 are denoted by the same symbols, and detailed description will be omitted.

In the module 80A illustrated in FIG. 16, the conductive particles 85d have entered into the protective layer 17. The power supply line 85 is thus electrically connected to the power supply unit 40, due to the conductive particles 85d entering into the protective layer 17. That is to say, at the time of pressure-bonding the power supply line 85 to the wiring board 10, the conductive particles 85d of the anisotropic conductive film 85c penetrate the surface of the protective layer 17, and enter into the protective layer 17. Part of the conductive particles 85d are thereby in contact with the power supply unit 40. Thus, the power supply line 85 is electrically connected to the power supply unit 40 due to the conductive particles 85d entering into the protective layer 17.

Pencil hardness of the surface of the protective layer 17 is preferably B or higher and 2H or lower in the present modification. Due to the pencil hardness of the surface of the protective layer 17 being B or higher, abrasion resistance and weather resistance of the protective layer 17 can be improved. Also, due to the pencil hardness of the surface of the protective layer 17 being 2H or lower, the conductive particles 85d of the anisotropic conductive film (ACF) 85c can enter into the protective layer 17 more readily, and electrical connectivity between the power supply unit 40 and the power supply line 85 can be improved. Note that the pencil hardness can be measured conforming to the pencil hardness test stipulated by JIS K5600-5-4:1999.

Also, as described above, the thickness T₆ (see FIG. 6) of the protective layer 17 may be 4.0 μm or more and 8.0 μm or less. Due to the thickness T₆ of the protective layer 17 being 8.0 μm or less, the conductive particles 85d come into contact with the power supply unit 40 more readily when the conductive particles 85d of the anisotropic conductive film (ACF) 85c enter into the protective layer 17. Thus, electrical connection between the power supply unit 40 and the power supply line 85 can be secured.

Next, a manufacturing method of the module according to the present modification will be described with reference to FIG. 17 (a) to (c).

First, as illustrated in FIG. 17 (a), the wiring board 10 is prepared. At this time, the wiring board 10 is fabricated by the method illustrated in FIG. 10 (a) to (f), for example. Now, in the present modification, the protective layer 17 may be formed to cover the entire region of the power supply unit 40 (see FIG. 17 (a)).

Next, the power supply line 85 is pressure-bonded to the wiring board 10 via the anisotropic conductive film 85c containing the conductive particles 85d. In doing so, as illustrated in FIG. 17 (b), the anisotropic conductive film 85c is first disposed over the wiring board 10. At this time, the anisotropic conductive film 85c is disposed so as to face the power supply unit 40.

Next, as illustrated in FIG. 17 (c), the power supply line 85 is pressure-bonded to the wiring board 10. At this time, the conductive particles 85d of the anisotropic conductive film 85c penetrate the surface of the protective layer 17 and enter into the protective layer 17. Part of the conductive particles 85d then come into contact with the power supply unit 40. Due to the conductive particles 85d entering into the protective layer 17 in this way, the power supply line 85 is electrically connected to the power supply unit 40.

Thus, the module 80A, which includes the wiring board 10 and the power supply line 85 electrically connected to the power supply unit 40 via the anisotropic conductive film 85c containing the conductive particles 85d, is obtained.

According to the present modification, the power supply line 85 is electrically connected to the power supply unit 40 by the conductive particles 85d entering into the protective layer 17. In this case as well, deterioration in electrical connectivity between the power supply line 85 and the power supply unit 40 can be suppressed, and also corrosion and the like of the power supply unit 40 can be suppressed.

Next, modifications of the wiring board will be described.

### (First Modification)

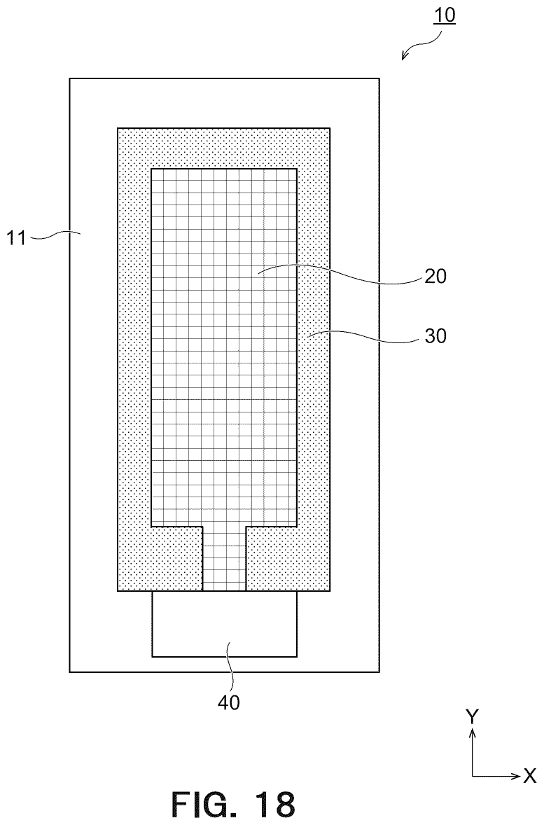

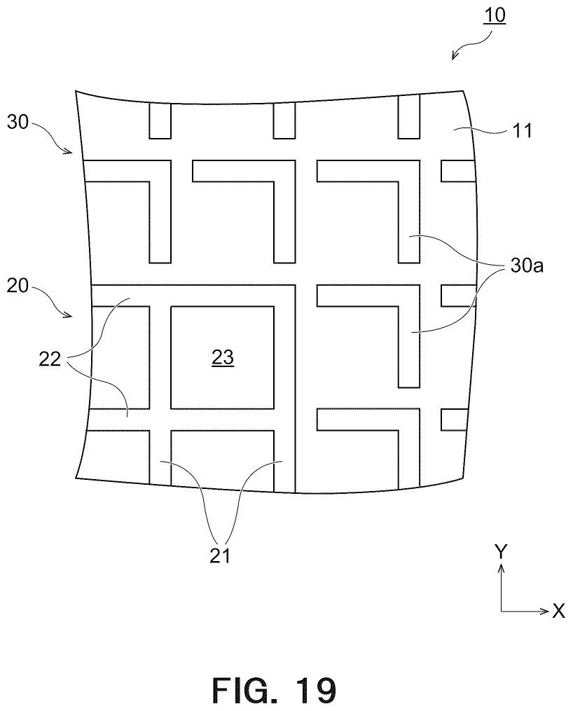

FIG. 18 and FIG. 19 illustrate a first modification of the wiring board. The modification illustrated in FIG. 18 and FIG. 19 differs with respect to the point of a dummy wiring layer 30 being provided around the mesh wiring layer 20, and other configurations are generally the same as the form described above, which is illustrated in FIG. 1 to FIG. 17. In FIG. 18 and FIG. 19, portions that are the same as in the form illustrated in FIG. 1 to FIG. 17 are denoted by the same signs, and detailed description will be omitted.

In the wiring board 10 illustrated in FIG. 18, the dummy wiring layer 30 is provided so as to follow around the mesh wiring layer 20. Unlike the mesh wiring layer 20, this dummy wiring layer 30 does not substantially function as an antenna.

As illustrated in FIG. 19, the dummy wiring layer 30 is made up of a repetition of dummy wiring lines 30a having a predetermined unit pattern shape. That is to say, the dummy wiring layer 30 includes a plurality of the dummy wiring lines 30a of the same shape, and each dummy wiring line 30a is electrically isolated from each of the mesh wiring layers 20 (first-direction wiring lines 21 and second-direction wiring lines 22). In other words, each dummy wiring line 30a is separated from the respective mesh wiring layers 20 in a horizontal direction. Also, the plurality of dummy wiring lines 30a are regularly disposed over the entire region within the dummy wiring layer 30. The plurality of dummy wiring lines 30a are distanced from each other in a planar direction, and are also disposed so as to protrude on the substrate 11. That is to say, each dummy wiring line 30a is electrically isolated from the mesh wiring layer 20, the power supply unit 40, and other dummy wiring lines 30a. The dummy wiring lines 30a are each generally L-shaped in plan view.

In this case, the dummy wiring lines 30a have a shape in which part of the unit pattern shape of the mesh wiring layer 20 described above is missing. Thus, difference between the mesh wiring layer 20 and the dummy wiring layer 30 can be made to be difficult to visually recognize, and the mesh wiring layer 20 disposed on the substrate 11 can be made to be difficult to see. An aperture ratio of the dummy wiring layer 30 may be the same as the aperture ratio of the mesh wiring layer 20, or may be different, but preferably is near the aperture ratio of the mesh wiring layer 20.

Thus, by disposing the dummy wiring layer 30 that is electrically isolated from the mesh wiring layer 20 around the mesh wiring layer 20, an outer edge of the mesh wiring layer 20 can be made obscure. Accordingly, the mesh wiring layer 20 can be made to be difficult to see on the front face of the image display device 60, and the mesh wiring layer 20 can be made to be difficult to visually recognize by the bare eye of the user of the image display device 60.

### (Second Modification)

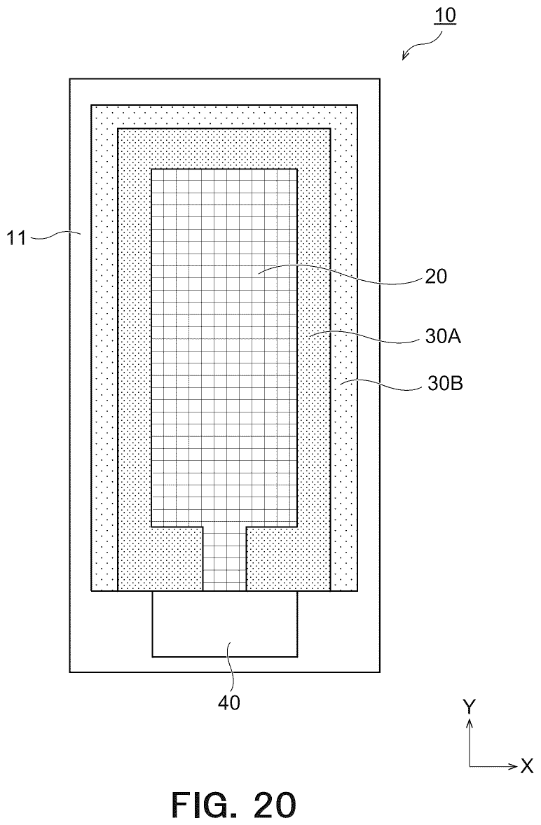

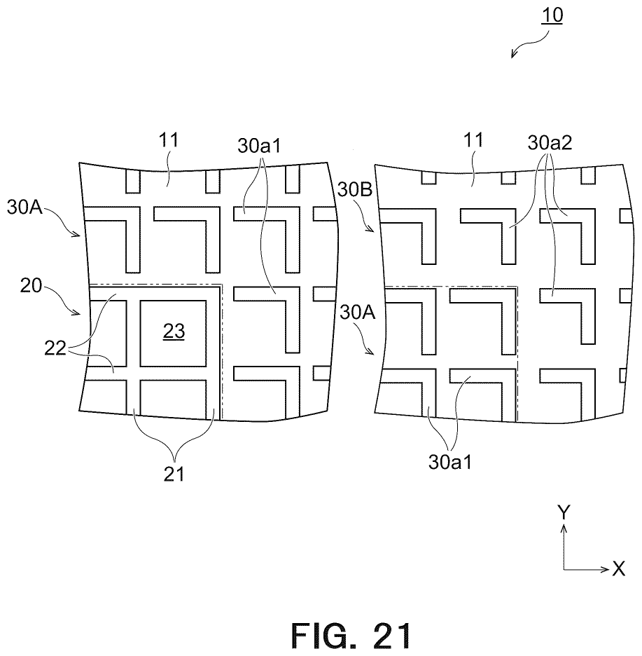

FIG. 20 and FIG. 21 illustrate a second modification of the wiring board. The modification illustrated in FIG. 20 and FIG. 21 differs with respect to the point that a plurality of dummy wiring layers 30A and 30B that have different aperture ratios from each other are provided around the mesh wiring layer 20, and other configurations are generally the same as the forms illustrated in FIG. 1 to FIG. 19 described above. In FIG. 20 and FIG. 21, portions that are the same as in the forms illustrated in FIG. 1 to FIG. 19 are denoted by the same signs, and detailed description will be omitted.

In the wiring board 10 illustrated in FIG. 20, the plurality of (two in this case) dummy wiring layers 30A and 30B (first dummy wiring layer 30A and second dummy wiring layer 30B) that have different aperture ratios from each other are provided so as to follow around the mesh wiring layer 20. Specifically, the first dummy wiring layer 30A is disposed so as to follow around the mesh wiring layer 20, and the second dummy wiring layer 30B is disposed so as to follow around the first dummy wiring layer 30A. Unlike the mesh wiring layer 20, these dummy wiring layers 30A and 30B do not substantially function as an antenna.

As illustrated in FIG. 21, the first dummy wiring layer 30A is made up of a repetition of dummy wiring lines 30a1 that have a predetermined unit pattern form. Also, the second dummy wiring layer 30B is made up of a repetition of dummy wiring lines 30a2 that have a predetermined unit pattern form. That is to say, the dummy wiring layers 30A and 30B include a plurality of the dummy wiring lines 30a1 and 30a2 of the same shapes, respectively, and each of the dummy wiring lines 30a1 and 30a2 is electrically isolated from the mesh wiring layer 20. Also, each of the dummy wiring lines 30a1 and 30a2 is regularly disposed within the entire region of the respective dummy wiring layers 30A and 30B. The dummy wiring lines 30a1 and 30a2 are each distanced from each other in the planar direction, and are also disposed so as to protrude on the substrate 11. The dummy wiring lines 30a1 and 30a2 are each electrically isolated from the mesh wiring layer 20, the power supply unit 40, and other dummy wiring lines 30a1 and 30a2. Also, the dummy wiring lines 30a1 and 30a2 are each generally L-shaped in plan view.

In this case, the dummy wiring lines 30a1 and 30a2 have shapes in which part of the unit pattern shape of the mesh wiring layer 20 described above is missing. Thus, difference between the mesh wiring layer 20 and the first dummy wiring layer 30A, and difference between the first dummy wiring layer 30A and the second dummy wiring layer 30B can be made to be difficult to visually recognize, and the mesh wiring layer 20 disposed on the substrate 11 can be made to be difficult to see. The aperture ratio of the first dummy wiring layer 30A is larger than the aperture ratio of the mesh wiring layer 20, and the aperture ratio of the first dummy wiring layer 30A is larger than the aperture ratio of the second dummy wiring layer 30B.

Note that the area of each dummy wiring line 30a1 of the first dummy wiring layer 30A is greater than the area of each dummy wiring line 30a2 of the second dummy wiring layer 30B. In this case, the line width of each dummy wiring line 30a1 is the same as the line width of each dummy wiring line 30a2, but this is not restrictive, and the line width of each dummy wiring line 30a1 may be wider than the line width of each dummy wiring line 30a2. Also, three or more dummy wiring layers with aperture ratios different from each other may be provided. In this case, the aperture ratio of each dummy wiring layer preferably gradually increases from those close to the mesh wiring layer 20 toward those far away.

Thus, by disposing the dummy wiring layers 30A and 30B that are electrically isolated from the mesh wiring layer 20, the outer edge of the mesh wiring layer 20 can be made obscure. Accordingly, the mesh wiring layer 20 can be made to be difficult to see on the front face of the image display device 60, and the mesh wiring layer 20 can be made to be difficult to visually recognize by the bare eye of the user of the image display device 60.

### (Third Modification)

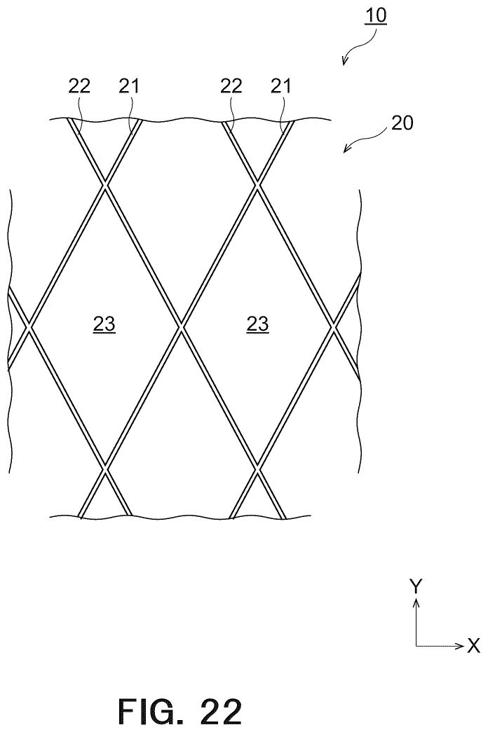

FIG. 22 illustrates a third modification of the wiring board. The modification illustrated in FIG. 22 differs in the planar form of the mesh wiring layer 20, and other configurations are generally the same as the forms illustrated in FIG. 1 to FIG. 21 described above. In FIG. 22, portions that are the same as in the forms illustrated in FIG. 1 to FIG. 21 are denoted by the same signs, and detailed description will be omitted.

FIG. 22 is an enlarged plan view illustrating the mesh wiring layer 20 according to a modification. FIG. 22, the first-direction wiring lines 21 and the second-direction wiring lines 22 intersect obliquely (non-orthogonally), and each opening 23 is formed as a rhombus shape in plan view. The first-direction wiring lines 21 and the second-direction wiring lines 22 are each not parallel to either of the X direction and the Y direction, but one of the first-direction wiring lines 21 and the second-direction wiring lines 22 may be parallel to the X direction or the Y direction.

### Second Embodiment

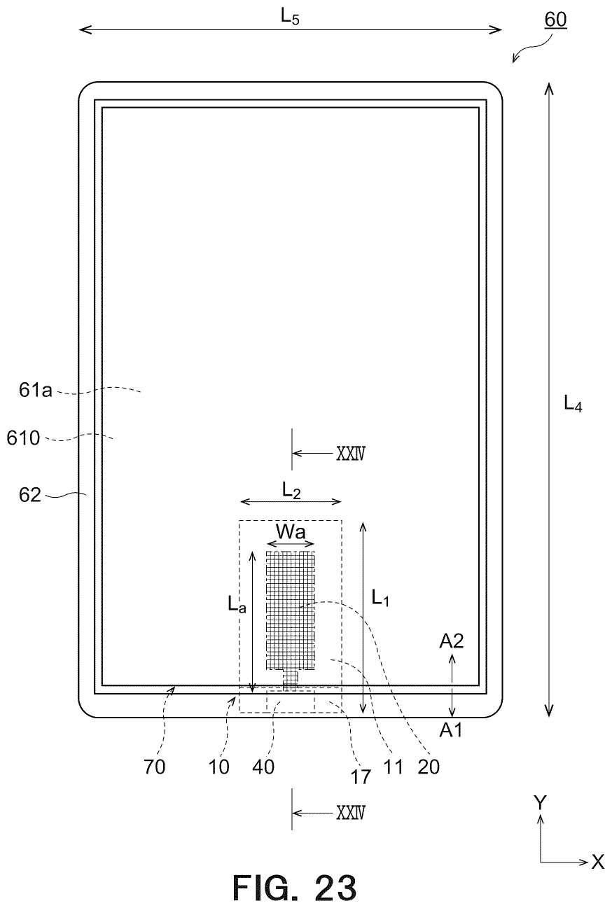

Next, a second embodiment will be described with reference to FIG. 23 to FIG. 30. FIG. 23 to FIG. 30 are diagrams illustrating the present embodiment. In FIG. 23 to FIG. 30, portions that are the same as those of the first embodiment illustrated in FIG. 1 to FIG. 22 may be denoted by the same symbols, and detailed description omitted.

### [Configuration of Image Display Device]

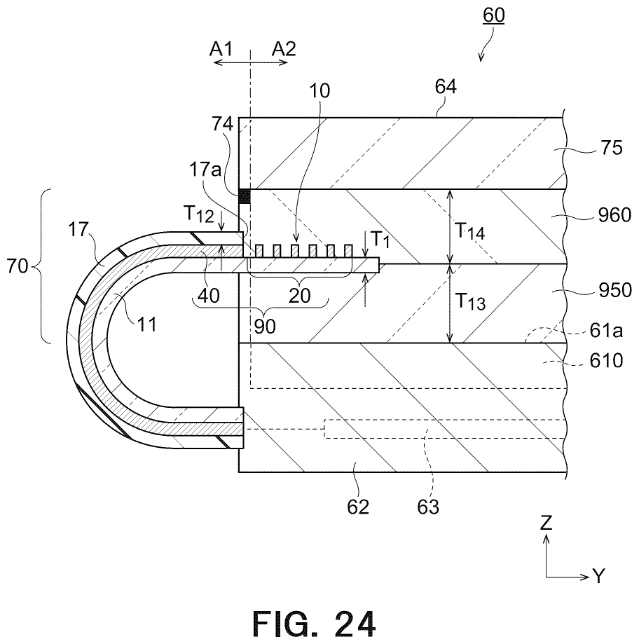

A configuration of the image display device according to the present embodiment will be described with reference to FIG. 23 and FIG. 24.

As illustrated in FIG. 23 and FIG. 24, the image display device 60 according to the present embodiment includes the image display device laminate 70, and a display unit (display) 610 that is laminated on the image display device laminate 70 and that has a display region 61a. Of these, the image display device laminate 70 includes a third adhesive layer 950, a fourth adhesive layer 960, and the wiring board 10 situated between the third adhesive layer 950 and the fourth adhesive layer 960. Also, the communication module 63 is disposed on the minus side of the display unit 610 in the Z direction. The image display device laminate 70, the display unit 610, and the communication module 63 are accommodated in the housing 62.

The wiring board 10 includes the substrate 11 that has transparency, a metal layer 90, and the protective layer 17. The metal layer 90 is disposed on the substrate 11. The metal layer 90 has the mesh wiring layer 20, and the power supply unit 40 that is electrically connected to the mesh wiring layer 20. The protective layer 17 covers part of the metal layer 90. That is to say, part of the metal layer 90 is not covered by the protective layer 17. In other words, the metal layer 90 includes a portion that is not covered by the protective layer 17. The protective layer 17 is present in at least part of a first region A1, and is not present in a second region A2. The first region A1 is a region that does not overlap the display region 61a of the image display device 60. Also, the second region A2 is a region that overlaps the display region 61a of the image display device 60.

As illustrated in FIG. 24, the image display device 60 has the light-emitting face 64. The wiring board 10 is situated on the light-emitting face 64 side (plus side in Z direction) as to the display unit 610. The communication module 63 is situated on the opposite side (minus side in Z direction) from the light-emitting face 64 as to the display unit 610.

The display unit 610 is made up of an organic EL (Electro Luminescence) display device, for example. The display unit 610 has the display region 61a on the wiring board 10 side. The display region 61a is a region of the surface of the display unit 610 that corresponds to the screen for displaying images and so forth. The display unit 610 may include a metal layer, a support base material, a resin base material, a thin-film transistor (TFT), and an organic EL layer, which are not illustrated, for example. A touch sensor that is not illustrated may be disposed on the display unit 610. Also, the wiring board 10 is disposed above the display unit 610, with the third adhesive layer 950 interposed therebetween. Note that the display unit 610 is not limited to an organic EL display device. For example, the display unit 610 may be some other display device that has functions of emitting light of itself, or may be a micro LED display device that includes micro LED elements (light emitters). Also, the display unit 610 may be a liquid crystal display device that includes liquid crystal. The cover glass (surface protection plate) 75 is disposed over the wiring board 10, with the fourth adhesive layer 960 interposed therebetween. A decorative film 74 is disposed between the fourth adhesive layer 960 and the cover glass 75. The decorative film 74 may define a boundary between the second region A2 and the first region A1. That is to say, an inner periphery of the decorative film 74 may be situated on the above boundary. Note that a polarization plate that is not illustrated may be disposed between the fourth adhesive layer 960 and the cover glass 75.

The third adhesive layer 950 is an adhesive layer that directly or indirectly bonds the display unit 610 to the wiring board 10. The third adhesive layer 950 has optical transparency. The third adhesive layer 950 has a greater area than the substrate 11 of the wiring board 10. Transmittance of visible light rays of the third adhesive layer 950 may be 85% or more, and preferably is 90% or more. Note that there is no upper limit in particular for the transmittance of visible light rays of the third adhesive layer 950, but this may be, for example, 100% or less. Note that the term visible light rays refers to light rays having a wavelength of 400 nm or higher and 700 nm or lower. Also, the term transmittance of visible light rays of 85% or more means that transmittance of the entire wavelength domain of 400 nm or higher and 700 nm or lower is 85% or more when light absorbance is measured for the third adhesive layer 950 using a known spectrophotometer (e.g., spectroscope: V-670 manufactured by JASCO Corporation).

The third adhesive layer 950 may be an OCA (Optical Clear Adhesive) layer. The OCA layer is a layer that is fabricated as follows, for example. First, a curable adhesive layer composition that is in a liquid state and that includes a polymerizable compound is coated on a releasing film of polyethylene terephthalate (PET) or the like. Next, the curable adhesive layer composition is cured by using ultraviolet rays (UV) or the like, for example, thereby obtaining an OCA sheet. This OCA sheet is applied to an object, following which the releasing film is removed by separation, thereby obtaining the OCA layer. The material of the third adhesive layer 950 may be an acrylic-based resin, a silicone-based resin, a urethane-based resin, or the like.

The wiring board 10 is disposed on the light-emitting face 64 side with respect to the display unit 610, as described earlier. In this case, the wiring board 10 is situated between the third adhesive layer 950 and the fourth adhesive layer 960. More specifically, a partial region of the substrate 11 of the wiring board 10 is disposed in a partial region between the third adhesive layer 950 and the fourth adhesive layer 960. In this case, the third adhesive layer 950, the fourth adhesive layer 960, the display unit 610 and the cover glass 75 each have an area that is greater than the substrate 11 of the wiring board 10. Thus, disposing the substrate 11 of the wiring board 10 in a partial region and not the entire face of the image display device 60 in plan view enables the overall thickness of the image display device 60 to be made thinner.

The wiring board 10 has the substrate 11 that has transparency, the metal layer 90 disposed on the substrate 11, and the protective layer 17 that covers part of the metal layer 90. The metal layer 90 includes the mesh wiring layer 20 and the power supply unit 40 that is electrically connected to the mesh wiring layer 20. The power supply unit 40 is electrically connected to the communication module 63. Also, in the first region A1, part of the wiring board 10 is not disposed between the third adhesive layer 950 and the fourth adhesive layer 960, and protrudes outward (minus side in Y direction) from between the third adhesive layer 950 and the fourth adhesive layer 960. Specifically, a region of the wiring board 10 in which the power supply unit 40 is provided protrudes outward. Thus, electrical connection of the power supply unit 40 and the communication module 63 can be easily performed. On the other hand, a region of the wiring board 10 in which the mesh wiring layer 20 is provided is situated between the third adhesive layer 950 and the fourth adhesive layer 960. Note that part of the mesh wiring layer 20 may protrude outward. Also, in the first region A1, part of the wiring board 10 is curved. Note that details of the wiring board 10 will be described later.

The fourth adhesive layer 960 is an adhesive layer that directly or indirectly bonds the wiring board 10 to the cover glass 75. The fourth adhesive layer 960 has a greater area than that of the substrate 11 of the wiring board 10. The fourth adhesive layer 960 has optical transparency, in the same way as the third adhesive layer 950. Transmittance of visible light rays of the fourth adhesive layer 960 may be 85% or more, and preferably is 90% or more. There is no upper limit in particular to the transmittance of visible light rays of the fourth adhesive layer 960, but this may be, for example, 100% or less. The fourth adhesive layer 960 may be an OCA (Optical Clear Adhesive) layer. The material of the fourth adhesive layer 960 may be an acrylic-based resin, a silicone-based resin, a urethane-based resin, or the like. The fourth adhesive layer 960 may be made from the same material as the third adhesive layer 950.

Also, in FIG. 24, at least one thickness of thickness T₁₃ of the third adhesive layer 950 and thickness T₁₄ of the fourth adhesive layer 960 may be 1.5 times the thickness T₁ of the substrate 11 or more, preferably is 2.0 times thereof or more, and even more preferably is 2.5 times thereof or more. By making the thickness T₁₃ of the third adhesive layer 950 or the thickness T₁₄ of the fourth adhesive layer 960 to be sufficiently thick as to the thickness T₁ of the substrate 11 in this way, the third adhesive layer 950 or the fourth adhesive layer 960 deforms in the thickness direction in a region overlapping the substrate 11, and takes up the thickness of the substrate 11. Accordingly, stepped portions can be suppressed from being formed in the third adhesive layer 950 or the fourth adhesive layer 960 at the peripheral edge of the substrate 11, and the presence of the substrate 11 can be made to be difficult to visually recognize by the observer.

Also, at least one thickness of the thickness T₁₃ of the third adhesive layer 950 and the thickness T₁₄ of the fourth adhesive layer 960 may be 10 times the thickness T₁ of the substrate 11 or less, and preferably is five times thereof or less. Accordingly, the thickness T₁₃ of the third adhesive layer 950 or the thickness T₁₄ of the fourth adhesive layer 960 does not become excessively great, and the thickness of the overall image display device 60 can be reduced.

The thickness T₁₃ of the third adhesive layer 950 and the thickness T₁₄ of the fourth adhesive layer 960 may be the same as each other. In this case, the thickness T₁₃ of the third adhesive layer 950 and the thickness T₁₄ of the fourth adhesive layer 960 may each be 1.2 times the thickness T₁ of the substrate 11 or more, preferably 1.5 times or more, and even more preferably 2.0 times thereof or more. That is to say, the total of the thickness T₁₃ of the third adhesive layer 950 and the thickness T₁₄ of the fourth adhesive layer 960 (T₁₃+T₁₄) is three times the thickness T₁ of the substrate 11 or more. Thus, by making the total of thicknesses T₁₃ and T₁₄ of the third adhesive layer 950 and the fourth adhesive layer 960 to be sufficiently thick with respect to the thickness T₁ of the substrate 11, the third adhesive layer 950 and the fourth adhesive layer 960 deform in the thickness direction in the region overlapping the substrate 11, and take up the thickness of the substrate 11. Accordingly, stepped portions can be suppressed from being formed in the third adhesive layer 950 or the fourth adhesive layer 960 at the peripheral edge of the substrate 11, and the presence of the substrate 11 can be made to be difficult to visually recognize by the observer.

Also, in a case in which the thickness T₁₃ of the third adhesive layer 950 and the thickness T₁₄ of the fourth adhesive layer 960 are the same as each other, the thickness T₁₃ of the third adhesive layer 950 and the thickness T₁₄ of the fourth adhesive layer 960 may each be five times the thickness T₁ of the substrate 11 or less, and preferably three times thereof or less. Accordingly, the thicknesses T₁₃ and T₁₄ of both of the third adhesive layer 950 and the fourth adhesive layer 960 do not become excessively great, and the thickness of the overall image display device 60 can be reduced.

Specifically, the thickness T₁ of the substrate 11 may be 10 μm or more and 50 μm or less for example, and preferably is 15 μm or more and 25 μm or less. By making the thickness T₁ of the substrate 11 to be 10 μm or more, strength of the wiring board 10 can be maintained, so that the first-direction wiring lines 21 and the second-direction wiring lines 22 of the mesh wiring layer 20, to be described later, are not readily deformed. Also, by making the thickness T₁ of the substrate 11 to be 50 μm or less, stepped portions can be suppressed from being formed between the third adhesive layer 950 and the fourth adhesive layer 960 at the peripheral edge of the substrate 11, and the presence of the substrate 11 can be made to be difficult to visually recognize by the observer.

The thickness T₁₃ of the third adhesive layer 950 may be 15 μm or more and 500 μm or less for example, and preferably is 20 μm or more and 250 μm or less. The thickness T₁₄ of the fourth adhesive layer 960 may be 15 μm or more and 500 μm or less for example, and preferably is 20 μm or more and 250 μm or less.

As described above, the image display device laminate 70 is made up of the wiring board 10, the third adhesive layer 950, and the fourth adhesive layer 960. Such an image display device laminate 70 is also provided in the present embodiment.

The decorative film 74 is disposed on the fourth adhesive layer 960. This decorative film 74 may open at a portion corresponding to the second region A2 (display region 61a) as viewed from the observer side. The decorative film 74 shields light in the first region A1 other than the second region A2 (display region 61a). That is to say, the decorative film 74 may be disposed so as to cover the entire periphery of edge portions of the display unit 610 as viewed from the observer side.

As illustrated in FIG. 23, the image display device 60 is generally rectangular overall in plan view, the longitudinal direction thereof is parallel to the Y direction, and the lateral direction thereof is parallel to the X direction. The length L₄ of the image display device 60 in the longitudinal direction (Y direction) can be selected from a range of 20 mm or more and 500 mm or less for example, and preferably 100 mm or more and 200 mm or less. The length L₅ of the substrate 11 in the lateral direction (X direction) can be selected from a range of 20 mm or more and 500 mm or less for example, and preferably 50 mm or more and 100 mm or less. Note that the corner portions of the image display device 60 each may be rounded.

### [Configuration of Wiring Board]

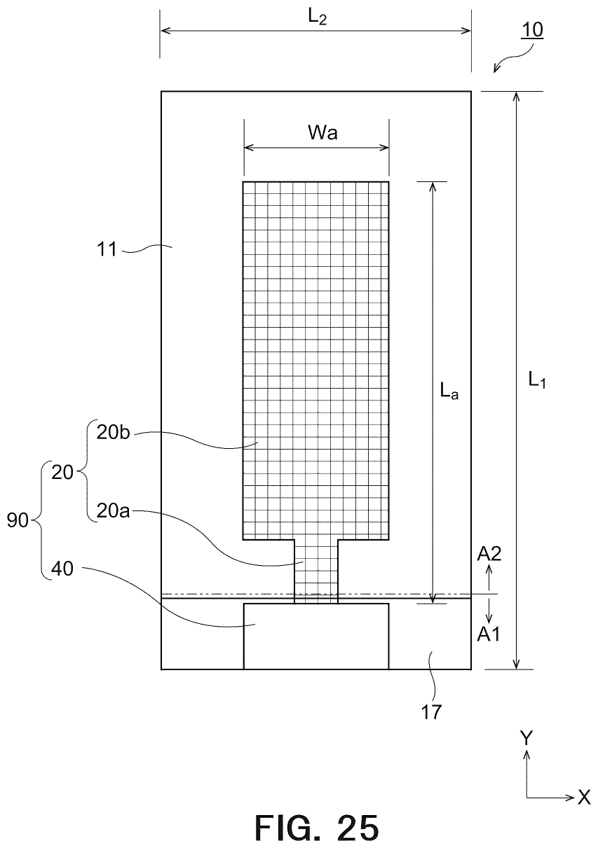

Next, a configuration of the wiring board will be described with reference to FIG. 25 to FIG. 28. FIG. 25 to FIG. 28 are diagrams illustrating the wiring board according to the present embodiment.

As illustrated in FIG. 25, the wiring board 10 according to the present embodiment is used in the image display device 60 (see FIG. 23 and FIG. 24) described above. The wiring board 10 is disposed between the third adhesive layer 950 and the fourth adhesive layer 960, closer to the light-emitting face 64 side than the display unit 610. Such a wiring board 10 includes the substrate 11 that has transparency, the metal layer 90, and the protective layer 17. The metal layer 90 is disposed on the substrate 11. The protective layer 17 covers part of the metal layer 90. Also, the metal layer 90 includes the mesh wiring layer 20 and the power supply unit 40 that is electrically connected to the mesh wiring layer 20.

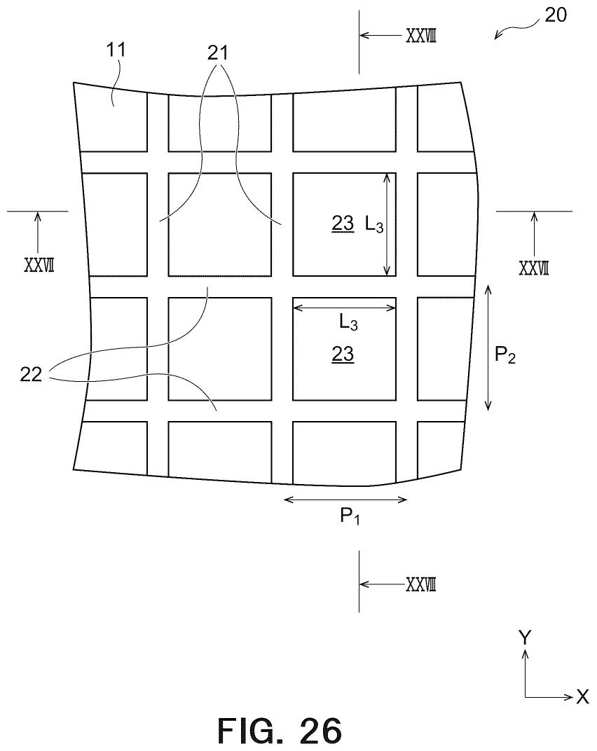

As illustrated in FIG. 26, in the present embodiment as well, the plurality of openings 23 are formed by being surrounded by the first-direction wiring lines 21 adjacent to each other and the second-direction wiring lines 22 adjacent to each other. In the present embodiment as well, the pitch P₁ of the plurality of first-direction wiring lines 21 may be in a range of 0.01 mm or more and 1 mm or less, for example. Also, the pitch P₂ of the plurality of second-direction wiring lines 22 may be in a range of 0.01 mm or more and 1 mm or less, for example. Further, the length L3 of one side of the openings 23 may be in a range of 0.01 mm or more and 1 mm or less, for example.

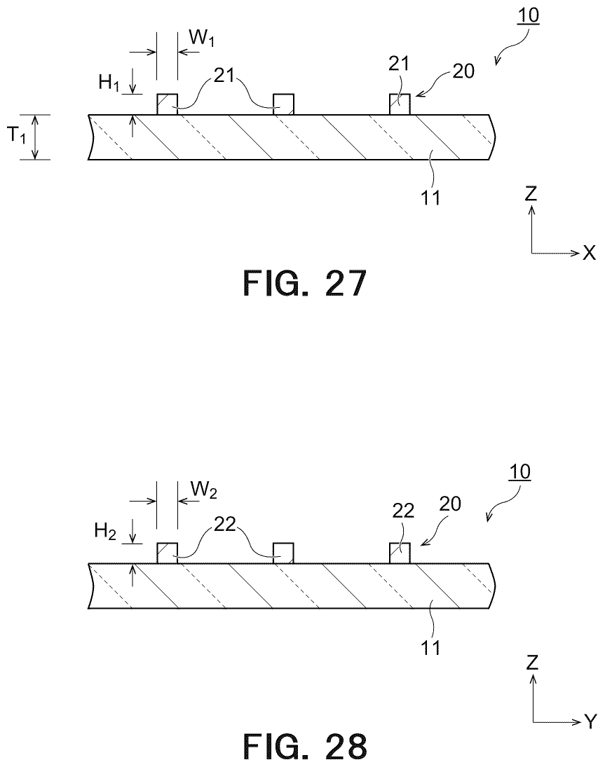

As illustrated in FIG. 27, in the present embodiment as well, the cross-section of each first-direction wiring line 21 perpendicular to the longitudinal direction (X-direction cross-section) is a generally rectangular shape or a generally square shape. Also, as illustrated in FIG. 28, in the present embodiment as well, the cross-sectional shape of each second-direction wiring line 22 perpendicular to the longitudinal direction (Y-direction cross-section) is a generally rectangular shape or a generally square shape, and is generally the same as the cross-sectional shape of the first-direction wiring lines 21 described above (X-direction cross-section).

The protective layer 17 is formed on the surface of the substrate 11, so as to cover the metal layer 90. That is to say, the protective layer 17 is formed on the wiring board 10 so as to lie over the metal layer 90 in plan view. The protective layer 17 is for protecting the metal layer 90. Specifically, the protective layer 17 covers the entire region, except for portions of the power supply unit 40 that are electrically connected. The protective layer 17 also further covers a partial region (region on power supply unit 40 side) of the mesh wiring layer 20. Note that this is not restrictive, and the protective layer 17 may cover only a partial region of the power supply unit 40. Also, the protective layer 17 does not have to cover the mesh wiring layer 20. The protective layer 17 covers the substrate 11 in regions where the metal layer 90 is not present. The protective layer 17 is formed on the entire region in the width direction (X direction) of the substrate 11, but may be formed only in a partial region of the width direction of the substrate 11.

As described above, the protective layer 17 is present in the first region A1 that does not overlap the display region 61a. The protective layer 17 is present only in the first region A1 of the wiring board 10. On the other hand, the protective layer 17 is not present in the second region A2 that overlaps the display region 61a. That is to say, the protective layer 17 is not present over the entire region of the second region A2. Now, the first region A1 is a region that does not overlap the display region 61a (non-display region) as viewed from the light-emitting face 64 side (plus side in Z direction). Also, the second region A2 is a region that overlaps the display region 61a (display region) as viewed from the light-emitting face 64 side (plus side in Z direction). An end edge 17a (see FIG. 24) that is situated on the second region A2 side (plus side in Y direction) of the protective layer 17 may overlap the decorative film 74. The end edge 17a of the protective layer 17 is situated between the third adhesive layer 950 and the fourth adhesive layer 960. However, this is not restrictive, and the end edge 17a of the protective layer 17 may be exposed outward from the third adhesive layer 950 and the fourth adhesive layer 960. Thus, due to not providing the protective layer 17 in the second region A2, the protective layer 17 is substantially not visually recognized by the bare eye of the observer, and the presence of the wiring board 10 is difficult for the observer to visually recognize.

As illustrated in FIG. 24, part of the wiring board 10 is bent outward from the third adhesive layer 950 and the fourth adhesive layer 960. Specifically, the substrate 11, the metal layer 90, and the protective layer 17 of the wiring board 10 are bent in a generally letter-C shape toward the display unit 610 side. The substrate 11, the metal layer 90, and the protective layer 17 bend toward the display unit 610 side (minus side in Z direction). However, this is not restrictive, and the substrate 11, the metal layer 90, and the protective layer 17 may be bent to the opposite side from the display unit 610 side (plus side in Z direction). Note that the term “bent” in the Present Specification is not limited to cases of being bent in a curved line shape. This also includes cases in which a plane is bent so as to form an acute angle, a right angle, or an obtuse angle. For example, the substrate 11, the metal layer 90, and the protective layer 17 may be bent in a letter-L shape.

At portions bent in this way, the protective layer 17 situated on the outermost side covers the substrate 11 and the metal layer 90. Accordingly, when performing bending of the wiring board 10 for the purpose of mounting, for example, and the metal layer 90 is bent in conjunction with this, the metal layer 90 is protected by the protective layer 17. Thus, the metal layer 90 can be suppressed from breaking or peeling under tensile force placed on the metal layer 90.

Acrylic resins such as polymethyl (meth)acrylate, polyethyl (meth)acrylate, and so forth, and denatured resins and copolymers thereof, polyvinyl resins such as polyester, polyvinyl alcohol, polyvinyl acetate, polyvinyl acetal, polyvinyl butyral, and so forth, and copolymers thereof, polyurethane, epoxy resin, polyamide, chlorinated polyolefin, and so forth, and like insulating resins that are colorless and transparent, can be used as the material of the protective layer 17.

The difference in the coefficient of thermal contraction of the protective layer 17 and the coefficient of thermal contraction of the substrate 11 after one hour at 120° C. may be 0% or more and 1% or less, and preferably is 0% or more and 0.5% or less. Due to the difference in the coefficient of thermal contraction of the protective layer 17 and the coefficient of thermal contraction of the substrate 11 being within this range, the metal layer 90 can be suppressed from breaking or peeling when the wiring board 10 is placed in a high-temperature environment for a prolonged time. Specifically, the coefficient of thermal contraction of the protective layer 17 after one hour at 120° C. may be 0.01% or more and 2.0% or less, preferably is 0.01% or more and 1.0% or less, and even more preferably is 0.05% or more and 0.3% or less. Also, the coefficient of thermal contraction of the substrate 11 after one hour at 120° C. may be 0.01% or more and 2.0% or less, preferably is 0.01% or more and 1.0% or less, and even more preferably is 0.05% or more and 0.3% or less.

Now, the coefficient of thermal contraction of the protective layer 17 or the substrate 11 after one hour at 120° C. is a value representing how much the dimensions of the protective layer 17 or the substrate 11 change when heat is applied thereto, and can be measured by the following method. First, the protective layer 17 or the substrate 11 is cut to a size of 50 mm (MD) long×4 mm (TD) wide to serve as a test piece. Next, a length M (mm) of the text piece is measured by a precision automatic two-dimensional coordinates measuring machine (AMIC 700, manufactured by Sinto S-Precision, Ltd.). Note that the length and width can be adjusted as appropriate in accordance with the size of the protective layer 17 and the substrate 11, and may be smaller than each of 50 mm long and 4 mm wide. Next, an end portion (approximately 1 mm) of the length direction of the test piece is fixed to a wire net by tape, and the test piece is placed in a state suspended from the wire net. In this state, the test piece is left in an oven heated to 120° C. for one hour, following which the test piece is removed along with the wire net, and left to naturally cool under a room temperature (25° C.) environment. Next, a length N (mm) of the test piece naturally cooled to room temperature is measured by the precision automatic two-dimensional coordinates measuring machine (AMIC 700, manufactured by Sinto S-Precision, Ltd.). The coefficient of thermal contraction is calculated by the following Expression at this time.

coefficient of thermal contraction (%)=(1−(length N/length M))×100

The dissipation factor of the protective layer 17 may be 0.002 or less, and preferably is 0.001 or less. Note that while there is no particular lower limit to the dissipation factor of the protective layer 17, this may be greater than 0. Having the dissipation factor of the protective layer 17 in the above range enables loss of gain (sensitivity) in conjunction with transmission/reception of electromagnetic waves to be reduced, particularly in a case in which electromagnetic waves transmitted/received by the mesh wiring layer 20 (e.g., millimeter waves) are radio frequency waves. Note that the dielectric constant of the protective layer 17 is not limited in particular, but may be 2.0 or higher and 10.0 or lower.

The dissipation factor of the protective layer 17 can be measured in conformance with IEC 62562. Specifically, first, cutting out of the substrate 11 and the protective layer 17 is performed, and the protective layer 17 is peeled off from the substrate 11, so as to prepare a test piece. The dimensions of the test piece are 10 mm to 20 mm in width and 50 mm to 100 mm in length. Next, the dissipation factor is measured in conformance with IEC 62562.

A thickness T₁₂ of the protective layer 17 may be 1 μm or more and 100 μm or less, may be 1 μm or more and 50 μm or less, may be 5 μm or more and 50 μm or less, and preferably is 5 μm or more and 25 μm or less. Due to the thickness T₁₂ of the protective layer 17 being 1 μm or more, abrasion resistance and weather resistance of the protective layer 17 can be improved. Also, due to the thickness T₁₂ of the protective layer 17 being 100 μm or less, the thickness of the wiring board 10 can be reduced, and bendability of the bent portion of the wiring board 10 can be secured. Also, due to the thickness T₁₂ of the protective layer 17 being 50 μm or less, the thickness of the wiring board 10 can be further reduced, and bendability of the bent portion of the wiring board 10 can be further secured. Note that in the present embodiment, the thickness T₁₂ of the protective layer 17 is a distance measured from the surface of the metal layer 90 to the surface of the protective layer 17 in a state in which the wiring board 10 is not bent.

The proportion of the thickness T₁₂ of the protective layer 17 as to the thickness T₁ of the substrate 11 (T₁₂/T₁) may be 0.02 or more and 5.0 or less, and preferably is 0.2 or more and 1.5 or less. Due to this proportion (T₁₂/T₁) being 0.02 or more, abrasion resistance and weather resistance of the protective layer 17 can be improved. Also, due to this proportion (T₁₂/T₁) being 5.0 or less, the thickness of the wiring board 10 can be reduced, and bendability of the bent portion of the wiring board 10 can be secured.

In the present embodiment as well, the power supply line 85 may be electrically connected to the power supply unit 40 of the wiring board 10 via the anisotropic conductive film 85c. The module 80A may further be made up of the wiring board 10 and the power supply line 85 electrically connected to the power supply unit 40 via the anisotropic conductive film 85c (see FIG. 1, FIG. 2, and FIG. 7, etc.).

### [Manufacturing Method of Wiring Board]

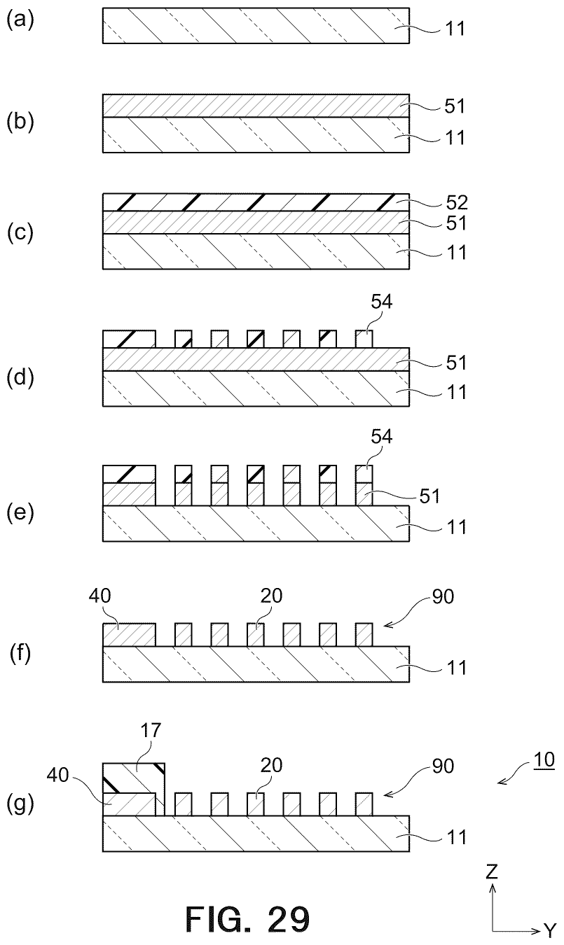

Next, a manufacturing method of the wiring board according to the present embodiment will be described with reference to FIG. 29 (a) to (g). FIG. 29 (a) to (g) are cross-sectional views illustrating the manufacturing method of the wiring board according to the present embodiment.

As illustrated in FIG. 29 (a), the substrate 11 that has transparency is prepared.

Next, the metal layer 90 is formed on the substrate 11. The metal layer 90 includes the mesh wiring layer 20, and the power supply unit 40 that is electrically connected to the mesh wiring layer 20.

At this time, first, as illustrated in FIG. 29 (b), metal foil 51 is laminated on generally the entire region of the front face of the substrate 11. The thickness of the metal foil 51 in the present embodiment may be 0.1 μm or more and 5.0 μm or less. The metal foil 51 in the present embodiment may contain copper.

Next, as illustrated in FIG. 29 (c), photo-curing insulating resist 52 is supplied to generally the entire region of the surface of the metal foil 51. Examples of this photo-curing insulating resist 52 include organic resins such as acrylic resins, epoxy-based resins, and so forth.

Next, as illustrated in FIG. 29 (d), the insulating layer 54 is formed by photolithography. In this case, the photo-curing insulating resist 52 is patterned by photolithography, thereby forming the insulating layer 54 (resist pattern). At this time, the insulating layer 54 is formed such that the metal foil 51 corresponding to the metal layer 90 is exposed.

Next, as illustrated in FIG. 29 (e), the metal foil 51 situated at portions on the front face of the substrate 11, not covered by the insulating layer 54, is removed. At this time, the metal foil 51 is etched such that the surface of the substrate 11 is exposed, by performing wet processing using such as ferric chloride, cupric chloride, strong acids such as sulfuric acid, hydrochloric acid, or the like, persulfate, hydrogen peroxide, or aqueous solutions thereof, or combinations of the above, or the like.

Next, as illustrated in FIG. 29 (f), the insulating layer 54 is removed. At this time, the insulating layer 54 on the metal foil 51 is removed by performing wet processing using a permanganate solution, N-methyl-2-pyrrolidone, acid or alkali solutions, or the like, or dry processing using oxygen plasma.

Thus, the wiring board 10 having the substrate 11, and the metal layer 90 provided on the substrate 11, is obtained. The metal layer 90 includes the mesh wiring layer 20 and the power supply unit 40 that is electrically connected to the mesh wiring layer 20.

Thereafter, as illustrated in FIG. 29 (g), the protective layer 17 is formed on the substrate 11, so as to cover the metal layer 90 situated in the first region A1. The protective layer 17 is not formed in the second region A2 at this time. Roll coating, gravure coating, reverse gravure coating, micro-gravure coating, slot-die coating, die coating, knife coating, ink-jet coating, dispenser coating, kiss coating, spray coating, screen printing, offset printing, or flexo printing may be used as the method for forming the protective layer 17.

### Effects of Present Embodiment

Next, the effects of the present embodiment having such a configuration will be described.

As illustrated in FIG. 23 and FIG. 24, the wiring board 10 is assembled into the image display device 60 that has the display unit 610. At this time, the wiring board 10 is disposed above the display unit 610. The mesh wiring layer 20 of the wiring board 10 is electrically connected to the communication module 63 of the image display device 60 via the power supply unit 40. In this way, radio waves of the predetermined frequency can be transmitted/received via the mesh wiring layer 20, and communication can be performed by using the image display device 60.

According to the present embodiment, the protective layer 17 is present in the first region A1 that does not overlap the display region 61a of the image display device 60. The protective layer 17 is not present in the second region A2 that overlaps the display region 61a of the image display device 60. Accordingly, when the observer observes the image display device 60 from the light-emitting face 64 side, reflected light at the interface of the protective layer 17 and the substrate 11, or at the interface of the protective layer 17 and the fourth adhesive layer 960, is not visually recognized. Accordingly, the wiring board 10 is difficult to visually recognize by the bare eye of the observer. In particular, when the third adhesive layer 950 and the fourth adhesive layer 960 each have an area that is wider than the substrate 11, an outer edge of the substrate 11 can be made to be difficult to visually recognize by the bare eye of the observer, and the observer can be kept from recognizing the presence of the substrate 11.

Also, according to the present embodiment, the protective layer 17 does not overlap the fourth adhesive layer 960 in the second region A2. Accordingly, a stepped portion is not readily created at the portion of the fourth adhesive layer 960 that corresponds to the outer edge of the substrate 11. Accordingly, the outer edge of the substrate 11 can be made to be difficult to visually recognize by the bare eye of the observer, and the observer can be kept from recognizing the presence of the substrate 11.

Also, according to the present embodiment, the protective layer 17 is present on the metal layer 90 situated in the first region A1. Accordingly, when mounting the wiring board 10, situations in which the metal layer 90 is scratched or the metal layer 90 is fractured can be suppressed.

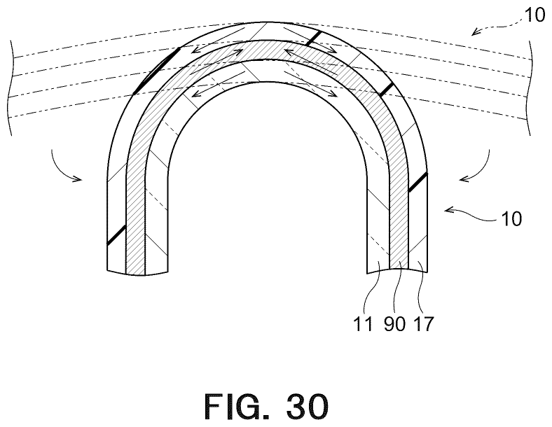

In particular, in a case in which part of the wiring board 10 is bent in the first region A1, a situation in which the metal layer 90 cracks or peels due to tensile force when the wiring board 10 is bent is suppressed. That is to say, as illustrated in FIG. 30, when the wiring board 10 is bent, the substrate 11 and the protective layer 17 that are relatively flexible are each stretched to the outer side. On the other hand, force in an opposite direction (inner side) acts on the metal layer 90 situated between the substrate 11 and the protective layer 17. Accordingly, the metal layer 90 does not become markedly stretched. Thus, the metal layer 90 is protected by the protective layer 17, and cracking or peeling of the metal layer 90 is suppressed.

Also, according to the present embodiment, the wiring board 10 has the substrate 11 that has transparency, and the mesh wiring layer 20 disposed on the substrate 11. This mesh wiring layer 20 has a mesh pattern made up of a conductor portion serving as a formation portion of a non-transparent conductor layer, and a great number of openings. Accordingly, the transparency of the wiring board 10 is secured. Thus, when the wiring board 10 is disposed over the display unit 610, the display region 61a can be visually recognized from the openings 23 of the mesh wiring layer 20, and visual recognition of the display region 61a is not impeded.

### EXAMPLES

Next, specific examples according to the above embodiment will be described.

### Example A1

A wiring board including a substrate, a metal layer, and a protective layer (Example A1) was fabricated. The substrate was made of polyethylene terephthalate, and the thickness thereof was 10 μm. The metal layer was made of copper, and the thickness thereof was 2 μm. The line width of a mesh wiring layer was 2 μm for all, and all openings were squares within one side of 100 μm. The protective layer was formed only in a first region of the metal layer that does not overlap a display region. The protective layer was made of an acrylic-based resin, and the thickness thereof was 10 μm.

### Example A2

A wiring board (Example A2) was fabricated in the same way as with Example A1, except that the thickness of the substrate was 25 μm, and the thickness of the protective layer was 25 μm.

### Comparative Example A1

A wiring board (Comparative Example A1) was fabricated in the same way as with Example A1, except that no protective layer was provided.

### Comparative Example A2

A wiring board (Comparative Example A2) was fabricated in the same way as with Example A1, except that the thickness of the protective layer was 12 μm, and that the protective layer was formed in the second region in addition to the first region as well.

Next, the wiring boards according to Examples A1 and 2 and Comparative Examples A1 and 2 were each evaluated regarding mounting withstanding, non-visibility, and bending withstanding when assembled into an image display device. Results thereof are shown in Table 1.

For “mounting withstanding”, those with no damage such as line breakage, pattern distortion, or pattern collapse when subjected to heat or pressure at the time of mounting the wiring board were determined to be “high”, and those that exhibited damage such as line breakage, pattern distortion, or pattern collapse when subjected to heat or pressure at the time of mounting the wiring board were determined to be “low”.

For “non-visibility”, those regarding which the outer edge of the wiring board could not be visually discerned when observing the front face of the base material under a general visual inspection environment from angles of 30°, 60°, and 90°, were determined to be “high”, and those regarding which the outer edge of the wiring board could be visually discerned when observing the front face of the base material under a general visual inspection environment from angles of 30°, 60°, and 90°, were determined to be “low”.

For “bending withstanding”, those that exhibited no peeling or breakage of the metal layer, and also variance in resistance value was less than 0.5 Ω/sq when bending the wiring board 180° along a perimeter of a cylinder 2 mm in diameter, using a cylindrical mandrel bend tester, were determined to be “high”, and those that exhibited peeling or breakage of the metal layer, or variance in resistance value was 0.5 Ω/sq or higher when bending the wiring board 180° along the perimeter of the cylinder 2 mm in diameter, using the cylindrical mandrel bend tester, were determined to be “low”.

TABLE 1

| | | | Location of | | | |
|---|---|---|---|---|---|---|
| | Thickness of | | forming | | | |
| | protective | Thickness of | protective | Mounting | Non- | Bending |
| | layer | substrate | layer | withstanding | visibility | withstanding |
| Example A1 | 10 μm | 10 μm | First region | High | High | High |
| Example A2 | 25 μm | 25 μm | First region | High | High | High |
| Comparative | None | 10 μm | None | Low | High | Low |
| Example A3 | | | | | | |
| Comparative | 12 μm | 10 μm | First region + | High | Low | High |
| Example A4 | | | second | | | |
| | | | region | | | |

Thus, it was found that the wiring boards according to Examples A1 and 2 were high in all of mounting withstanding, non-visibility, and bending withstanding. It was also found that the wiring boards according to Comparative Examples A1 and 2 were low in one or another of mounting withstanding, non-visibility, and bending withstanding.

### [Modifications]

Next, modifications of the wiring board will be described.

### (First Modification)

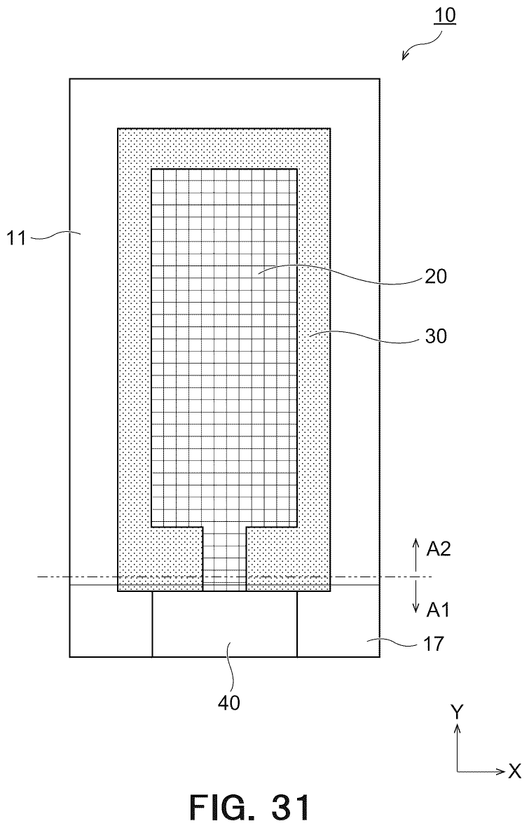

FIG. 31 illustrates a first modification of the wiring board. The modification illustrated in FIG. 31 differs with respect to the point of the dummy wiring layer 30 being provided around the mesh wiring layer 20, and other configurations are generally the same as the embodiments described above, which are illustrated in FIG. 1 to FIG. 30. In FIG. 31, portions that are the same as in the form illustrated in FIG. 1 to FIG. 30 are denoted by the same signs, and detailed description will be omitted.

In the wiring board 10 illustrated in FIG. 31, the dummy wiring layer 30 is provided so as to follow around the mesh wiring layer 20. Unlike the mesh wiring layer 20, this dummy wiring layer 30 does not substantially function as an antenna. In this case, the metal layer 90 includes the mesh wiring layer 20, the dummy wiring layer 30, and the power supply unit 40. The protective layer 17 is present in the first region A1, and is not present in the second region A2.

Thus, by disposing the dummy wiring layer 30 that is electrically isolated from the mesh wiring layer 20 around the mesh wiring layer 20, the outer edge of the mesh wiring layer 20 can be made obscure. Accordingly, the mesh wiring layer 20 can be made to be difficult to see on the front face of the image display device 60, and the mesh wiring layer 20 can be made to be difficult to visually recognize by the bare eye of the user of the image display device 60.

### (Second Modification)

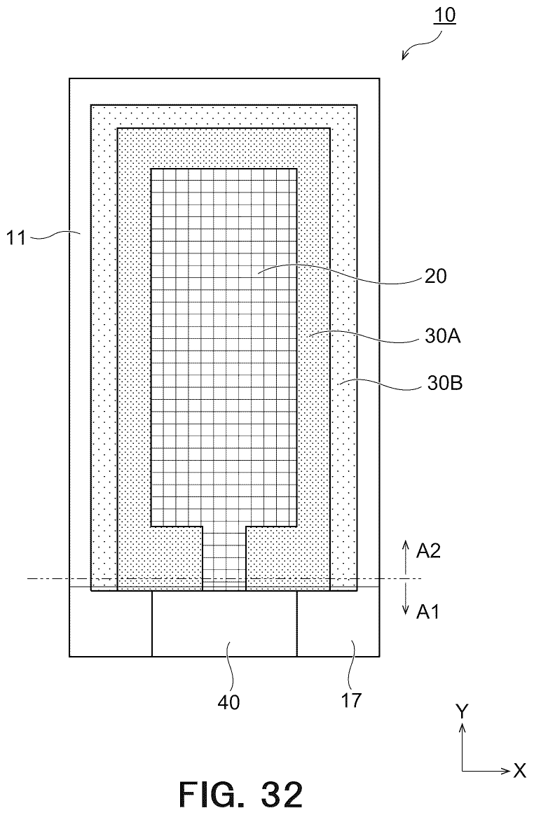

FIG. 32 illustrates a second modification of the wiring board. The modification illustrated in FIG. FIG. 32 differs with respect to the point that a plurality of dummy wiring layers 30A and 30B that have different aperture ratios from each other are provided around the mesh wiring layer 20, and other configurations are generally the same as the embodiments illustrated in FIG. 1 to FIG. 31 described above. In FIG. 32, portions that are the same as in the forms illustrated in FIG. 1 to FIG. 31 are denoted by the same signs, and detailed description will be omitted.

In the wiring board 10 illustrated in FIG. 32, the plurality of (two in this case) dummy wiring layers 30A and 30B (first dummy wiring layer 30A and second dummy wiring layer 30B) that have different aperture ratios from each other are provided so as to follow around the mesh wiring layer 20. Specifically, the first dummy wiring layer 30A is disposed so as to follow around the mesh wiring layer 20, and the second dummy wiring layer 30B is disposed so as to follow around the first dummy wiring layer 30A. Unlike the mesh wiring layer 20, these dummy wiring layers 30A and 30B do not substantially function as an antenna. The metal layer 90 includes the mesh wiring layer 20, the dummy wiring layers 30A and 30B, and the power supply unit 40. The protective layer 17 is present in the first region A1, and is not present in the second region A2.

Thus, by disposing the dummy wiring layers 30A and 30B that are electrically isolated from the mesh wiring layer 20, the outer edge of the mesh wiring layer 20 can be made obscure. Accordingly, the mesh wiring layer 20 can be made to be difficult to see on the front face of the image display device 60, and the mesh wiring layer 20 can be made to be difficult to visually recognize by the bare eye of the user of the image display device 60.

### (Third Modification)

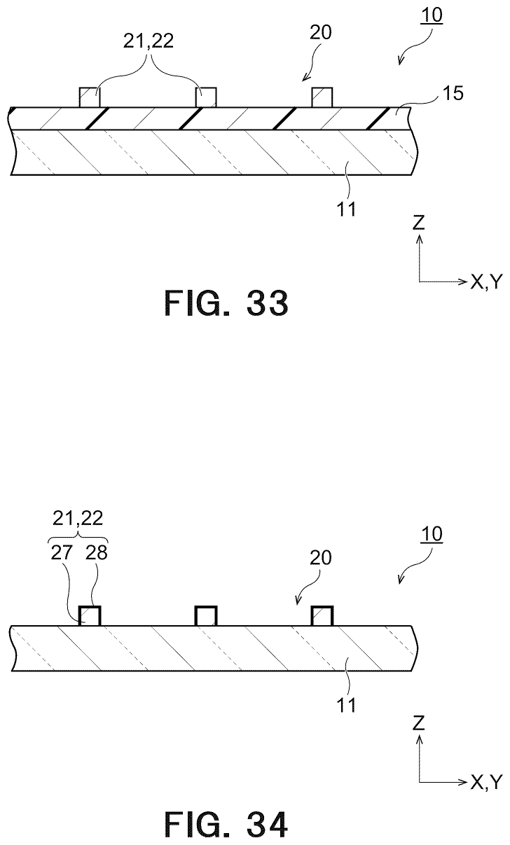

FIG. 33 illustrates a third modification of the wiring board. The modification illustrated in FIG. FIG. 33 differs with respect to the point that a primer layer 15 is disposed between the substrate 11 and the mesh wiring layer 20, and other configurations are generally the same as the embodiments illustrated in FIG. 1 to FIG. 32 described above. In FIG. 33, portions that are the same as in the forms illustrated in FIG. 1 to FIG. 32 are denoted by the same signs, and detailed description will be omitted.

In the wiring board 10 illustrated in FIG. 33, the primer layer 15 is formed on the substrate 11, and the mesh wiring layer 20 is formed on the primer layer 15. The primer layer 15 serves to improve adhesion between the mesh wiring layer 20 and the substrate 11. In this case, the primer layer 15 is provided on generally the entire region of the surface of the substrate 11. Note that the primer layer 15 may be provided only in the region of the surface of the substrate 11 where the mesh wiring layer 20 is provided.

The primer layer 15 may include a polymer material. Thus, the adhesion between the mesh wiring layer 20 and the substrate 11 can be effectively improved. In this case, a colorless and transparent polymer material can be used as the material for the primer layer 15. Also, the primer layer 15 preferably contains an acrylic-based resin or a polyester-based resin. Accordingly, the adhesion between the mesh wiring layer 20 and the substrate 11 can be improved even more effectively.

The thickness of the primer layer 15 is preferably 0.05 μm or more and 0.5 μm or less. Due to the thickness of the primer layer 15 being in the above range, the adhesion between the mesh wiring layer 20 and the substrate 11 can be improved, and also transparency of the wiring board 10 can be secured.

### (Fourth Modification)

FIG. 34 illustrates a fourth modification of the wiring board. The modification illustrated in FIG. 34 differs with respect to the point that the first-direction wiring lines 21 and the second-direction wiring lines 22 each have a blackened layer 28, and other configurations are generally the same as the embodiments illustrated in FIG. 1 to FIG. 33 described above. In FIG. 34, portions that are the same as in the forms illustrated in FIG. 1 to FIG. 33 are denoted by the same signs, and detailed description will be omitted.

In the wiring board 10 illustrated in FIG. 34, the first-direction wiring lines 21 and the second-direction wiring lines 22 each have a main body portion 27, and the blackened layer 28 formed on an outer periphery of each main body portion 27. Of these, the main body portion 27 makes up a primary portion of each of the first-direction wiring lines 21 and the second-direction wiring lines 22, and is situated at the center of the first-direction wiring lines 21 and the second-direction wiring lines 22. Also, the blackened layer 28 is situated on the outermost faces of the first-direction wiring lines 21 and the second-direction wiring lines 22.

It is sufficient for the material of the main body portion 27 to be a metal material that has conductivity. In the present modification, the material of the main body portion 27 is copper, but is not restricted thereto. Examples of materials that can be used for the main body portion 27 include gold, silver, copper, platinum, tin, aluminum, iron, nickel, and other such metal materials (including alloys).

The blackened layer 28 is formed so as to cover an outer face of the main body portion 27. The blackened layer 28 is formed on each of the front face (face on plus side in Z direction) and side faces (faces orthogonal to Z direction). The blackened layer 28 is preferably formed on the entire region of the front face and side faces of the main body portion 27. On the other hand, the blackened layer 28 does not have to be formed on the rear face (face on minus side in Z direction) of the main body portion 27. The blackened layer 28 overall has a black-colored appearance, and is a layer at which visible light is reflected less readily than the main body portion 27. Note that black-colored is not strictly achromatic black, and also includes dark gray, and black or dark gray with tinges of color.

The material of the blackened layer 28 is preferably a metal material that is black-colored, and may contain palladium or tellurium, for example. The palladium or tellurium may be formed by substitution processing of the main body portion 27. Specifically, this may be formed by substitution processing in which metal atoms on the outer face of the main body portion 27 are substituted by palladium or tellurium atoms. Alternatively, the blackened layer 28 may be a layer obtained by oxidization processing of the main body portion 27. Specifically, the blackened layer 28 that is an oxide film in which the main body portion 27 is oxidized may be formed on the outer face of the main body portion 27, by performing oxidization processing of the outer face of main body portion 27 by a blackening treatment liquid. In a case in which the material of the main body portion 27 is copper, for example, the blackened layer 28 may contain cupric oxide.

The thickness of the blackened layer 28 may be 10 nm or more, and preferably is 20 nm or more. Making the thickness of the blackened layer 28 to be 10 nm or more sufficiently covers the main body portion 27 by the blackened layer 28, and accordingly the blackened layer 28 can sufficiently absorb visible light. Accordingly, reflection of visible light at the blackened layer 28 can be suppressed, and the mesh wiring layer 20 can be made to be more difficult to visually recognize with the bare eye. The thickness of the blackened layer 28 may be 100 nm or less, and preferably is 60 nm or less. Making the thickness of the blackened layer 28 to be 100 nm or less suppresses deterioration in electrical conductivity of the mesh wiring layer 20 due to the presence of the blackened layer 28, and can keep current from not readily flowing through the mesh wiring layer 20 when transmitting/receiving radio waves. The thickness of the blackened layer 28 can be measured using STEM-EDS (Scanning Transmission Electron Microscopy-Energy Dispersive X-ray Spectroscopy).

According to the present modification, the first-direction wiring lines 21 and the second-direction wiring lines 22 each have the main body portion 27 and the blackened layer 28 formed on the outer periphery of the main body portion 27. Thus, the blackened layer 28 absorbs visible light, and accordingly reflection of visible light at the main body portion 27 can be suppressed. As a result, the mesh wiring layer 20 can be more difficult to see on the front face of the image display device 60, and recognition of the mesh wiring layer 20 by the bare eye of the observer can be made to be more difficult.

### Third Embodiment

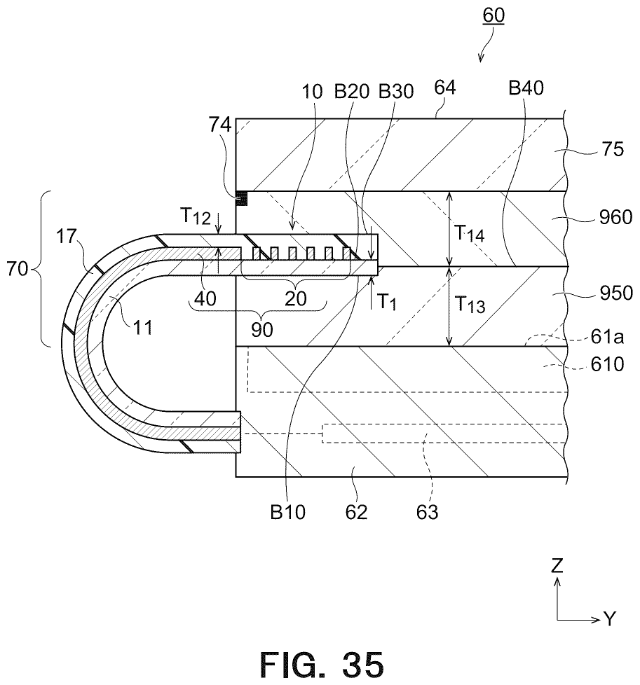

Next, a third embodiment will be described with reference to FIG. 35 to FIG. 37. FIG. 35 to FIG. 37 are diagrams illustrating the present embodiment. In FIG. 35 to FIG. 37, portions that are the same as in the first embodiment illustrated in FIG. 1 to FIG. 22, and portions that are the same as in the second embodiment illustrated in FIG. 23 to FIG. 34, are denoted by the same signs, and detailed description may be omitted.

### [Configuration of Image Display Device]

A configuration of the image display device according to the present embodiment will be described with reference to FIG. 35.

As illustrated in FIG. 35, the image display device 60 according to the present embodiment includes the image display device laminate 70, and the display unit (display) 610 that is laminated on the image display device laminate 70 and that has the display region 61a. In the present embodiment, the protective layer 17 covers the metal layer 90. The difference between the refractive index of the substrate 11 and the refractive index of the protective layer 17 is 0.1 or less.

In the present embodiment, the difference between the greatest value and the smallest value of the refractive index of the substrate 11, the refractive index of the protective layer 17, the refractive index of the third adhesive layer 950, and the refractive index of the fourth adhesive layer 960 is 0.1 or less, preferably is 0.07 or less, and even more preferably is 0.05 or less. Although there is no lower limit to the above difference between the greatest value and the smallest value of the refractive indices, this may be 0 or more. Here, refractive index refers to absolute refractive index, and can be found on the basis of Method A of JIS K-7142. For example, in a case in which the material of the third adhesive layer 950 and the material of the fourth adhesive layer 960 are acrylic-based resins (refractive index 1.49), the refractive indices of the substrate 11 and the protective layer 17 are each 1.39 or more and 1.59 or less, and the difference between the refractive index of the substrate 11 and the refractive index of the protective layer 17 is 0.1 or less.

Thus, the difference between the greatest value and the smallest value of the refractive index of the substrate 11, the refractive index of the protective layer 17, the refractive index of the third adhesive layer 950, and the refractive index of the fourth adhesive layer 960 is 0.1 or less. Accordingly, reflection of visible light at each of an interface B10 of the third adhesive layer 950 and the substrate 11, an interface B20 of the substrate 11 and the protective layer 17, and an interface B30 of the protective layer 17 and the fourth adhesive layer 960, can be suppressed, and the wiring board 10 can be made to be more difficult to visually recognize by the bare eye of the observer.

Further, the material of the third adhesive layer 950 and the material of the fourth adhesive layer 960 are preferably the same as each other. Accordingly, the difference in refractive index between the third adhesive layer 950 and the fourth adhesive layer 960 can be further reduced, and reflection of visible light at an interface B40 of the third adhesive layer 950 and the fourth adhesive layer 960 can be suppressed.

### [Configuration of Wiring Board]

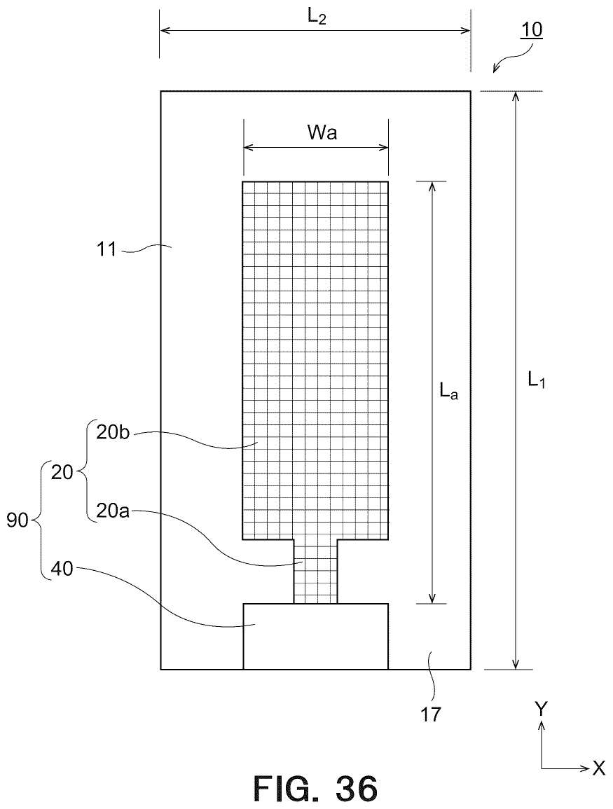

Next, a configuration of the wiring board will be described with reference to FIG. 36. FIG. 36 is a diagram illustrating the wiring board according to the present embodiment.

As illustrated in FIG. 36, the wiring board 10 according to the present embodiment is used in the image display device 60 (see FIG. 35) described above. The wiring board 10 is disposed between the third adhesive layer 950 and the fourth adhesive layer 960, closer to the light-emitting face 64 side than the display unit 610. Such a wiring board 10 includes the substrate 11 that has transparency, the metal layer 90, and the protective layer 17. The metal layer 90 is disposed on the substrate 11. The protective layer 17 covers the metal layer 90. Also, the metal layer 90 includes the mesh wiring layer 20 and the power supply unit 40 that is electrically connected to the mesh wiring layer 20.

The material of the substrate 11 is a material that has transparency in the visible light domain, and electrical insulating properties. In the present embodiment, a material of which the difference as to the refractive index of the protective layer 17 is 0.1 or less is used for the substrate 11, as described above. Also, with respect to the material of the substrate 11, a material by which the difference between the greatest value and the smallest value of the refractive index of the substrate 11, the refractive index of the protective layer 17, the refractive index of the third adhesive layer 950, and the refractive index of the fourth adhesive layer 960, becomes 0.1 or less, is preferably used.

The protective layer 17 is formed on the surface of the substrate 11, so as to cover the metal layer 90. The protective layer 17 is for protecting the metal layer 90. The protective layer 17 may cover the entire region of the mesh wiring layer 20 and the entire region of the power supply unit 40. Alternatively, the protective layer 17 may cover only a partial region of the power supply unit 40. Also, the protective layer 17 covers the substrate 11 in regions where the metal layer 90 is not present. In this case, the protective layer 17 is formed over the entire region of the substrate 11. Specifically, the protective layer 17 is formed over generally the entire region of the substrate 11 in the width direction (X direction) and the longitudinal direction (Y direction). Note that this is not restrictive, and the protective layer 17 may be provided in only a partial region of the substrate 11. For example, the protective layer 17 may be formed in only a partial region of the width direction of the substrate 11.

The difference between the refractive index of the substrate 11 and the refractive index of the protective layer 17 is 0.1 or less, preferably is 0.07 or less, and even more preferably is 0.05 or less. Although there is no particular lower limit to the above difference in refractive index, this may be 0 or more. Suppressing the difference between the refractive index of the substrate 11 and the refractive index of the protective layer 17 to 0.1 or less suppresses reflection of visible light at the interface B20 of the substrate 11 and the protective layer 17, and the wiring board 10 can be made to be more difficult to visually recognize by the bare eye of the observer.

As illustrated in FIG. 35, part of the wiring board 10 is bent at a position outward from the third adhesive layer 950 and the fourth adhesive layer 960. Specifically, the substrate 11, the metal layer 90, and the protective layer 17 of the wiring board 10 are bent in a generally letter-C shape toward the display unit 610 (minus side in Z direction). However, this is not restrictive, and the substrate 11, the metal layer 90, and the protective layer 17 may be bent to the opposite side from the display unit 610 side (plus side in Z direction). Note that the term “bent” in the Present Specification is not limited to cases of being bent in a curved line shape. This also includes cases in which a plane is bent so as to form an acute angle, a right angle, or an obtuse angle. For example, the substrate 11, the metal layer 90, and the protective layer 17 may be bent in a letter-L shape.

At portions bent in this way, the protective layer 17 situated one the outermost side covers the substrate 11 and the metal layer 90. Accordingly, when performing bending of the wiring board 10 for the purpose of mounting, for example, and the metal layer 90 is bent in conjunction with this, the metal layer 90 is protected by the protective layer 17. Thus, the metal layer 90 can be suppressed from breaking or peeling under tensile force placed on the metal layer 90.

For the material of the protective layer 17, one regarding which the difference in refractive index as to the substrate 11 is 0.1 or lower is used. Also, for the material of the protective layer 17, one regarding which the difference between the greatest value and the smallest value of the refractive index of the substrate 11, the refractive index of the protective layer 17, the refractive index of the third adhesive layer 950, and the refractive index of the fourth adhesive layer 960 is 0.1 or less is preferably used. Acrylic resins such as polymethyl (meth)acrylate, polyethyl (meth)acrylate, and so forth, and denatured resins and copolymers thereof, polyvinyl resins such as polyester, polyvinyl alcohol, polyvinyl acetate, polyvinyl acetal, polyvinyl butyral, and so forth, and copolymers thereof, polyurethane, epoxy resin, polyamide, chlorinated polyolefin, and so forth, and like insulating resins that are colorless and transparent, can be used as the material of the protective layer 17, for example.

In the present embodiment as well, the power supply line 85 may be electrically connected to the power supply unit 40 of the wiring board 10 via the anisotropic conductive film 85c. The module 80A may further be made up of the wiring board 10 and the power supply line 85 electrically connected to the power supply unit 40 via the anisotropic conductive film 85c (see FIG. 1, FIG. 2, and FIG. 7, etc.).

### [Manufacturing Method of Wiring Board]

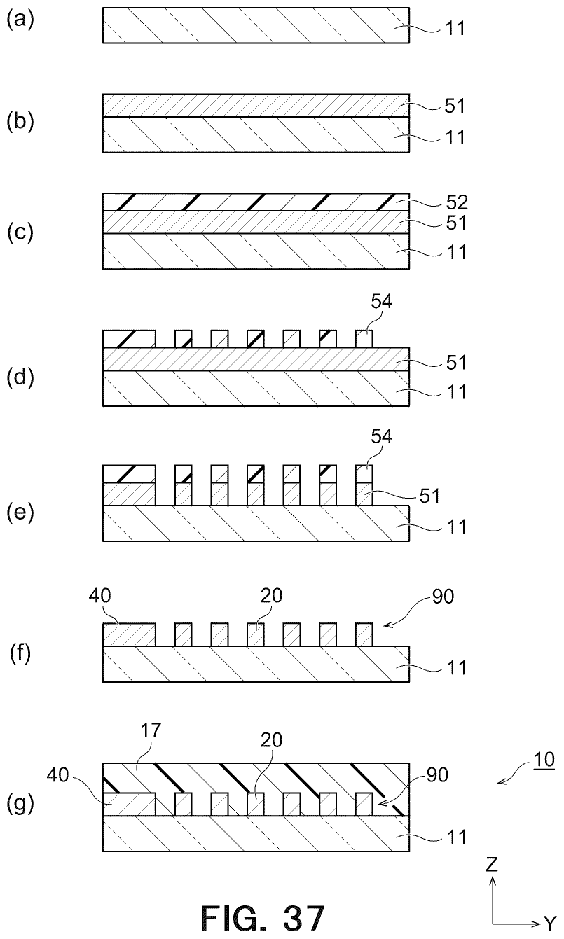

Next, a manufacturing method of the wiring board according to the present embodiment will be described with reference to FIG. 37 (a) to (g). FIG. 37 (a) to (g) are cross-sectional views illustrating the manufacturing method of the wiring board according to the present embodiment.

As illustrated in FIG. 37 (a), the substrate 11 that has transparency is prepared.

Next, the metal layer 90 is formed on the substrate 11. The metal layer 90 includes the mesh wiring layer 20, and the power supply unit 40 that is electrically connected to the mesh wiring layer 20.

At this time, first, as illustrated in FIG. 37 (b), the metal foil 51 is laminated on generally the entire region of the front face of the substrate 11. The thickness of the metal foil 51 in the present embodiment may be 0.1 μm or more and 5.0 μm or less. The metal foil 51 in the present embodiment may contain copper.

Next, as illustrated in FIG. 37 (c), the photo-curing insulating resist 52 is supplied to generally the entire region of the surface of the metal foil 51. Examples of this photo-curing insulating resist 52 include organic resins such as acrylic resins, epoxy-based resins, and so forth.

Next, as illustrated in FIG. 37 (d), the insulating layer 54 is formed by photolithography. In this case, the photo-curing insulating resist 52 is patterned by photolithography, thereby forming the insulating layer 54 (resist pattern). At this time, the insulating layer 54 is formed such that the metal foil 51 corresponding to the metal layer 90 is exposed.

Next, as illustrated in FIG. 37 (e), the metal foil 51 situated at portions on the front face of the substrate 11 not covered by the insulating layer 54 is removed. At this time, the metal foil 51 is etched such that the surface of the substrate 11 is exposed, by performing wet processing using such as ferric chloride, cupric chloride, strong acids such as sulfuric acid, hydrochloric acid, or the like, persulfate, hydrogen peroxide, or aqueous solutions thereof, or combinations of the above, or the like.

Next, as illustrated in FIG. 37 (f), the insulating layer 54 is removed. At this time, the insulating layer 54 on the metal foil 51 is removed by performing wet processing using a permanganate solution, N-methyl-2-pyrrolidone, acid or alkali solutions, or the like, or dry processing using oxygen plasma.

Thus, the wiring board 10 having the substrate 11, and the metal layer 90 provided on the substrate 11, is obtained. The metal layer 90 includes the mesh wiring layer 20 and the power supply unit 40 electrically connected to the mesh wiring layer 20.

Thereafter, as illustrated in FIG. 37 (g), the protective layer 17 is formed, so as to cover the metal layer 90 situated on the substrate 11. The protective layer 17 may be formed on generally the entire region of the substrate 11 at this time. Roll coating, gravure coating, reverse gravure coating, micro-gravure coating, slot-die coating, die coating, knife coating, ink-jet coating, dispenser coating, kiss coating, spray coating, screen printing, offset printing, or flexo printing may be used as the method for forming the protective layer 17.

### Effects of Present Embodiment

Next, the effects of the present embodiment having such a configuration will be described.

As illustrated in FIG. 35, the wiring board 10 is assembled into the image display device 60 that has the display unit 610. At this time, the wiring board 10 is disposed above the display unit 610. The mesh wiring layer 20 of the wiring board 10 is electrically connected to the communication module 63 of the image display device 60 via the power supply unit 40. In this way, radio waves of the predetermined frequency can be transmitted/received via the mesh wiring layer 20, and communication can be performed by using the image display device 60.

According to the present embodiment, the difference between the refractive index of the substrate 11 and the refractive index of the protective layer 17 is 0.1 or lower. Accordingly, reflection of visible light at the interface B20 of the substrate 11 and the protective layer 17 can be suppressed. As a result, when the observer observes the image display device 60 from the light-emitting face 64 side, the substrate 11 of the wiring board 10 can be made to be difficult to visually recognized by the bare eye.

Also, according to the present embodiment, the difference between the greatest value and the smallest value of the refractive index of the substrate 11, the refractive index of the protective layer 17, the refractive index of the third adhesive layer 950, and the refractive index of the fourth adhesive layer 960 is 0.1 or less. Accordingly, reflection of visible light at each of the interface B10 of the third adhesive layer 950 and the substrate 11, the interface B20 of the substrate 11 and the protective layer 17, and the interface B30 of the protective layer 17 and the fourth adhesive layer 960, can be suppressed. As a result, when observing the image display device 60 from the light-emitting face 64 side, the substrate 11 of the wiring board 10 can be made to be more difficult to visually recognize by the bare eye of the observer. In particular, when the third adhesive layer 950 and the fourth adhesive layer 960 each have an area that is wider than that of the substrate 11, the outer edge of the substrate 11 can be made to be difficult to visually recognize by the bare eye of the observer, and the observer can be kept from recognizing the presence of the substrate 11.

Also, according to the present embodiment, the protective layer 17 is formed so as to cover the metal layer 90. Thus, the metal layer 90 can be protected from external shock and so forth. Accordingly, when mounting the wiring board 10, situations in which the metal layer 90 is scratched, the metal layer 90 is fractured, or the like, can be suppressed.

In particular, in a case in which part of the wiring board 10 is bent outward of the third adhesive layer 950 and the fourth adhesive layer 960, a situation in which the metal layer 90 cracks or peels due to tensile force when the wiring board 10 is bent can be suppressed. That is to say, as illustrated in FIG. 30, when the wiring board 10 is bent, the substrate 11 and the protective layer 17 that are relatively flexible are each stretched to the outer side. On the other hand, force in the opposite direction (inner side) acts on the metal layer 90 situated between the substrate 11 and the protective layer 17. Accordingly, the metal layer 90 is not markedly stretched. Thus, the metal layer 90 is protected by the protective layer 17, and cracking or peeling of the metal layer 90 is suppressed.

Also, according to the present embodiment, the wiring board 10 has the substrate 11 that has transparency, and the mesh wiring layer 20 disposed on the substrate 11. This mesh wiring layer 20 has a mesh pattern made up of a conductor portion serving as a formation portion of a non-transparent conductor layer, and a great number of openings, and accordingly, the transparency of the wiring board 10 is secured. Thus, when the wiring board 10 is disposed over the display region 61a, the display region 61a can be visually recognized from the openings 23 of the mesh wiring layer 20, and visual recognition of the display region 61a is not impeded.

### Examples

Next, specific examples according to the above embodiment will be described.

### Example B1

An image display device laminate including a third adhesive layer, a fourth adhesive layer, and a wiring board (Example B1) was fabricated. The wiring board includes a substrate, a metal layer, and a protective layer. The substrate was made of polyethylene terephthalate, and the thickness thereof was 10 μm. The refractive index of the substrate was 1.57. The metal layer was made of copper, and the thickness thereof was 2 μm. The line width of a mesh wiring layer was 2 μm for all, and all openings were squares within one side of 100 μm. The protective layer was formed over the entire region of the substrate. The protective layer was made of an acrylic-based resin, and the thickness thereof was 10 μm. The refractive index of the protective layer was 1.53. For the third adhesive layer, an OCA film made of acrylic-based resin, 25 μm thick, was used. The refractive index of the third adhesive layer was 1.55. For the fourth adhesive layer, an OCA film made of acrylic-based resin, 25 μm thick, was used. The refractive index of the fourth adhesive layer was 1.55. In this case, the difference between the refractive index of the substrate and the refractive index of the protective layer was 0.04. Also, the difference between the greatest value and the smallest value of the refractive index of the substrate, the refractive index of the protective layer, the refractive index of the third adhesive layer, and the refractive index of the fourth adhesive layer, was 0.04.

### Example B2

An image display device laminate (Example B2) was fabricated in the same way as with Example B1, except that an item having a thickness of 25 μm and a refractive index of 1.51 was used as the substrate, an item having a thickness of 25 μm and a refractive index of 1.57 was used as the protective layer, an item having a thickness of 50 μm and a refractive index of 1.54 was used as the third adhesive layer, and an item having a thickness of 75 μm and a refractive index of 1.54 was used as the fourth adhesive layer. In this case, the difference between the refractive index of the substrate and the refractive index of the protective layer was 0.06. Also, the difference between the greatest value and the smallest value of the refractive index of the substrate, the refractive index of the protective layer, the refractive index of the third adhesive layer, and the refractive index of the fourth adhesive layer, was 0.06.

### Example B3

An image display device laminate (Example B3) was fabricated in the same way as with Example B1, except that an item having a thickness of 12 μm and a refractive index of 1.53 was used as the substrate, and an item having a thickness of 0.2 μm and a refractive index of 1.55 was used as the protective layer. In this case, the difference between the refractive index of the substrate and the refractive index of the protective layer was 0.02. Also, the difference between the greatest value and the smallest value of the refractive index of the substrate, the refractive index of the protective layer, the refractive index of the third adhesive layer, and the refractive index of the fourth adhesive layer, was 0.02.

### Comparative Example B1

An image display device laminate (Comparative Example B1) was fabricated in the same way as with Example B1, except that an item having a thickness of 25 μm and a refractive index of 1.51 was used as the substrate, an item having a thickness of 50 μm and a refractive index of 1.65 was used as the protective layer, an item having a thickness of 50 μm and a refractive index of 1.54 was used as the third adhesive layer, and an item having a thickness of 75 μm and a refractive index of 1.54 was used as the fourth adhesive layer. In this case, the difference between the refractive index of the substrate and the refractive index of the protective layer was 0.14. Also, the difference between the greatest value and the smallest value of the refractive index of the substrate, the refractive index of the protective layer, the refractive index of the third adhesive layer, and the refractive index of the fourth adhesive layer, was 0.14.

### Comparative Example B2

An image display device laminate (Comparative Example B2) was fabricated in the same way as with Example B1, except that no protective layer was provided.

Next, the wiring boards according to Examples B1 to 3 and Comparative Examples B1 and 2 were each evaluated regarding mounting withstanding, non-visibility, and bending withstanding when assembled into an image display device. Results thereof are shown in Table 2.

For “mounting withstanding”, those with no damage such as line breakage, pattern distortion, or pattern collapse when subjected to heat or pressure at the time of mounting the wiring board were determined to be “high”, and those that exhibited damage such as line breakage, pattern distortion, or pattern collapse when subjected to heat or pressure at the time of mounting the wiring board were determined to be “low”.

For “non-visibility”, those regarding which the outer edge of the wiring board could not be visually discerned when observing the front face of the base material under a general visual inspection environment from angles of 30°, 60°, and 90°, were determined to be “high”, and those regarding which the outer edge of the wiring board could be visually discerned when observing the front face of the base material under a general visual inspection environment from angles of 30°, 60°, and 90°, were determined to be “low”.

For “bending withstanding”, those that exhibited no peeling or breakage of the metal layer, and also variance in resistance value was less than 0.5 Ω/sq when bending the wiring board 180° along a perimeter of a cylinder 2 mm in diameter, using a cylindrical mandrel bend tester, were determined to be “high”, and those that exhibited peeling or breakage of the metal layer, or variance in resistance value was 0.5 Ω/sq or higher when bending the wiring board 180° along the perimeter of the cylinder 2 mm in diameter, using the cylindrical mandrel bend tester, were determined to be “low”.

TABLE 2

| | | | Protective | | | First adhesive | | Second adhesive | | | | |
|---|---|---|---|---|---|---|---|---|---|---|---|---|
| | Substrate | | layer | | | layer | | layer | | | | |
| | | Refractive | | | Refractive | | Refractive | | Refractive | Mounting | Non- | Bending |
| | Thickness | index | Thickness | | index | Thickness | index | Thickness | index | withstanding | visibility | withstanding |
| Example B1 | 10 μm | 1.57 | 10 | μm | 1.53 | 25 μm | 1.55 | 25 μm | 1.55 | High | High | High |
| Example B2 | 25 μm | 1.51 | 25 | μm | 1.57 | 50 μm | 1.54 | 75 μm | 1.54 | High | High | High |
| Example B3 | 12 μm | 1.53 | 0.2 | μm | 1.55 | 25 μm | 1.55 | 25 μm | 1.55 | High | High | High |
| Comparative | 25 μm | 1.51 | 25 | μm | 1.65 | 50 μm | 1.54 | 75 μm | 1.54 | High | Low | High |

| | | | | | | | | | | | |
|---|---|---|---|---|---|---|---|---|---|---|---|
| Example B1 | | | | | | | | | | | |
| Comparative | 10 μm | 1.53 | None | None | 25 μm | 1.55 | 25 μm | 1.55 | Low | High | Low |
| Example B2 | | | | | | | | | | | |

Thus, it was found that the wiring boards according to Examples B1 to 3 were high in all of mounting withstanding, non-visibility, and bending withstanding. It was also found that the wiring boards according to Comparative Examples B1 and 2 were low in one or another of mounting withstanding, non-visibility, and bending withstanding.

### [Modifications]

Next, modifications of the wiring board will be described.

### (First Modification)

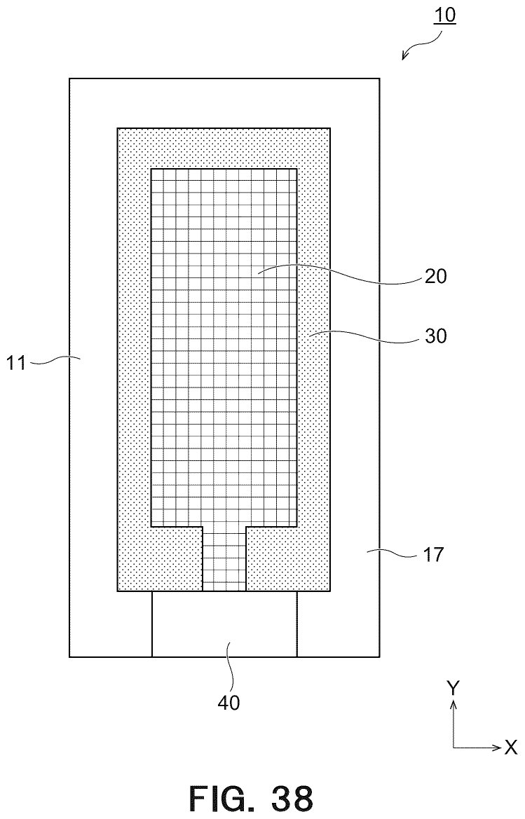

FIG. 38 illustrates a first modification of the wiring board. The modification illustrated in FIG. 38 differs with respect to the point of the dummy wiring layer 30 being provided around the mesh wiring layer 20, and other configurations are generally the same as the embodiments described above, which are illustrated in FIG. 1 to FIG. 37. In FIG. 38, portions that are the same as in the forms illustrated in FIG. 1 to FIG. 37 are denoted by the same signs, and detailed description will be omitted.

In the wiring board 10 illustrated in FIG. 38, the dummy wiring layer 30 is provided so as to follow around the mesh wiring layer 20. Unlike the mesh wiring layer 20, this dummy wiring layer 30 does not substantially function as an antenna. In this case, the metal layer 90 includes the mesh wiring layer 20, the dummy wiring layer 30, and the power supply unit 40.

Thus, by disposing the dummy wiring layer 30 that is electrically isolated from the mesh wiring layer 20 around the mesh wiring layer 20, the outer edge of the mesh wiring layer 20 can be made obscure. Accordingly, the mesh wiring layer 20 can be made to be difficult to see on the front face of the image display device 60, and the mesh wiring layer 20 can be made to be difficult to visually recognize by the bare eye of the user of the image display device 60.

### (Second Modification)

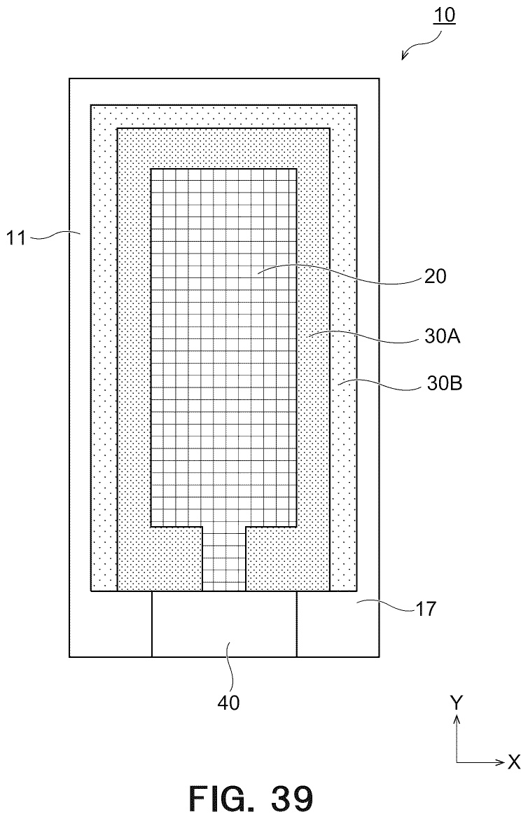

FIG. 39 illustrates a second modification of the wiring board. The modification illustrated in FIG. FIG. 39 differs with respect to the point that the plurality of dummy wiring layers 30A and 30B that have different aperture ratios from each other are provided around the mesh wiring layer 20, and other configurations are generally the same as the embodiments illustrated in FIG. 1 to FIG. 38 described above. In FIG. 39, portions that are the same as in the forms illustrated in FIG. 1 to FIG. 38 are denoted by the same signs, and detailed description will be omitted.

In the wiring board 10 illustrated in FIG. 39, the plurality of (two in this case) dummy wiring layers 30A and 30B (first dummy wiring layer 30A and second dummy wiring layer 30B) that have different aperture ratios from each other are provided so as to follow around the mesh wiring layer 20. Specifically, the first dummy wiring layer 30A is disposed so as to follow around the mesh wiring layer 20, and the second dummy wiring layer 30B is disposed so as to follow around the first dummy wiring layer 30A. Unlike the mesh wiring layer 20, these dummy wiring layers 30A and 30B do not substantially function as an antenna. The metal layer 90 includes the mesh wiring layer 20, the dummy wiring layers 30A and 30B, and the power supply unit 40.

Thus, by disposing the dummy wiring layers 30A and 30B that are electrically isolated from the mesh wiring layer 20, the outer edge of the mesh wiring layer 20 can be made even more obscure. Accordingly, the mesh wiring layer 20 can be made to be difficult to see on the front face of the image display device 60, and the mesh wiring layer 20 can be made to be difficult to visually recognize by the bare eye of the user of the image display device 60.

The plurality of components disclosed in the above embodiments and modifications can be appropriately combined as necessary. Alternatively, some of the components may be omitted from all components shown in the above embodiments and modifications.

1. A module, comprising:
a wiring board that has a substrate including a first face and a second face situated on an opposite side from the first face, a mesh wiring layer disposed on the first face of the substrate, a power supply unit electrically connected to the mesh wiring layer, and a protective layer that is disposed on the first face of the substrate and that covers the mesh wiring layer and the power supply unit; and
a power supply line that is electrically connected to the power supply unit via an anisotropic conductive film containing conductive particles, wherein
the substrate has transparency,
the protective layer covers only part of the power supply unit, and
the anisotropic conductive film covers a region of the power supply unit that is not covered by the protective layer.

2. The module according to claim 1, wherein part of the anisotropic conductive film is disposed on the protective layer.

3. The module according to claim 1, wherein a region of the power supply unit that is covered by neither the protective layer nor the anisotropic conductive film is covered by a covering layer containing a material that has corrosion resistance.

4. The module according to claim 1, wherein the power supply line is electrically connected to the power supply unit by the conductive particles entering into the protective layer.

5. The module according to claim 1, wherein a thickness of the protective layer is 4.0 μm or more and 8.0 μm or less.

6. The module according to claim 1, wherein a dummy wiring layer that is electrically isolated from the mesh wiring layer is provided on a periphery of the mesh wiring layer.

7. The module according to claim 1, wherein the wiring board has a radio wave transmission/reception function.

8. The module according to claim 1, wherein the mesh wiring layer includes a transfer portion that is connected to the power supply unit and a transmission/reception unit that is connected to the transfer portion.

9. An image display device laminate, comprising:
the module according to claim 1;
a first adhesive layer situated on the first face side of the substrate; and
a second adhesive layer situated on the second face side of the substrate, wherein
a partial region of the substrate is disposed in a partial region between the first adhesive layer and the second adhesive layer.

10. An image display device, comprising:
the image display device laminate according to claim 9; and
a display device that is laminated on the image display device laminate.

11. A manufacturing method of a module, the method comprising:
a step of preparing a substrate that includes a first face and a second face situated on an opposite side from the first face;
a step of forming a mesh wiring layer and a power supply unit that is electrically connected to the mesh wiring layer on the first face of the substrate;
a step of forming a protective layer on the first face of the substrate, so as to cover the mesh wiring layer and the power supply unit; and
a step of electrically connecting a power supply line to the power supply unit via an anisotropic conductive film containing conductive particles, wherein
the substrate has transparency,
the protective layer covers only part of the power supply unit, and
the anisotropic conductive film covers a region of the power supply unit that is not covered by the protective layer.

12. A wiring board for an image display device, the wiring board comprising;
a substrate;
a metal layer disposed on the substrate; and
a protective layer that covers part of the metal layer, wherein
the substrate has transparency,
the metal layer includes a mesh wiring layer, and
the protective layer is present in a first region that does not overlap a display region of the image display device, and is not present in a second region that overlaps the display region of the image display device.

13. The wiring board according to claim 12, wherein a difference in a coefficient of thermal contraction of the protective layer and a coefficient of thermal contraction of the substrate after one hour at 120° C. is 1% or less.

14. The wiring board according to claim 12, wherein a dissipation factor of the protective layer is 0.002 or less.

15. The wiring board according to claim 12, wherein a proportion of a thickness T₁₂ of the protective layer as to a thickness T₁ of the substrate (T₁₂/T₁) is 0.02 or more and 5.0 or less.

16. The wiring board according to claim 12, wherein a thickness of the substrate is 10 μm or more and 50 μm or less.

17. The wiring board according to claim 12, wherein a dummy wiring layer that is electrically isolated from the mesh wiring layer is provided on a periphery of the mesh wiring layer.

18. The wiring board according to claim 12, wherein the mesh wiring layer functions as an antenna.

19. The wiring board according to claim 12, further comprising:
a power supply unit electrically connected to the mesh wiring layer, wherein
the mesh wiring layer includes a transfer portion that is connected to the power supply unit and a transmission/reception unit that is connected to the transfer portion.

20. The wiring board according to claim 12, wherein the substrate, the metal layer, and the protective layer are bent in the first region.

21. A module, comprising:
the wiring board according to claim 12; and
a power supply line electrically connected to the wiring board.

22. An image display device laminate, comprising:
the wiring board according to claim 12;
a third adhesive layer that has a wider area than the substrate; and
a fourth adhesive layer that has a wider area than the substrate, wherein
the third adhesive layer has transparency,
the fourth adhesive layer has transparency, and
a partial region of the substrate is disposed in a partial region between the third adhesive layer and the fourth adhesive layer.

23. The image display device laminate according to claim 22, wherein at least one thickness of a thickness of the third adhesive layer and a thickness of the fourth adhesive layer is 1.5 times or more a thickness of the substrate.

24. The image display device laminate according to claim 22, wherein material of the third adhesive layer is acrylic-based resin, and material of the fourth adhesive layer is acrylic-based resin.

25. An image display device, comprising:
the image display device laminate according to claim 22; and
a display unit that has a display region and that is laminated on the image display device laminate.

26-39. (canceled)
